(19) United States
(12) Patent Application Publication
(10) Pub. No.: US 2016/0343708 A1
(43) Pub. Date: Nov. 24, 2016

(54) SEMICONDUCTOR DEVICES AND METHODS OF MANUFACTURING THE SAME

(71) Applicants: Jungil PARK, Gwacheon-si (KR); Jeong-Hoon AHN, Yongin-si (KR); Junjung KIM, Suwon-si (KR); Chul-Yong PARK, Hwaseong-si (KR)

(72) Inventors: Jungil PARK, Gwacheon-si (KR); Jeong-Hoon AHN, Yongin-si (KR); Junjung KIM, Suwon-si (KR); Chul-Yong PARK, Hwaseong-si (KR)

(21) Appl. No.: 15/048,986

(22) Filed: Feb. 19, 2016

(30) Foreign Application Priority Data
May 20, 2015 (KR) 10-2015-0070626

(51) Int. Cl. H01L 27/088; H01L 29/06; H01L 29/417; H01L 29/78; H01L 23/528; H01L 23/522

(52) U.S. Cl. CPC H01L 27/0886; H01L 23/5286; H01L 23/5226; H01L 29/41725; H01L 29/7832; H01L 29/0696; H01L 29/785

(57) ABSTRACT

A semiconductor device may include a substrate, a plurality of first contact plugs, a first via and a power rail. The substrate may include first and second cell regions and a power rail region. The first and second cell regions may be disposed in a second direction, and the power rail region may be disposed between the first and second regions. The plurality of first contact plugs may be formed on the power rail region of the substrate, and may be spaced apart from each other by a first distance in a first direction crossing the second direction. The first via may commonly contact top surfaces of the first contact plugs. The power rail may be formed on the first via. The power rail may provide a voltage for the first and second cell regions through the first via and the first contact plugs.

### CROSS-REFERENCE TO RELATED APPLICATION

This application claims priority under 35 USC §119 to Korean Patent Application No. 10-2015-0070626, filed on May 20, 2015 in the Korean Intellectual Property Office (KIPO), the contents of which are herein incorporated by reference in their entirety.

### BACKGROUND

1. Technical Field

Example embodiments relate to semiconductor devices and methods of manufacturing the same. More particularly, example embodiments relate to semiconductor devices having power rails and methods of manufacturing the same.

2. Description of the Related Art

A power rail of a semiconductor device may be formed on an edge of a cell region of a substrate, and may contact an underlying contact plug to provide power for cells in the cell region. The power rail may be formed to include a via and a wiring by a dual damascene process, and the via may contact the contact plug. When the contact plugs are formed to be close to each other as the semiconductor device has been small, the vias contacting the contact plugs may not be exactly formed.

### SUMMARY

Example embodiments provide semiconductor devices having a high reliability, and to methods of manufacturing such semiconductor devices.

According to example embodiments, there is provided a semiconductor device. The semiconductor device may include a substrate, a plurality of first contact plugs, a first via and a power rail. The substrate may include first and second cell regions and a power rail region. The first and second cell regions may be disposed in a second direction, and the power rail region may be disposed between the first and second regions. The plurality of first contact plugs may be formed on the power rail region of the substrate, and may be spaced apart from each other by a first distance in a first direction crossing the second direction. The first via may commonly contact top surfaces of the first contact plugs. The power rail may be formed on the first via. The power rail may provide a voltage for the first and second cell regions through the first via and the first contact plugs.

According to example embodiments, there is provided a semiconductor device. The semiconductor device may include a substrate, an active fin, a gate structure, a source/drain layer, a first lower contact plug, a plurality of upper contact plugs, a first via, and a power rail. The substrate may include a cell region and a power rail region. Cells may be formed in the cell region, and a power rail providing a voltage for the cells may be formed in the power rail region. The active fin may be formed on the substrate, and may protrude from a top surface of an isolation pattern on the substrate. The active fin may extend in a first direction. The gate structure may extend in a second direction crossing the first direction on the active fin and the isolation pattern. The source/drain layer may be formed on a portion of the active fin adjacent to the gate structure. The first lower contact plug may be formed on the source/drain layer. The plurality of upper contact plugs may be disposed in the first direction on the power rail region of the substrate. At least one of the upper contact plugs may be electrically connected to the first lower contact plug. The first via may commonly contact top surfaces of the upper contact plugs. The power rail may be formed on the first via, and may extend in the first direction.

According to example embodiments, there is provided a semiconductor device. The semiconductor device may include a substrate, finFETs, a lower contact plug structure, an upper contact plug structure, a via structure, and a power rail. The substrate may include a plurality of cell regions and a plurality of power rail regions. The cell regions and the power rail regions may be alternately and repeatedly disposed in a second direction. The finFETs may be formed on the cell regions. The lower contact plug structure may be electrically connected to at least one of the finFETs. The upper contact plug structure may be formed on each of the power rail regions, and may be electrically connected to the lower contact plug structure. The upper contact plug structure may include a plurality of first upper contact plugs adjacent to each other in a first direction substantially perpendicular to the second direction, and a second upper contact plug. The via structure may be formed on each of the power rail regions, and may include a first via commonly contacting top surfaces of the first upper contact plugs and having a first width in the first direction, and a second via contacting the second upper contact plug and having a second width in the first direction less than the first width. The power rail may be integrally formed with the via structure, and provide a voltage for at least one of the finFETs.

According to example embodiments, there is provided a method of manufacturing a semiconductor device. In the method, a plurality of first contact plugs may be formed on a power rail region of a substrate including first and second cell regions disposed in a second direction and the power rail region between the first and second cell regions. The plurality of first contact plugs may be spaced apart from each other by a first distance in a first direction crossing the second direction. A first via may be formed to commonly contact top surfaces of the first contact plugs. A power rail may be formed on the first via. The power rail may provide a voltage for the first and second cell regions through the first via and the first contact plugs.

According to example embodiments, there is provided a method of manufacturing a semiconductor device. In the method, an isolation pattern may be formed on a substrate to define an active fin protruding from the isolation pattern and extending in a first direction. The substrate may include a cell region and a power rail region. Cells may be formed in the cell region and a power rail providing a voltage for the cells may be formed in the power rail region. A gate structure may be formed on the active fin and the isolation pattern to extend in a second direction crossing the first direction. A source/drain layer may be formed on a portion of the active fin adjacent to the gate structure. A first lower contact plug may be formed on the source/drain layer. A plurality of upper contact plugs may be formed in the first direction on the power rail region of the substrate. At least one of the upper contact plugs may be electrically connected to the first lower contact plug. A first via may be formed to commonly contact top surfaces of the upper contact plugs. A power rail may be formed on the first via to extend in the first direction.

According to example embodiments, there is provided a method of manufacturing a semiconductor device. In the method, finFETs may be formed on cell regions of a substrate including the cell regions and power rail regions that are alternately and repeatedly disposed in a second direction. A lower contact plug structure may be formed to be electrically connected to at least one of the finFETs. An upper contact plug structure may be formed on each of the power rail regions to be electrically connected to the lower contact plug structure. The upper contact plug structure may include a plurality of first upper contact plugs adjacent to each other in a first direction substantially perpendicular to the second direction, and a second upper contact plug. A via structure and a power rail may be integrally formed on each of the power rail regions. The via structure may include a first via commonly contacting top surfaces of the first upper contact plugs and having a first width in the first direction, and a second via contacting the second upper contact plug and having a second width in the first direction less than the first direction. The power rail may provide a voltage for at least one of the finFETs.

In the method of manufacturing the semiconductor device in accordance with example embodiments, only one via may be formed to commonly contact a plurality of contact plugs spaced apart from each other in a direction by a short distance, instead of a plurality of vias contacting the plurality of contact plugs, respectively. Thus, the via may be exactly formed by a simple process.

### BRIEF DESCRIPTION OF THE DRAWINGS

Example embodiments will be more clearly understood from the following detailed description taken in conjunction with the accompanying drawings. FIGS. 1 to 69 represent non-limiting, example embodiments as described herein.

FIG. 1 is a cross-sectional view illustrating a semiconductor device in accordance with example embodiments;

FIGS. 2 to 6 are cross-sectional views illustrating stages of a method of manufacturing a semiconductor device in accordance with example embodiments;

FIG. 7 is a cross-sectional view illustrating a semiconductor device in accordance with example embodiments;

FIG. 8 is a cross-sectional view illustrating a stage of a method of manufacturing a semiconductor device in accordance with example embodiments;

FIGS. 9 to 16 are plan views and cross-sectional views illustrating a semiconductor device in accordance with example embodiments;

FIGS. 17 to 60 are plan views and cross-sectional views illustrating stages of a method of manufacturing a semiconductor device in accordance with example embodiments;

FIGS. 61 to 63 are a plan view and cross-sectional views illustrating a semiconductor device in accordance with example embodiments;

FIGS. 64 to 66 are a plan view and cross-sectional views illustrating a semiconductor device in accordance with example embodiments; and

FIGS. 67 to 69 are a plan view and cross-sectional views illustrating a semiconductor device in accordance with example embodiments.

### DESCRIPTION OF EMBODIMENTS

Various example embodiments will be described more fully hereinafter with reference to the accompanying drawings, in which some example embodiments are shown. These embodiments may, however, be realized in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

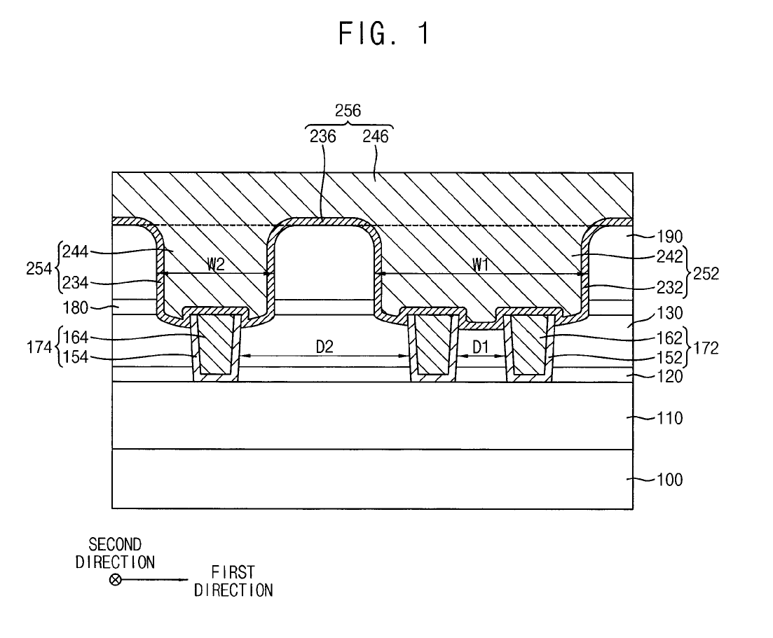

FIG. 1 is a cross-sectional view illustrating a semiconductor device in accordance with example embodiments.

Referring to FIG. 1, the semiconductor device may include a contact plug structure, a via structure and a power rail 256 on a substrate 100. The semiconductor device may further include first, second and third insulating interlayers 110, 130 and 190, respectively, and first and second etch stop layers 120 and 180, respectively, on the substrate 100.

The substrate 100 may include a semiconductor material, e.g., silicon, germanium, silicon-germanium, etc., or III-V semiconductor compounds, e.g., GaP, GaAs, GaSb, etc. In an example embodiment, the substrate 100 may be a silicon-on-insulator (SOI) substrate, a germanium-on-insulator (GOI) substrate, etc.

The substrate 100 may include a cell region (not shown) in which cells may be formed, and a power rail region in which the power rail 256 may be formed. The contact plug structure, the via structure and the power rail 256 may be formed on the power rail region of the substrate 100. Although not shown, various types of elements, e.g., gate structures, source/drain layers, contact plugs, etc., may be formed on the cell region of the substrate 100, and may be covered by the first insulating interlayer 110.

The first insulating interlayer 110, the first etch stop layer 120, the second insulating interlayer 130, the second etch stop layer 180 and the third insulating interlayer 190 may be sequentially formed on the substrate 100. The first, second and third insulating interlayers 110, 130 and 190 may include, e.g., silicon oxide. Alternatively, the first, second and third insulating interlayers 110, 130 and 190 may include a low-k dielectric material (e.g., silicon oxide doped with carbon (SiCOH), silicon oxide doped with fluorine (F—SiO₂), etc.), a porous silicon oxide, a spin-on organic polymer, an inorganic polymer (e.g., hydrogen silsesquioxane (HSSQ), methyl silsesquioxane (MSSQ), etc.), or the like. The first, second and third insulating interlayers 110, 130 and 190 may include substantially the same material or different materials.

The first etch stop layer 120 may include a nitride, e.g., silicon nitride, silicon carbonitride, silicon oxycarbonitride, etc. The second etch stop layer 180 may include a nitride, e.g., silicon nitride, silicon carbonitride, silicon oxycarbonitride, aluminum nitride, etc., an oxide, e.g., titanium oxide, tantalum oxide, zinc oxide, etc., or the like. The first and second etch stop layers 120 and 180 may include substantially the same material or different materials.

The contact plug structure may include first and second contact plugs 172 and 174, respectively, which may be formed on the first insulating interlayer 110 and may penetrate through the second insulating interlayer 130 and the first etch stop layer 120.

In example embodiments, a plurality of first contact plugs 172 may be spaced apart from each other by a first distance D1 in a first direction substantially parallel to a top surface of the substrate 100, and the second contact plug 174 may be spaced apart from one of the first contact plugs 172 closest thereto by a second distance D2, which is greater than the first distance D1.

Although FIG. 1 shows two first contact plugs 172 and one second contact plug 174, it will be appreciated that the inventive concepts are not limited thereto. That is, any number of first contact plugs 172 may be formed in the first direction, and a plurality of second contact plugs 174 may be also formed in the first direction. The plurality of second contact plugs 174 may be spaced apart from each other by any distance that is greater than the first distance D1 in the first direction. Further, the first distance D1 between the first contact plugs 172 or the distance between the second contact plugs 174 may not be constant, and may vary. In other words, first distances D1 between neighboring ones of the first contact plugs 172 disposed in the first direction may be different from each other, and the distances between neighboring ones of the second contact plugs 174 disposed in the first direction may be also different from each other, however, the first distances D1 may be smaller than the distances between the second contact plugs 174 or the second distance D2 between the second contact plug 174 and the nearest one of the first contact plugs 172 thereto.

In an example embodiment, each of the first and second contact plugs 172 and 174 may extend in a second direction, which may be substantially parallel to the top surface of the substrate 100 and cross the first direction. In example embodiments, the first and second directions may cross each other at a right angle. That is, the first and second directions may be perpendicular (or at least substantially perpendicular) to each other.

The first contact plug 172 may include a first barrier pattern 152 and a first conductive pattern 162, sequentially stacked; and the second contact plug 174 may include a second barrier pattern 154 and a second conductive pattern 164, sequentially stacked. The first barrier pattern 152 may cover a bottom and a sidewall of the first conductive pattern 162, and the second barrier pattern 154 may cover a bottom and a sidewall of the second conductive pattern 164.

The first and second barrier patterns 152 and 154 may include a metal nitride, e.g., tantalum nitride, titanium nitride, etc., and/or a metal, e.g., tantalum, titanium, etc. The first and second conductive patterns 162 and 164 may include a metal, e.g., tungsten, copper, aluminum, etc.

The via structure may include first and second vias 252 and 254, respectively, which may be formed on the contact plug structure and the second insulating interlayer 130, and may penetrate through a lower portion of the third insulating interlayer 190 and the second etch stop layer 180.

The first via 252 may contact top surfaces of the first contact plugs 172 and an upper surface of a portion of the second insulating interlayer 130 between the first contact pugs 172, and may further contact upper surfaces of portions of the second insulating interlayer 130 adjacent to outer edges of the first contact plugs 172. The second via 254 may contact a top surface of the second contact plug 174 and an upper surface of a portion of the second insulating interlayer 130 adjacent to the second contact plug 174.

When a plurality of second contact plugs 174 is formed, a plurality of second vias 254 may be formed on the plurality of second contact plugs 174, respectively. The first via 252 may commonly contact top surfaces of the plurality of first contact plugs 172. However, the second via 254 may not commonly contact top surfaces of the plurality of second contact plugs 174. Rather, each second via 254 of the plurality of second vias 254 may contact a respective top surface of an individual one of the plurality of second contact plugs 174. In example embodiments, the first via 252 may have a first width W1 in the first direction that is greater than a second width W2 of the second via 254 in the first direction.

A bottom of each of the first and second vias 252 and 254 may not have a constant height, and a portion of the bottom of each of the first and second vias 252 and 254 contacting top surfaces of the first and second contact plugs 172 and 174, respectively, may be higher than a portion of the bottom of each of the first and second vias 252 and 254 contacting upper surfaces of portions of the second insulating interlayer 130 laterally adjacent to the first and second contact plugs 172 and 174, respectively.

The power rail 256 may penetrate through an upper portion of the third insulating interlayer 190, and may be connected to and integrally formed with the first and second vias 252 and 254. The power rail 256 and the first and second vias 252 and 254 may include the same (or at least substantially the same) material, and a bottom of the power rail 256 may commonly contact top surfaces of the first and second vias 252 and 254. In example embodiments, the power rail 256 may extend in the first direction.

The first via 252 may include a third barrier pattern 232 and a third conductive pattern 242 sequentially stacked, the second via 254 may include a fourth barrier pattern 234 and a fourth conductive pattern 244 sequentially stacked, and the power rail 256 may include a fifth barrier pattern 236 and a fifth conductive pattern 246 sequentially stacked. The third barrier pattern 232 may cover a bottom and a sidewall of the third conductive pattern 242, the fourth barrier pattern 234 may cover a bottom and a sidewall of the fourth conductive pattern 244, and the fifth barrier pattern 236 may cover a portion of a bottom and a sidewall of the fifth conductive pattern 246.

The third, fourth and fifth barrier patterns 232, 234 and 236 may include a metal nitride, e.g., tantalum nitride, titanium nitride, etc., and/or a metal, e.g., tantalum, titanium, etc., and the third, fourth and fifth conductive patterns 242, 244 and 246 may include a metal, e.g., copper, aluminum, tungsten, etc. In example embodiments, the third, fourth and fifth barrier patterns 232, 234 and 236 may include the same (or at least substantially the same) material, and the third, fourth and fifth conductive patterns 242, 244 and 246 may include the same (or at least substantially the same) material.

In the semiconductor device, the power rail 256 on the power rail region of the substrate 100 may provide a voltage, e.g., source voltage, drain voltage, ground voltage, etc., for the cells on the cell region of the substrate 100 through the via structure and the contact plug structure. A plurality of first vias 252 may not be formed on the top surfaces of the plurality of first contact plugs 172, respectively, which may be spaced apart from each other by a relatively small distance in the first direction. Rather, only one first via 252 may be formed to commonly contact the top surfaces of the plurality of first contact plugs 172. Thus, the first via 252 may be exactly formed even though the first contact plugs 172 may be formed at a small distance, and the power rail 256 may adequately provide a voltage for the cells.

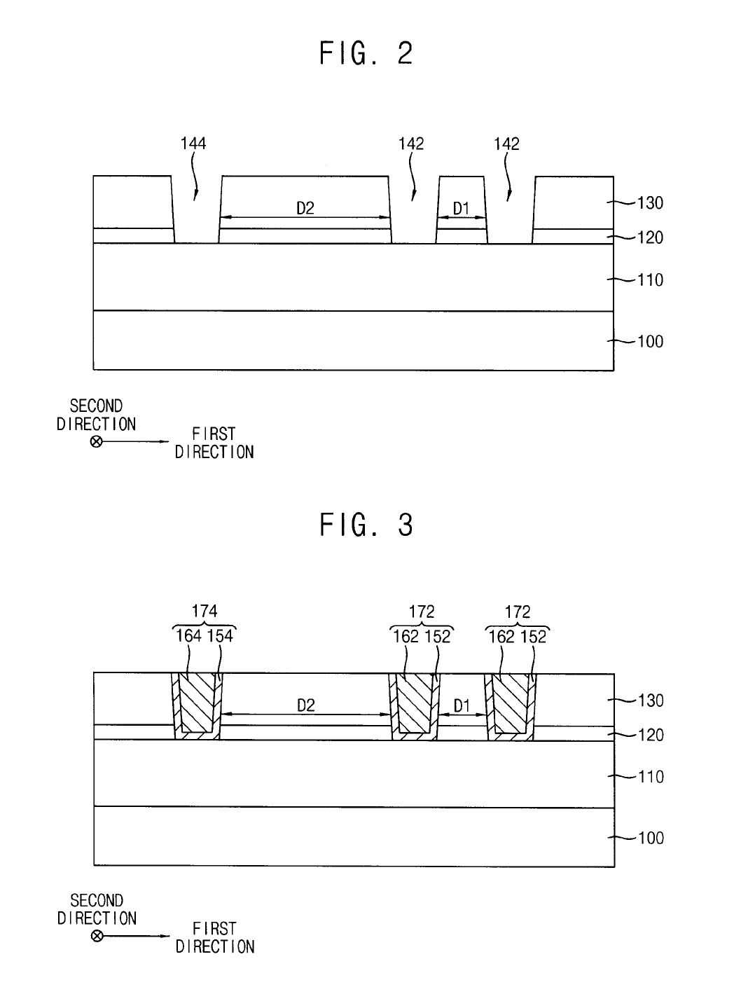

FIGS. 2 to 6 are cross-sectional views illustrating stages of a method of manufacturing a semiconductor device in accordance with example embodiments.

Referring to FIG. 2, a first insulating interlayer 110, a first etch stop layer 120 and a second insulating interlayer 130 may be sequentially formed on a substrate 100. Thereafter, the second insulating interlayer 130 and the first etch stop layer 120 may be partially removed to form first and second openings 142 and 144, respectively, exposing top surfaces of the first insulating interlayer 110.

The substrate 100 may include a semiconductor material, e.g., silicon, germanium, silicon-germanium, etc., or III-V semiconductor compounds, e.g., GaP, GaAs, GaSb, etc. In an example embodiment, the substrate 100 may be an SOI substrate, a GOI substrate, etc.

The substrate 100 may include a cell region (not shown) in which cells may be formed and a power rail region in which a power rail 256 (refer to FIG. 1) may be formed, and FIG. 2 shows the power rail region only. Although not shown, various types of elements, e.g., gate structures, source/drain layers, contact plugs, etc. may be formed on the cell region of the substrate 100, and may be covered by the first insulating interlayer 110.

The first and second insulating interlayers 110 and 130 may be formed of a low-k dielectric material (e.g., silicon oxide doped with carbon (SiCOH), silicon oxide doped with fluorine (F—SiO₂), etc.), a porous silicon oxide, a spin-on organic polymer, an inorganic polymer (e.g., hydrogen silsesquioxane (HSSQ), methyl silsesquioxane (MSSQ), etc.), or the like. The first and second insulating interlayers 110 and 130 may be formed of substantially the same material or different materials. The first etch stop layer 120 may be formed of a nitride, e.g., silicon nitride, silicon carbonitride, silicon oxycarbonitride, etc.

In example embodiments, the first and second openings 142 and 144 may be formed by forming a first photoresist pattern (not shown) on the second insulating interlayer 130, and performing an etching process using the first photoresist pattern as an etching mask.

In example embodiments, a plurality of first openings 142 may be formed to be spaced apart from each other by a first distance D1 in a first direction substantially parallel to a top surface of the substrate 100, and the second opening 144 may be formed to be spaced apart from one of the first openings 142 closest thereto by a second distance D2 greater than the first distance D1. Although FIG. 2 shows two first openings 142 and one second opening 144, it will be appreciated that the inventive concepts are not limited thereto. That is, any plural number of first openings 142 may be formed in the first direction, and a plurality of second openings 144 may be also formed in the first direction. The plurality of second openings 144 may be spaced apart from each other by a distance greater than the first distance D1 between the first openings 142 in the first direction. The first distance D1 between the first openings 142 or the distance between the second openings 144 may not be constant, and may vary. In other words, the first distances D1 between neighboring ones of the first openings 142 disposed in the first direction may be different from each other, and the distances between neighboring ones of the second openings 144 disposed in the first direction may be also different from each other, however, the first distances D1 may be smaller than the distances between the second openings 144 or the second distance D2 between the second opening 144 and the nearest one of the first openings 142 thereto.

In an example embodiment, each of the first and second openings 142 and 144 may extend in a second direction, which may be substantially parallel to the top surface of the substrate 100 and cross the first direction. In example embodiments, the first and second directions may cross each other at a right angle. That is, the first and second directions may be perpendicular (or at least substantially perpendicular) to each other.

After forming the first and second openings 142 and 144, the first photoresist pattern may be removed. In example embodiments, the first photoresist pattern may be removed by an ashing process and/or a stripping process.

Referring to FIG. 3, a first barrier layer may be formed on the exposed top surfaces of the first insulating interlayer 110, sidewalls of the first and second openings 142 and 144, and a top surface of the second insulating interlayer 130, and a first conductive layer may be formed on the first barrier layer to fill remaining portions of the first and second openings 142 and 144.

The first barrier layer may be formed of a metal nitride, e.g., tantalum nitride, titanium nitride, etc., and/or a metal, e.g., tantalum, titanium, etc. The first conductive layer may be formed of a metal, e.g., tungsten, copper, aluminum, etc.

In example embodiments, the first barrier layer may be formed by a process such as a chemical vapor deposition (CVD) process, an atomic layer deposition (ALD) process, a physical vapor deposition (PVD) process, etc. Thus, the first barrier layer may be conformally formed on the exposed top surfaces of the first insulating interlayer 110, the sidewalls of the first and second openings 142 and 144, and the top surface of the second insulating interlayer 130. In example embodiments, the first conductive layer may be formed by a process such as a CVD process or a PVD process, or an electroplating process.

The first conductive layer and the first barrier layer may be planarized until the top surface of the second insulating interlayer 130 may be exposed to form first and second contact plugs 172 and 174 filling the first and second openings 142 and 144, respectively. In example embodiments, the planarization process may be performed by a process such as a chemical mechanical polishing (CMP) process and/or an etch back process.

The first contact plug 172 may include a first barrier pattern 152 and a first conductive pattern 162 sequentially stacked, and the second contact plug 174 may include a second barrier pattern 154 and a second conductive pattern 164 sequentially stacked. The first barrier pattern 152 may cover a bottom and a sidewall of the first conductive pattern 162, and the second barrier pattern 154 may cover a bottom and a sidewall of the second conductive pattern 164.

As the first and second contact plugs 172 and 174 are formed to fill the first and second openings 142 and 144, respectively, the first contact plugs 172 may be formed to be spaced apart from each other in the first direction by the first distance D1, and the second contact plug 174 may be formed to be spaced apart from the nearest one of the first contact plugs 172 thereto in the first direction by the second distance D2, which is greater than the first distance D1.

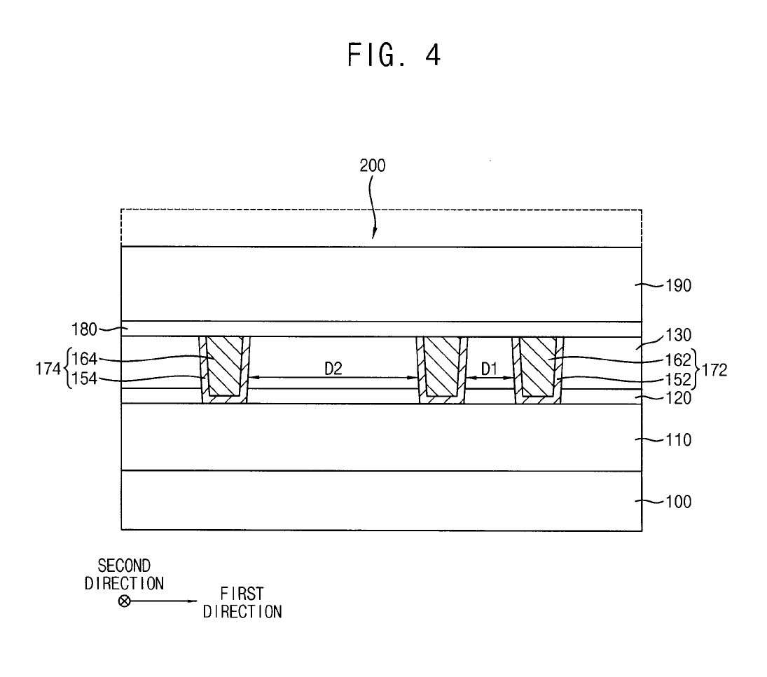

Referring to FIG. 4, a second etch stop layer 180 and a third insulating interlayer 190 may be sequentially formed on the second insulating interlayer 130, and the first and second contact plugs 172 and 174.

The second etch stop layer 180 may be formed of a nitride, e.g., silicon nitride, silicon carbonitride, silicon oxycarbonitride, aluminum nitride, etc., or an oxide, e.g., titanium oxide, tantalum oxide, zinc oxide, etc., or the like. The third insulating interlayer 190 may be formed of an oxide, e.g., silicon oxide, or a low-k dielectric material. The third insulating interlayer 190 may be formed of a material substantially the same as or different from that of the first and second insulating interlayers 110 and 130.

An upper portion of the third insulating interlayer 190 may be partially removed to form a trench 200. In example embodiments, the trench 200 may be formed by forming a second photoresist pattern (not shown) on the third insulating interlayer 190, and performing an etching process using the second photoresist pattern as an etching mask. In example embodiments, the trench 200 may be formed to extend in the first direction.

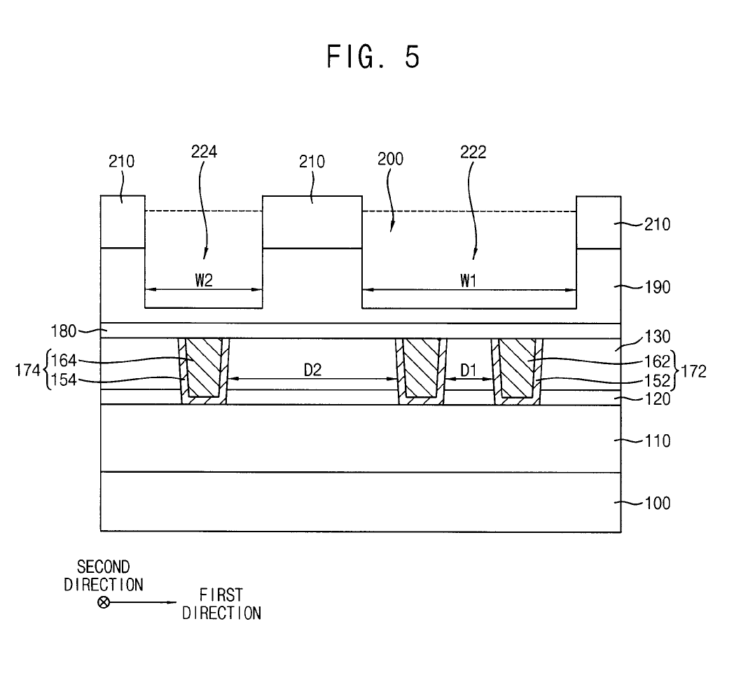

Referring to FIG. 5, the third insulating interlayer 190 may be partially removed to form first and second via holes 222 and 224 in communication with the trench 200. In example embodiments, the first and second via holes 222 and 224 may be formed by forming a third photoresist pattern 210 on the third insulating interlayer 190 having the trench 200 therein, and performing an etching process using the third photoresist pattern 210 as an etching mask.

The first via hole 222 may be formed to overlap at least the first contact plugs 172 and a portion of the second insulating interlayer 130 therebetween, and the second via hole 224 may be formed to overlap at least the second contact plug 174. Further, the first via hole 222 may overlap a portion of the second insulating interlayer 130 adjacent to outer edges of the first contact plugs 172, and the second via hole 224 may overlap a portion of the second insulating interlayer 130 adjacent to the second contact plug 174.

When a plurality of second contact plugs 174 is formed, a plurality of second via holes 224 may be formed such that each second via hole 224 overlaps a respective individual second contact plug 174 of the plurality of second contact plugs 174. The first via hole 222 may commonly overlap top surfaces of the plurality of first contact plugs 172, however, the second via hole 224 may not commonly overlap top surfaces of the plurality of second contact plugs 174, and may overlap the top surfaces of the plurality of second contact plugs 174, respectively. In example embodiments, the first via hole 222 may have a first width W1 in the first direction that is greater than a second width W2 of the second via hole 224 in the first direction.

Although FIG. 5 shows that the first and second via holes 222 and 224 do not penetrate through the third insulating interlayer 190, it will be appreciated that the inventive concepts are not limited thereto. Thus in another example embodiment, the first and second via holes 222 and 224 may penetrate through the third insulating interlayer 190 to expose the second etch stop layer 180.

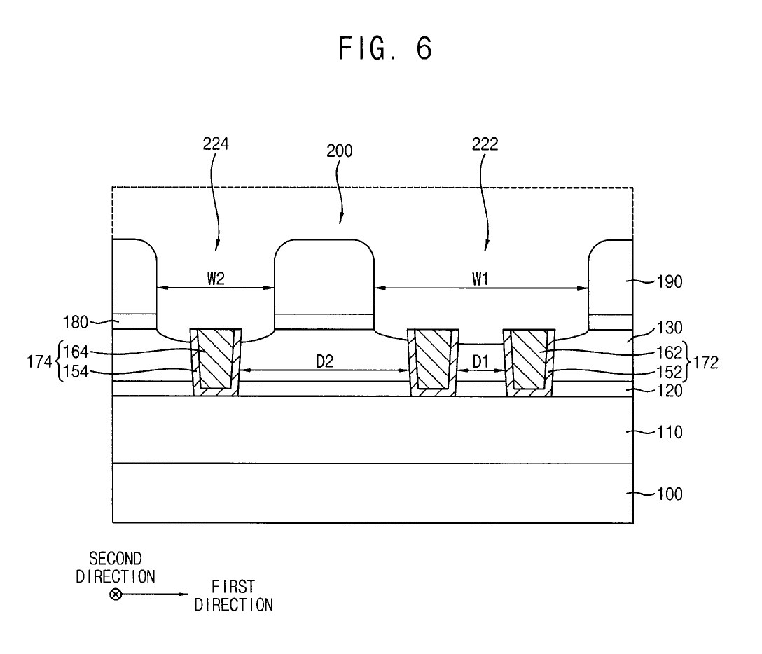

Referring to FIG. 6, after removing the third photoresist pattern 210, the third insulating interlayer 190 having the trench 200 and the first and second via holes 222 and 224 thereon, and the underlying second etch stop layer 180 may be etched until top surfaces of the first and second contact plugs 172 and 174 may be exposed. Thus, the trench 200 and the first and second via holes 222 and 224 may be extended downwardly.

By the etching process, the top surfaces of the first and second contact plugs 172 and 174 and upper surfaces of portions of the second insulating interlayer 130 adjacent thereto may be exposed, and an upper portion of the second insulating interlayer 130 including an insulating material may be also partially etched. Thus, a bottom of each of the first and second via holes 222 and 224 may not have a constant height, and a portion of the bottom of each of the first and second via holes 222 and 224 on the top surfaces of the first and second contact plugs 172 and 174, respectively, may be higher than a portion of the bottom of each of the first and second via holes 222 and 224 on the upper surfaces of the portions of the second insulating interlayer 130 adjacent thereto, respectively.

Referring back to FIG. 1, first and second vias 252 and 254 and the power rail 256 may be formed to fill the first and second via holes 222 and 224 and the trench 200, respectively, to complete the semiconductor device. For example, a second barrier layer may be formed on the exposed top surfaces of the first and second contact plugs 172 and 174, the exposed upper surfaces of the second insulating interlayer 130, sidewalls of the first and second via holes 222 and 224, a bottom and a sidewall of the trench 200, and a top surface of the third insulating interlayer 190. Thereafter, a second conductive layer may be formed on the second barrier layer to fill remaining portions of the first and second via holes 222 and 224 and the trench 200. The second conductive layer and the second barrier layer may then be planarized until the top surface of the third insulating interlayer 190 is exposed, thereby forming the first and second vias 252 and 254 and the power rail 256.

In example embodiments, the second barrier layer may be conformally formed by a process such as a CVD process, an ALD process, a PVD process, or the like, and the second conductive layer may be formed by forming a seed layer (not shown) on the second barrier layer and then performing an electroplating process. The second barrier layer may be formed of a metal nitride, e.g., tantalum nitride, titanium nitride, etc., and/or a metal, e.g., tantalum, titanium, etc. The second conductive layer may be formed of a metal, e.g., tungsten, copper, aluminum, etc.

The first via 252 may contact the top surfaces of the first contact plugs 172 and the upper surfaces of the portions of the second insulating interlayer 130 adjacent to the first contact pugs 172, and may fill the first via hole 222. Thus, the first via 252 may have the first width W1 in the first direction. The second via 254 may contact the top surface of the second contact plug 174 and the upper surface of the portion of the second insulating interlayer 130 adjacent to the second contact plug 174, and may fill the second via hole 224. Thus, the second via 254 may have the second width W2 in the first direction, which may be smaller than the first width W1.

The power rail 256 may be integrally formed with the first and second vias 252 and 254, and may fill the trench 200. In example embodiments, the power rail 256 may extend in the first direction.

The first via 252 may include a third barrier pattern 232 and a third conductive pattern 242 sequentially stacked, the second via 254 may include a fourth barrier pattern 234 and a fourth conductive pattern 244 sequentially stacked, and the power rail 256 may include a fifth barrier pattern 236 and a fifth conductive pattern 246 sequentially stacked. The third barrier pattern 232 may cover a bottom and a sidewall of the third conductive pattern 242, the fourth barrier pattern 234 may cover a bottom and a sidewall of the fourth conductive pattern 244, and the fifth barrier pattern 236 may cover a portion of a bottom and a sidewall of the fifth conductive pattern 246. The third, fourth and fifth barrier patterns 232, 234 and 236 may include substantially the same material, and the third, fourth and fifth conductive patterns 242, 244 and 246 may include substantially the same material.

As illustrated above, instead of forming a plurality of first vias on the plurality of first contact plugs 172, respectively, spaced apart from each other by a relatively short distance in the first direction, only one first via 252 may be formed to commonly contact the plurality of first contact plugs 172, and thus the first via 252 may be exactly formed by a simple process.

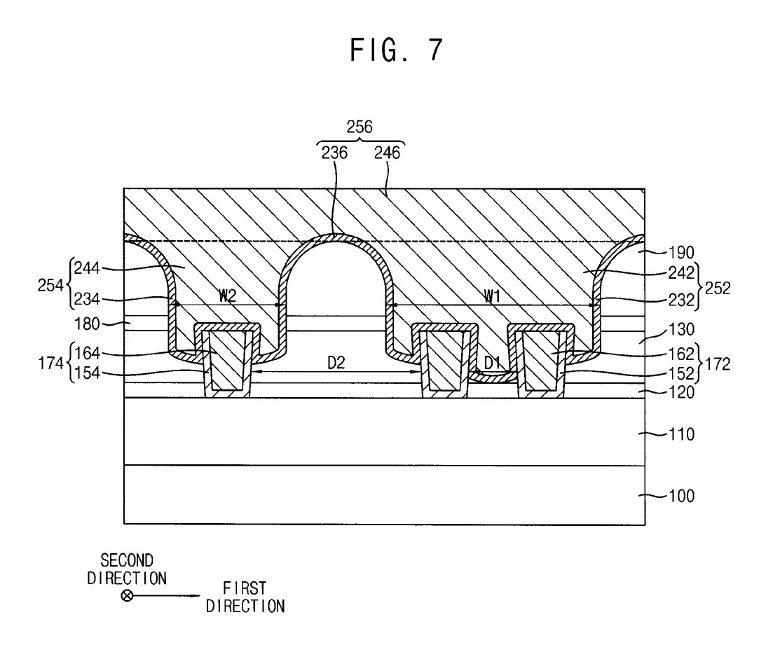

FIG. 7 is a cross-sectional view illustrating a semiconductor device in accordance with example embodiments. The semiconductor device may be substantially the same as or similar to that described with reference to FIG. 1, except for the shape of the via structure. Thus, like reference numerals refer to like elements, and detailed descriptions thereof are omitted herein.

Referring to FIG. 7, the semiconductor device may include the contact plug structure, the via structure and the power rail 256 on the substrate 100. The semiconductor device may further include the first, second and third insulating interlayers 110, 130 and 190, respectively, and the first and second etch stop layers 120 and 180, respectively, on the substrate 100.

The via structure may include the first and second vias 252 and 254, respectively, which may be formed on the contact plug structure, the second insulating interlayer 130 and the first etch stop layer 120, and may penetrate through a lower portion of the third insulating interlayer 190, the second etch stop layer 180 and the second insulating interlayer 130.

As exemplarily illustrated, the first via 252 may contact top surfaces of the first contact plugs 172, and may partially penetrate through a portion of the second insulating interlayer 130 between the first contact plugs 172 to contact a top surface of the first etch stop layer 120. Accordingly, a bottom of the first via 252 may not have a constant height. For example, portions of the bottom of the first via 252 contacting the top surfaces of the first contact plugs 172 may be at a relatively high elevation, a portion of the bottom of the first via 252 contacting the top surface of the first etch stop layer 120 may be at a relatively low elevation, and portions of the bottom of the first via 252 on portions of the second insulating interlayer 130 adjacent to outer edges of the first contact plugs 172 may be at a relatively intermediate elevation.

Similarly to the first via 252, a bottom of the second via 254 may not have a constant height. For example, a portion of the bottom of the second via 254 contacting a top surface of the second contact plug 174 may be relatively higher than portions of the bottom of the second via 254 on portions of the second insulating interlayer 130 laterally adjacent to the second contact plug 174.

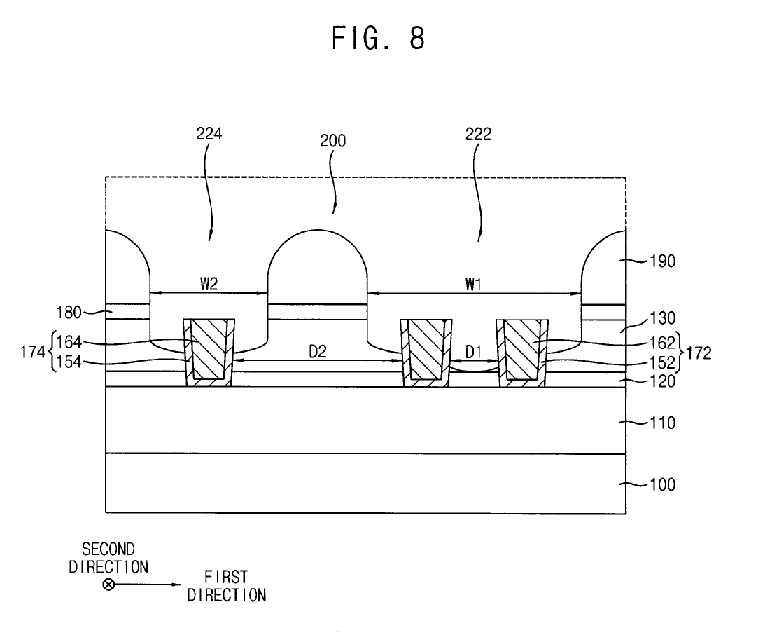

FIG. 8 is a cross-sectional view illustrating a stage of a method of manufacturing a semiconductor device in accordance with example embodiments. This method may include processes substantially the same as or similar to those described with reference to FIGS. 2 to 6 and FIG. 1, and thus detailed descriptions thereof are omitted herein.

First, processes substantially the same as or similar to those described with reference to FIGS. 2 to 5 may be performed. Thereafter, and with reference to FIG. 8, a process substantially the same as or similar to that described with reference to FIG. 6 may be performed to extend the trench 200 and the first and second via holes 222 and 224 downwardly. By the etching process, the top surfaces of the first and second contact plugs 172 and 174 and upper surfaces of portions of the second insulating interlayer 130 adjacent thereto may be exposed, and further a portion of the second insulating interlayer 130 including an insulating material may be also etched. Thus, portions of the second insulating interlayer 130 laterally adjacent to the first and second contact plugs 172 and 174 may be etched, and as a result, the first via hole 222 exposing the top surfaces of the first contact plugs 172 may be extended through a portion of the second insulating interlayer 130 between the first contact plugs 172 to expose the top surface of the first etch stop layer 120.

Thus, each of the first and second via holes 222 and 224 may not have a constant height, and a portion of the bottom of each of the first and second via holes 222 and 224 on the top surfaces of the first and second contact plugs 172 and 174, respectively, may be higher than portions of the bottom of each of the first and second via holes 222 and 224, located on the upper surfaces of the portions of the second insulating interlayer 130 laterally adjacent to the first and second contact plugs 172 and 174, respectively.

Referring back to FIG. 7, a process substantially the same as or similar to that described with reference to FIG. 1 may be performed to complete the semiconductor device.

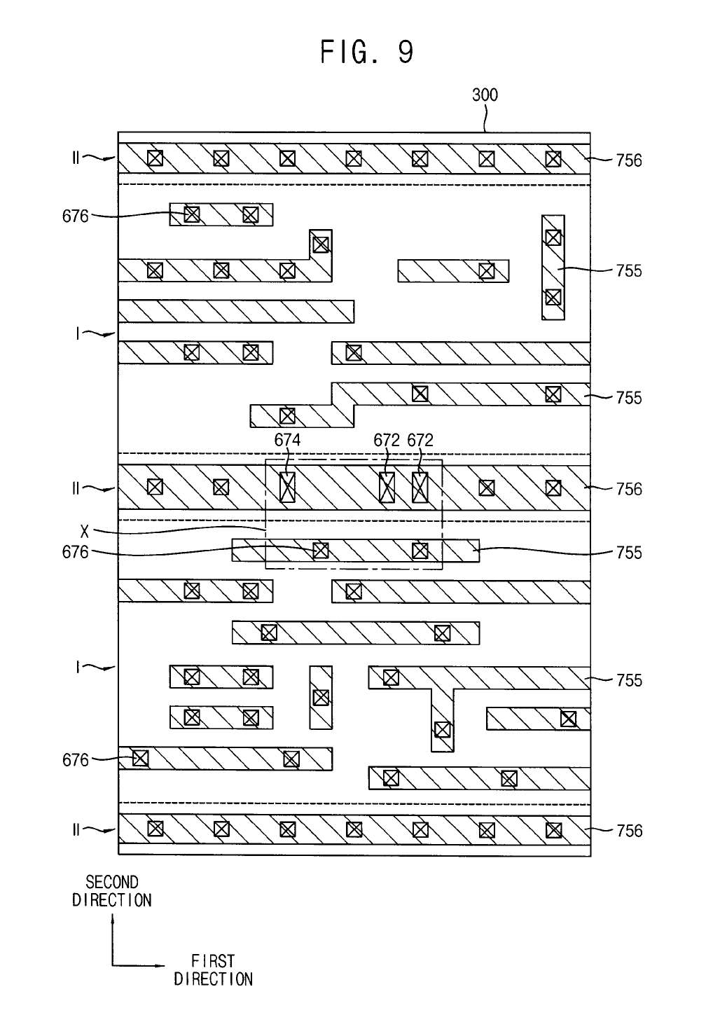

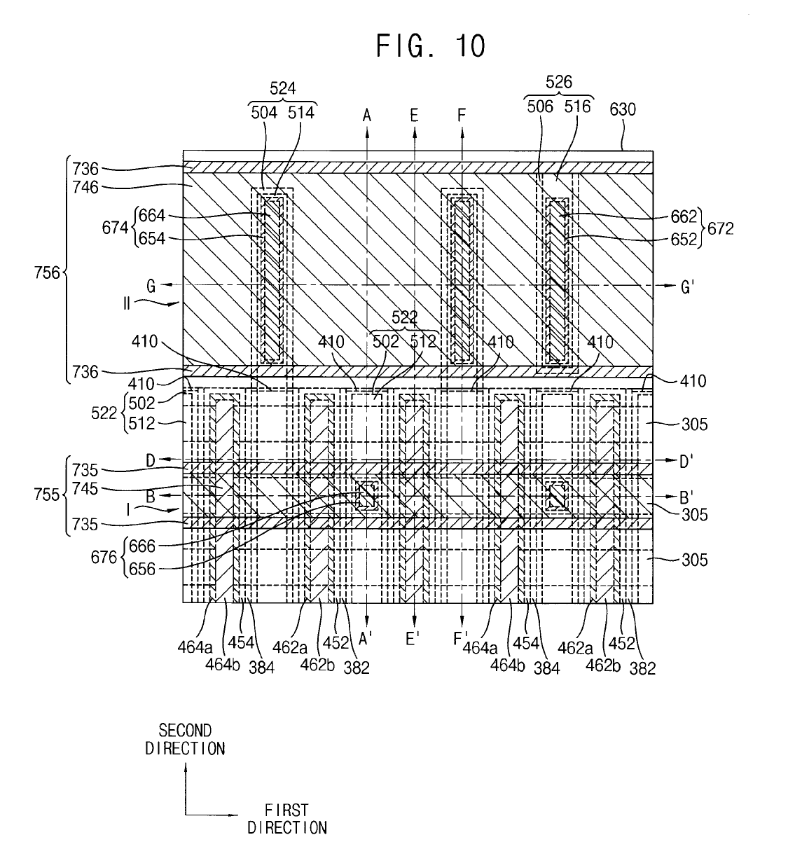

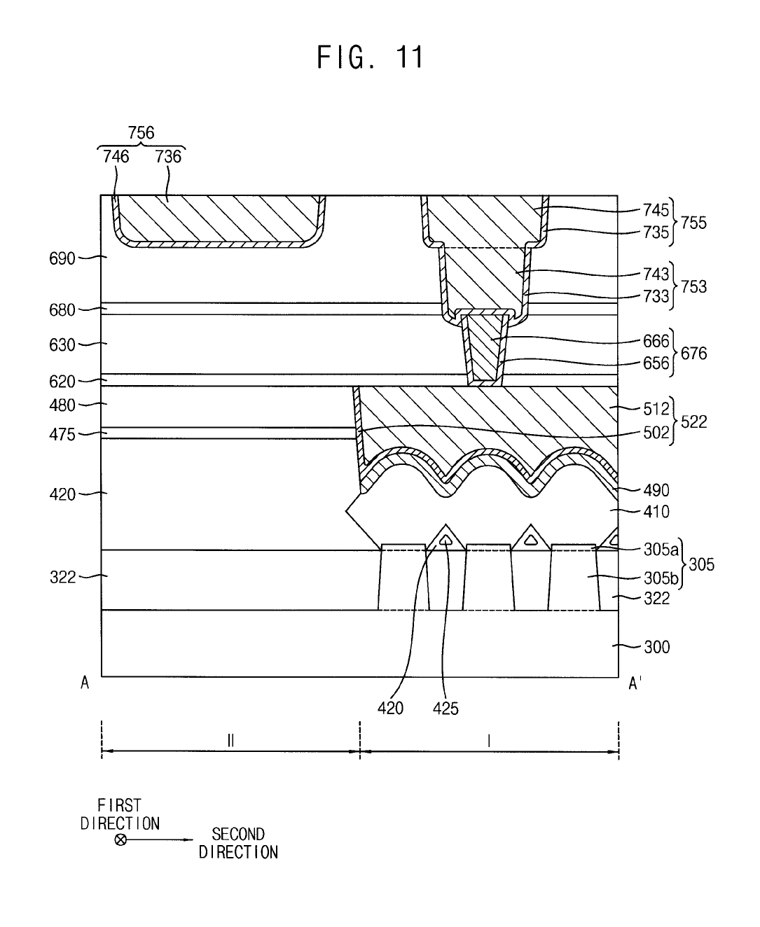

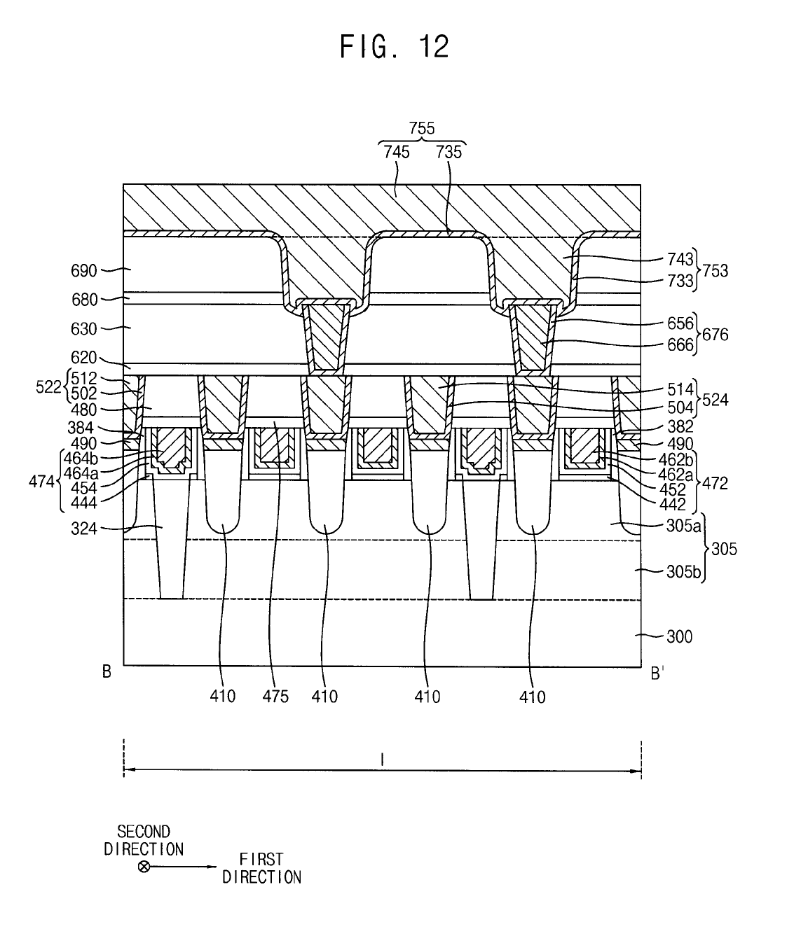

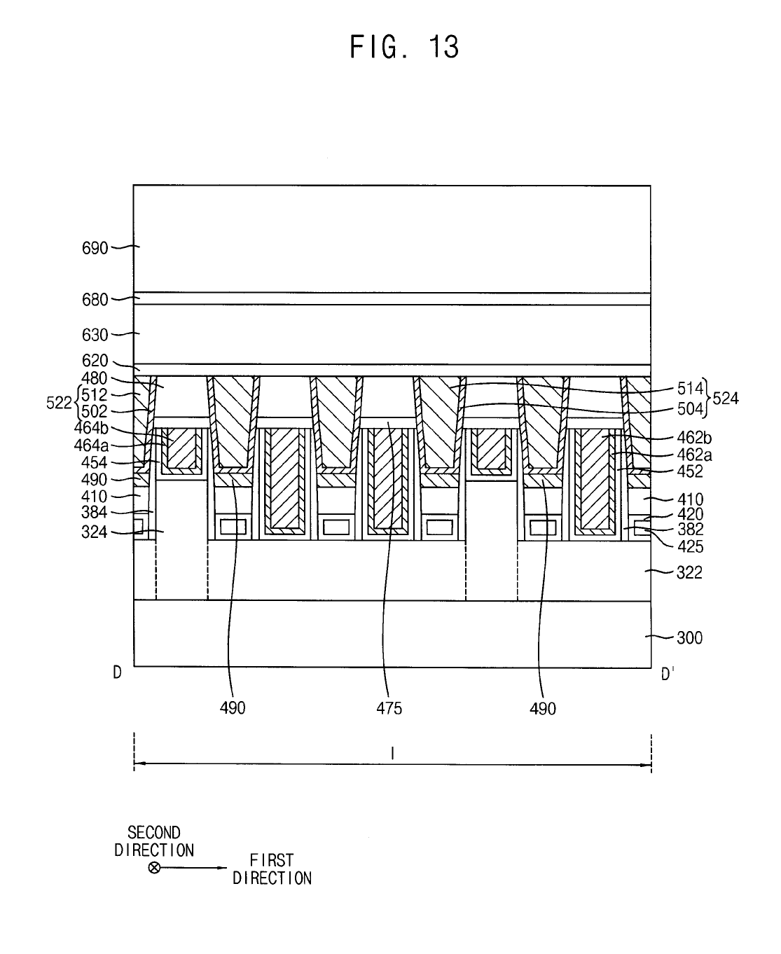

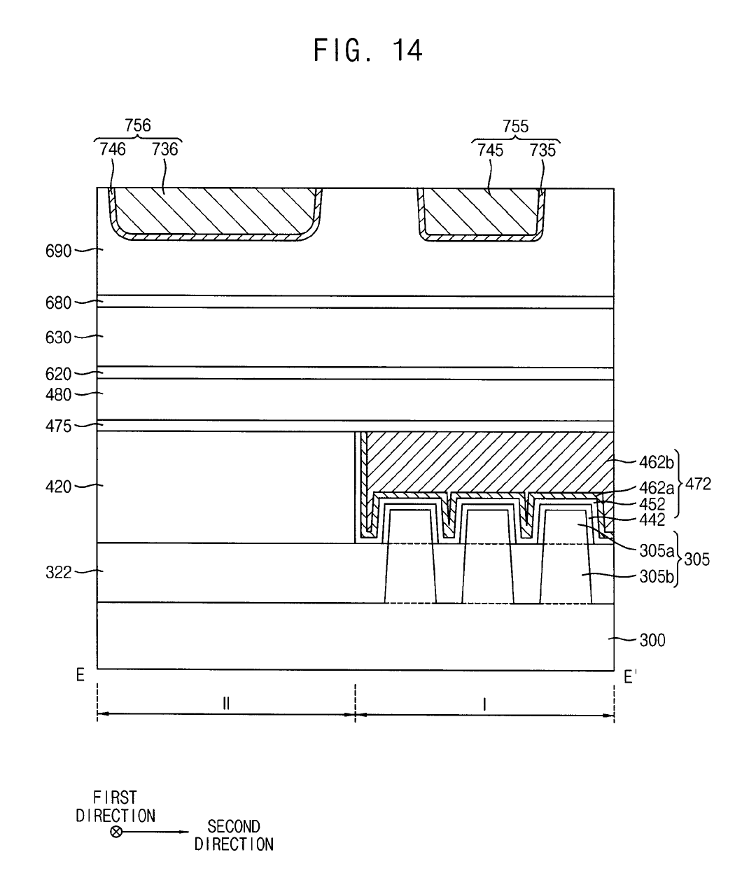

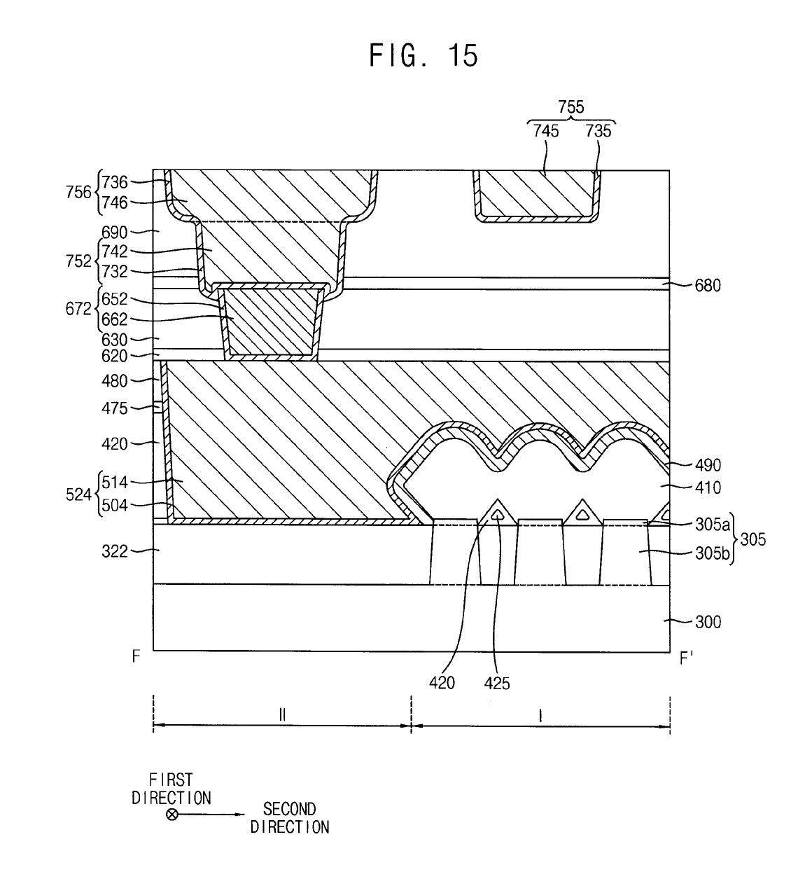

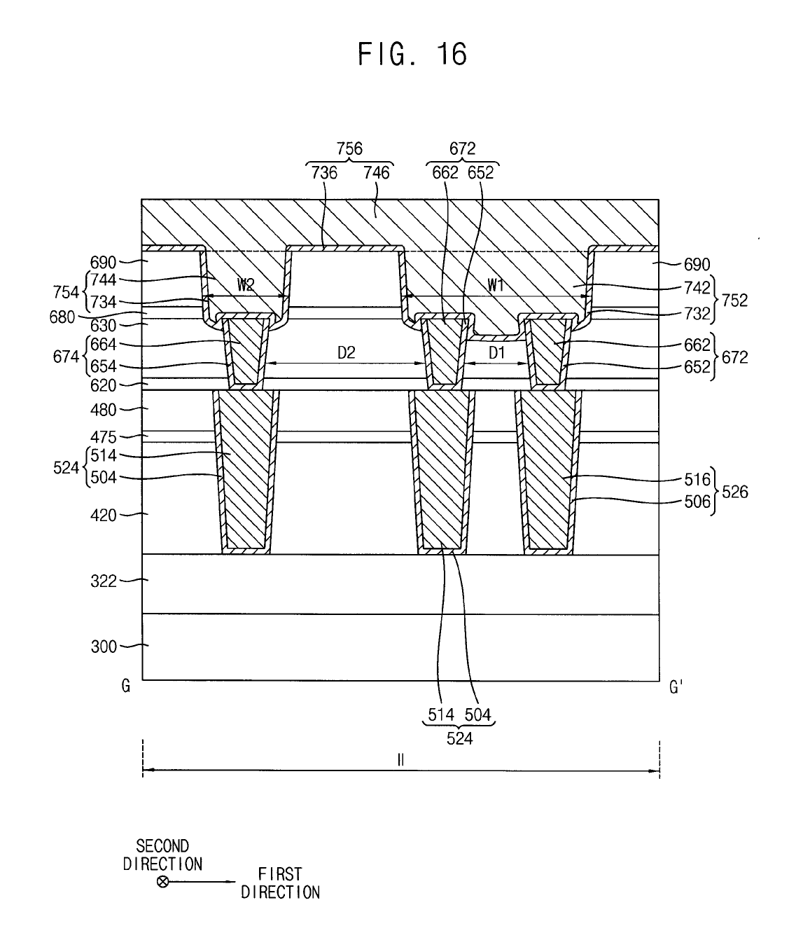

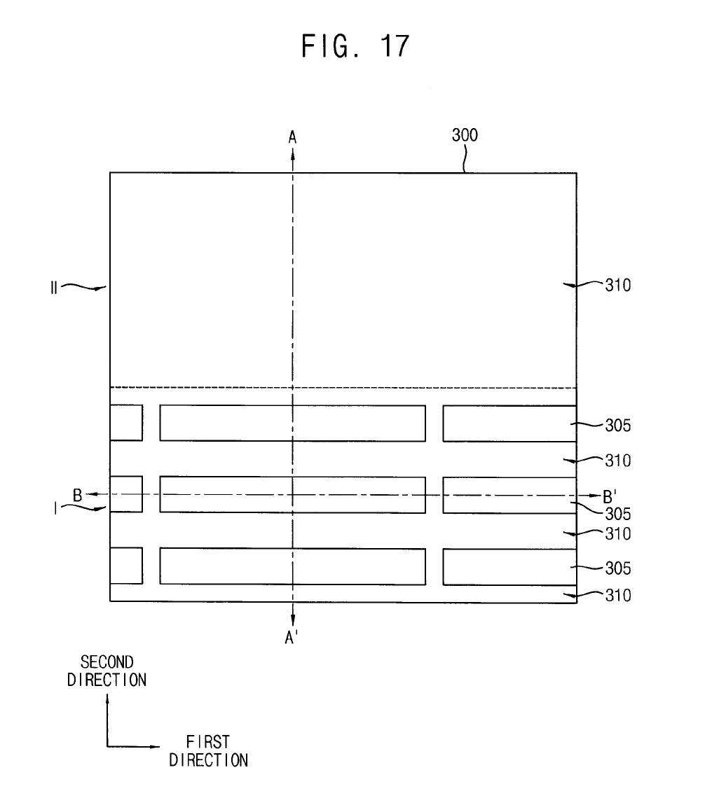

FIGS. 9 to 16 are plan views and cross-sectional views illustrating a semiconductor device in accordance with example embodiments. Particularly, FIGS. 9 and 10 are plan views of the semiconductor device, and FIGS. 11 to 16 are cross-sectional views of the semiconductor device. FIG. 10 is an enlarged plan view of a region X in FIG. 9, and FIG. 9 shows only contact plugs, wirings and power rails, in order to avoid undue complexity in describing the semiconductor device. FIG. 11 is a cross-sectional view taken along a line A-A′ shown in FIG. 10, FIG. 12 is a cross-sectional view taken along a line B-B′ shown in FIG. 10, FIG. 13 is a cross-sectional view taken along a line D-D′ shown in FIG. 10, FIG. 14 is a cross-sectional view taken along a line E-E′ shown in FIG. 10, FIG. 15 is a cross-sectional view taken along a line F-F′ shown in FIG. 10, and FIG. 16 is a cross-sectional view taken along a line G-G′ shown in FIG. 10.

Referring to FIG. 9, the semiconductor device may be formed on a substrate 300 having first and second regions I and II, respectively. In example embodiments, the first region I may be a cell region in which cells may be formed, and the second region II may be a power rail region in which a first wiring 756 serving as a power rail may be formed. Hereinafter, each of the first and second regions I and II may be defined as not only portions of the substrate 300 but also corresponding spaces above and/or beneath the portions of the substrate 300.

The first and second regions I and II may be alternately and repeatedly disposed in a second direction substantially parallel to a top surface of the substrate 300. Accordingly, the second region II may be disposed between ones of the first regions I adjacent to each other in the second direction, and the first wiring 756 in the second region II may provide a voltage, e.g., source voltage, drain voltage, ground voltage, etc., for the ones of the first regions I disposed at opposite sides of the second region II in the second direction. The first wiring 756 may be electrically connected to underlying first and second upper contact plugs 672 and 674. Additionally, a second wiring 755 may be formed in the second region II, and may be electrically connected to an underlying third upper contact plug 676.

Hereinafter, the semiconductor device and the method of manufacturing the same may be illustrated with reference to plan views and cross-sectional views for the region X, except for special cases.

Referring to FIGS. 9 to 16, the semiconductor device may include a transistor, a lower contact plug structure, an upper contact plug structure, a via structure, and a wiring structure on the substrate 300. The semiconductor device may further include an insulating interlayer structure, an etch stop layer structure, a spacer structure, and a metal silicide pattern 490 on the substrate 300.

The substrate 300 may include a semiconductor material, e.g., silicon, germanium, silicon-germanium, etc., or III-V semiconductor compounds, e.g., GaP, GaAs, GaSb, etc. In an example embodiment, the substrate 300 may be an SOI substrate, a GOI substrate, etc.

A plurality of active fins 305 may be formed on the substrate 300, e.g., so as to protrude therefrom. In example embodiments, each of the active fins 305 may extend in a first direction substantially parallel to the top surface of the substrate 300 and substantially perpendicular to the second direction, and the plurality of active fins 305 may be disposed both in the first and second directions. A region of the substrate 300 in which the active fins 305 are formed may be herein defined as an active region, and a region of the substrate 300 in which no active fin is formed may be herein defined as a field region.

First and second isolation patterns 322 and 324 may be formed on the substrate 300. The field region of the substrate 300 may be covered by the first and second isolation patterns 322 and 324, and the active region of the substrate 300 may not be covered by the first and second isolation patterns 322 and 324.

In example embodiments, each of the active fins 305 may include a lower active pattern 305b having a sidewall covered by the first isolation pattern 322, and an upper active pattern 305a protruding from a top surface of the first isolation pattern 322. In example embodiments, the upper active pattern 305a may have a width that is slightly smaller than a width of the lower active pattern 305b.

The second isolation pattern 324 may be formed between opposite ends of the active fins 305 in the first direction, and a top surface of the second isolation pattern 324 may be higher than that of the first isolation pattern 322. In example embodiments, the top surface of the second isolation pattern 324 may be substantially coplanar with top surfaces of the active fins 305. Alternatively, the top surface of the second isolation pattern 324 may be higher than those of the active fins 305.

The transistor may include first and second gate structures 472 and 474 and a source/drain layer 410. The space structure may include first and second gate spacers 382 and 384, respectively. Each of the first and second gate spacers 382 and 384 may be formed on opposite sidewalls of each of the first and second gate structures 472 and 474. The first and second gate spacers 382 and 384 may include a nitride, e.g., silicon nitride, silicon oxycarbonitride, etc.

The first gate structure 472 may include a first interface pattern 442, a first gate insulation pattern 452, a first workfunction control pattern 462a and a first gate electrode 462b sequentially stacked on the active fins 305 of the substrate 300 and portions of the first isolation patterns 322 adjacent thereto. Likewise, and the second gate structure 474 may include a second interface pattern 444, a second gate insulation pattern 454, a second workfunction control pattern 464a and a second gate electrode 464b sequentially stacked on the opposite ends of the active fins 305 of the substrate 300 in the first direction and portions of the second isolation patterns 324 therebetween.

The first interface pattern 442 may be formed on the active fin 305, the first gate insulation pattern 452 may be formed on the first interface pattern 442, the first isolation pattern 322 and an inner sidewall of the first gate spacer 382; the first workfunction control pattern 462a may be formed on the first gate insulation pattern 452; and a bottom and a sidewall of the first gate electrode 462b may be covered by the first workfunction control pattern 462a. The second interface pattern 444 may be formed on the opposite ends of the active fin 305; the second gate insulation pattern 454 may be formed on the second interface pattern 444, the second isolation pattern 324 and an inner sidewall of the second gate spacer 384; the second workfunction control pattern 464a may be formed on the second gate insulation pattern 454; and a bottom and a sidewall of the second gate electrode 462b may be covered by the second workfunction control pattern 464a.

Alternatively, the first and second interface patterns 442 and 444 may be formed not only on the active fin 305, but also on the first and second isolation patterns 322 and 324, respectively, and on the inner sidewalls of the first and second gate spacers 382 and 384, respectively.

The first and second interface patterns 442 and 444 may include an oxide, e.g., silicon oxide, the first and second gate insulation patterns 452 and 454 may include a metal oxide having a high dielectric constant, e.g., hafnium oxide, tantalum oxide, zirconium oxide, or the like, and the gate electrode 440 may include a material having a low resistance, e.g., a metal such as aluminum, copper, tantalum, etc., or a metal nitride thereof, the first and second workfunction control patterns 462a and 464a may include a metal nitride or a metal alloy, e.g., titanium nitride, titanium aluminum, titanium aluminum nitride, tantalum nitride, tantalum aluminum nitride, etc., and the first and second gate electrodes 462b and 464b may include a metal having a low resistance, e.g., aluminum, copper, tantalum, etc., or a nitride thereof.

In example embodiments, each of the first and second gate structures 472 and 474 may extend in the second direction in the first region I. A plurality of first gate structures 472 may be formed to be spaced apart from each other in the first direction, and a plurality of second gate structures 474 may be formed to be spaced apart from each other in the first direction.

Although the figures show that two first gate structures 472 are formed on a central portion of each of the active fins 305 and that two second gate structures 474 are formed on ends of each of the active fins 305, it will be appreciated that the inventive concepts are not limited thereto. That is, any number of first gate structures 472 may be formed on a central portion of each of the active fins 305. However, when lengths of the active fins 305 extending in the first direction are substantially the same, and a distance between ones of the first gate structures 472 in the first direction on each of the active fins 305 is constant, the number and order by which the first and second gate structures 472 and 474 are disposed in the first direction may be uniform. In the figures, two first gate structures 472 and one second gate structure 474 are alternately and repeatedly disposed in the first direction.

In example embodiments, the first gate structure 472 may have a thickness that varies in the second direction, and the second gate structure 474 may have a constant thickness in the second direction. Accordingly, top surfaces of the first and second gate structures 472 and 474 may be substantially coplanar with each other, a bottom of the first gate structure 472 may have a height that varies in the second direction, and a bottom of the second gate structure 474 may have a height that is constant in the second direction.

In example embodiments, a portion of the bottom of the first gate structure 472 on the active fin 305 may be lower than a portion of the bottom of the first gate structure 472 on the first isolation pattern 322, and a portion of the bottom of the second gate structure 474 on the active fin 305 may be substantially coplanar with a portion of the bottom of the second gate structure 474 on the second isolation pattern 324. In example embodiments, the bottom of the second gate structure 474 may be substantially coplanar with a top surface of the active fin 305. Alternatively, the bottom of the second gate structure 474 may be higher than the top surface of the active fin 305. In example embodiments, the first gate structure 472 may be an active gate (i.e., a gate which can be operated during operation of the semiconductor device), while the second gate structure 474 may be a dummy gate (i.e., a gate which is not operated during operation of the semiconductor device).

The source/drain layer 410 may be formed on portions of the active fins 305 adjacent to the first and second gate structures 472 and 474. In example embodiments, the source/drain layer 410 may be formed on a portion of the active fin 305 between the first and second gate structures 472 and 474 disposed in the first direction. The source/drain layer 410 may include, e.g., a single crystalline silicon carbide layer doped with n-type impurities, or a single crystalline silicon layer doped with n-type impurities. Thus, the source/drain layer 410 together with the first gate structure 472 may form a negative-channel metal oxide semiconductor (NMOS) transistor. Alternatively, the source/drain layer 410 may include, e.g., a single crystalline silicon-germanium layer doped with p-type impurities. Thus, the source/drain layer 410 together with the first gate structure 472 may form a positive-channel metal oxide semiconductor (PMOS) transistor.

The source/drain layer 410 may be grown by a selective epitaxial growth (SEG) process both in vertical and horizontal directions. Thus, the source/drain layer 410 may fill a recess (not shown) on the active fin 305, and may contact portions of the first and second gate spacers 382 and 384. A cross-section of the source/drain layer 410 may have a shape of pentagon or hexagon, and when neighboring ones of the active fins 305 in the second direction are spaced apart from each other by a small distance, the source/drain layers 410 growing on the neighboring ones of the active fins 305 in the second direction may be connected and merged with each other to form a single layer. In FIG. 15, one merged source/drain layer 410 grown from the neighboring ones of the active fins 305 in the second direction is shown.

The metal silicide pattern 490 may be formed on the source/drain layer 410. The metal silicide pattern 490 may include a metal silicide, e.g., cobalt silicide, nickel silicide, titanium silicide, etc. In some embodiments, the metal silicide pattern 490 may not be formed.

The insulating interlayer structure may include first, second, third and fourth insulating interlayers 420, 480, 630 and 690, respectively, which are sequentially stacked on the substrate 300, and the etch stop layer structure may include first and second etch stop layers 620 and 680, respectively, which are sequentially stacked on the substrate 300.

The first, second, third and fourth insulating interlayers 420, 480, 630 and 690 may include, e.g., silicon oxide. Alternatively, the third and fourth insulating interlayers 630 and 690 may include a low-k dielectric material (e.g., silicon oxide doped with carbon (SiCOH), silicon oxide doped with fluorine (F—SiO₂), etc.), a porous silicon oxide, a spin-on organic polymer, an inorganic polymer (e.g., hydrogen silsesquioxane (HSSQ), methyl silsesquioxane (MSSQ), etc.), or the like. The first, second, third and fourth insulating interlayers 420, 480, 630 and 690 may include substantially the same material or different materials.

The first and second etch stop layers 620 and 680 may include a nitride, e.g., silicon nitride, silicon carbonitride, silicon oxycarbonitride, etc. Alternatively, the first and second etch stop layers 620 and 680 may include an oxide, e.g., titanium oxide, tantalum oxide, zinc oxide, etc. The first and second etch stop layers 620 and 680 may include substantially the same material or different materials.

The first insulating interlayer 420 may be formed on the substrate 300, and may surround outer sidewalls of the first and second gate spacers 382 and 384 on sidewalls of the first and second gate structures 472 and 474, and cover the source/drain layer 410 and the metal silicide pattern 490 thereon. The second insulating interlayer 480 may be formed on the first insulating interlayer 420, the first and second gate structures 472 and 474, and the first gate spacers 382 and 384. The first insulating interlayer 420 may define an air gap 425 between the merged source/drain layer 410 and the first isolation pattern 322.

The lower contact plug structure may penetrate through the first and second insulating interlayers 420 and 480 and a capping layer 475 therebetween, and may contact the metal silicide pattern 490. The lower contact plug structure may include first, second and third lower contact plugs 522, 524 and 526, respectively.

In example embodiments, the first lower contact plug 522 may extend in the second direction in one of the first regions I, and may contact the metal silicide pattern 490 on the source/drain layer 410; and the second lower contact plug 524 may extend in the second direction in the one of the first regions I and the second region II, and may contact the metal silicide pattern 490 on the source/drain layer 410 and the first isolation pattern 322. The third lower contact plug 526 may extend in the second direction in the second region II and another one of the first regions I, which may be opposite to the aforementioned one of the first regions I in the second direction, and may contact the metal silicide pattern (not shown) on the source/drain layer (not shown).

In example embodiments, each of the first, second and third contact plugs 522, 524 and 526 may contact the outer sidewalls of the first and second gate spacers 382 and 384 on the sidewalls of the first and second gate structures 472 and 474, respectively.

The first lower contact plug 522 may include a first lower barrier pattern 502 and a first lower conductive pattern 512 sequentially stacked, the second lower contact plug 524 may include a second lower barrier pattern 504 and a second lower conductive pattern 514 sequentially stacked, and the third lower contact plug 526 may include a third lower barrier pattern 506 and a third lower conductive pattern 516 sequentially stacked. The first lower barrier pattern 502 may cover a bottom and a sidewall of the first lower conductive pattern 512, the second lower barrier pattern 504 may cover a bottom and a sidewall of the second lower conductive pattern 514, and the third lower barrier pattern 506 may cover a bottom and a sidewall of the third lower conductive pattern 516.

Each of the first, second and third lower barrier patterns 502, 504 and 506 may include a metal nitride, e.g., tantalum nitride, titanium nitride, etc., and/or a metal, e.g., tantalum, titanium, etc. Each of the first, second and third lower conductive patterns 512, 514 and 516 may include a metal, e.g., tungsten, copper, aluminum, etc. The first, second and third lower barrier patterns 502, 504 and 506 may include substantially the same material or different materials, and the first, second and third lower conductive patterns 512, 514 and 516 may include substantially the same material or different materials.

The first etch stop layer 620 and the third insulating interlayer 630 may be sequentially stacked on the second insulating interlayer 480 and the lower contact plug structure.

The upper contact plug structure may penetrate through the first etch stop layer 620 and the third insulating interlayer 630, and may contact the lower contact plug structure. The upper contact plug structure may include first, second and third upper contact plugs 672, 674 and 676, respectively.

Each of the first and second upper contact plugs 672 and 674 may be formed in the second region II, and may contact the second lower contact plug 524 or the third lower contact plug 526. The third upper contact plug 676 may be formed in the first region I, and may contact the first lower contact plug 522. Although the figures show two first upper contact plugs 672 contacting the second and third lower contact plugs 524 and 526, respectively, and one second upper contact plug 674 contacting one second lower contact plug 524, it will be appreciated that the inventive concepts are not limited thereto. For example, each of the first upper contact plugs 672 may be formed on the second contact plug 524 or the third lower contact plug 526 in the second region II. Alternatively, the first upper contact plugs 672 may be formed on the second and third lower contact plugs 524 and 526, respectively, in the second region II. The second upper contact plug 674 may be formed on the third lower contact plug 526 in the second region II, or a plurality of second upper contact plugs 674 may be formed on some or all of the second and third lower contact plugs 524 and 526 in the second region II. However, in the second region II, at least one of the first and second upper contact plugs 672 and 674 may be formed on the second lower contact plug 524, and at least one of the first and second upper contact plugs 672 and 674 may be formed on the third lower contact plug 526.

In example embodiments, the first upper contact plugs 672 may be spaced apart from each other in the first direction by a first distance D1, and the second upper contact plug 674 may be spaced apart from the nearest one of the first upper contact plugs 672 thereto in the first direction by a second distance D2, which is greater than the first distance D1. The plurality of second upper contact plugs 674 may be spaced apart from each other in the first direction by a distance that may be greater than the first distance D1.

The first upper contact plug 672 may include a first upper barrier pattern 652 and a first upper conductive pattern 662 sequentially stacked, the second upper contact plug 674 may include a second upper barrier pattern 654 and a second upper conductive pattern 664 sequentially stacked, and the third upper contact plug 676 may include a third upper barrier pattern 656 and a third upper conductive pattern 666 sequentially stacked. The first upper barrier pattern 652 may cover a bottom and a sidewall of the first upper conductive pattern 662, the second upper barrier pattern 654 may cover a bottom and a sidewall of the second upper conductive pattern 664, and the third upper barrier pattern 656 may cover a bottom and a sidewall of the third upper conductive pattern 666.

Each of the first, second and third upper barrier patterns 652, 654 and 656 may include a metal nitride, e.g., tantalum nitride, titanium nitride, etc., and/or a metal, e.g., tantalum, titanium, etc. Each of the first, second and third upper conductive patterns 662, 664 and 666 may include a metal, e.g., tungsten, copper, aluminum, etc. The first, second and third upper barrier patterns 652, 654 and 656 may include substantially the same material or different materials, and the first, second and third upper conductive patterns 662, 664 and 666 may include substantially the same material or different materials.

The second etch stop layer 680 and the fourth insulating interlayer 690 may be sequentially stacked on the third insulating interlayer 630 and the upper contact plug structure.

The via structure and the wiring structure may penetrate through the second etch stop layer 680 and the fourth insulating interlayer 690, and may contact the upper contact plug structure. The via structure may include first, second and third vias 752, 754 and 753, respectively, and the wiring structure may include first and second wirings 756 and 755, respectively.

The first via 752 may contact top surfaces of the first upper contact plugs 672 and an upper surface of a portion of the third insulating interlayer 630 therebetween, and may further contact upper surfaces of portions of the third insulating interlayer 630 adjacent to outer edges of the first upper contact plugs 672. The second via 754 may contact a top surface of the second upper contact plug 674 and an upper surface of a portion of the third insulating interlayer 630 adjacent to the second upper contact plug 674. The third via 753 may contact a top surface of the third upper contact plug 676 and an upper surface of a portion of the third insulating interlayer 630 adjacent to the third upper contact plug 676.

When a plurality of second upper contact plugs 674 is formed, a plurality of second vias 754 may be formed on the plurality of second upper contact plugs 674, respectively. The first via 752 may commonly contact top surfaces of the plurality of first upper contact plugs 672. However, the second via 754 may not commonly contact top surfaces of the plurality of second upper contact plugs 674. Rather, each second via 754 of the plurality of second vias 754 may contact a respective top surface of an individual one of the plurality of second contact plugs 674. In example embodiments, the first via 752 may have a first width W1 in the first direction that is greater than a second width W2 of the second via 754 in the first direction.

A bottom of each of the first, second and third vias 752, 754 and 753 may not have a constant height, and a portion of the bottom of each of the first, second and third vias 752, 754 and 753 contacting top surfaces of the first, second and third contact plugs 672, 674 and 676, respectively, may be higher than a portion of the bottom of each of the first, second and third vias 752, 754 and 753 contacting upper surfaces of portions of the third insulating interlayer 630 laterally adjacent to the first, second and third contact plugs 672, 674 and 676, respectively.

The first wiring 756 may penetrate through an upper portion of the fourth insulating interlayer 690 in the second region II, and may be connected to and integrally formed with the first and second vias 752 and 754. The first wiring 756 and the first and second vias 752 and 754 may include substantially the same material, and a bottom of the first wiring 756 may commonly contact top surfaces of the first and second vias 752 and 754. In example embodiments, the first wiring 756 may extend in the first direction.

The second wiring 755 may penetrate through an upper portion of the fourth insulating interlayer 690 in the first region I, and may be connected to and integrally formed with the third via 753. The second wiring 755 and the third via 753 may include substantially the same material, and a bottom of the second wiring 756 may contact a top surface of the third via 753. In example embodiments, the second wiring 755 may extend in the first direction or in the second direction, or may have various other shapes.

In example embodiments, the first wiring 756 may serve as a power rail that may provide a voltage, e.g., source voltage, drain voltage, ground voltage, etc., for cells in the first region I. Accordingly, a voltage provided by the first wiring 756 may be applied to the first and second upper contact plugs 672 and 674 through the first and second vias 752 and 754, and may be applied to the source/drain layers 410 in the first regions I through the second and third lower contact plugs 524 and 526.

The first via 752 may include a fourth upper barrier pattern 732 and a fourth upper conductive pattern 742 sequentially stacked, the second via 754 may include a fifth upper barrier pattern 734 and a fifth upper conductive pattern 744 sequentially stacked, and the third via 753 may include a sixth upper barrier pattern 733 and a sixth upper conductive pattern 743 sequentially stacked. The fourth upper barrier pattern 732 may cover a bottom and a sidewall of the fourth upper conductive pattern 742, the fifth upper barrier pattern 734 may cover a bottom and a sidewall of the fifth upper conductive pattern 744, and the sixth upper barrier pattern 736 may cover a bottom and a sidewall of the sixth upper conductive pattern 746.

The first wiring 756 may include a seventh upper barrier pattern 736 and a seventh upper conductive pattern 746 sequentially stacked, the second wiring 755 may include an eighth upper barrier pattern 735 and an eighth upper conductive pattern 745 sequentially stacked. The seventh upper barrier pattern 736 may cover a portion of a bottom and a sidewall of the seventh upper conductive pattern 746, and the eighth upper barrier pattern 735 may cover a portion of a bottom and a sidewall of the eighth upper conductive pattern 745.

Each of the fourth, fifth, sixth, seventh and eighth barrier patterns 732, 734, 733, 736 and 735 may include a metal nitride, e.g., tantalum nitride, titanium nitride, etc., and/or a metal, e.g., tantalum, titanium, etc., and the fourth, fifth, sixth, seventh and eighth conductive patterns 742, 744, 743, 746 and 745 may include a metal, e.g., copper, aluminum, tungsten, etc. In example embodiments, the fourth, fifth, sixth, seventh and eighth barrier patterns 732, 734, 733, 736 and 735 may include substantially the same material, and the fourth, fifth, sixth, seventh and eighth conductive patterns 742, 744, 743, 746 and 745 may include substantially the same material.

As illustrated above, in the semiconductor device, the second region II, in which the power rail may be formed, may be disposed between the first regions I, in which the cells may be formed. Various voltages provided by the first wiring 756 in the second region II may be applied to the second and third lower contact plugs 524 and 526, commonly formed in the first and second regions I and II, through the first and second vias 752 and 754 and the first and second upper contact plugs 672 and 674 in the second region II, which may be applied to the source/drain layers 410 in each of the first regions I. One first via 752 may be formed to commonly contact the first upper contact plugs 672, which may be spaced apart from each other by a relatively short distance, instead of a plurality of first vias 752 contacting the plurality of first upper contact plugs 672, respectively. Thus, the first via 752 may be exactly formed even with an additional etching mask, and the semiconductor device the first via 752 may have enhanced characteristics.

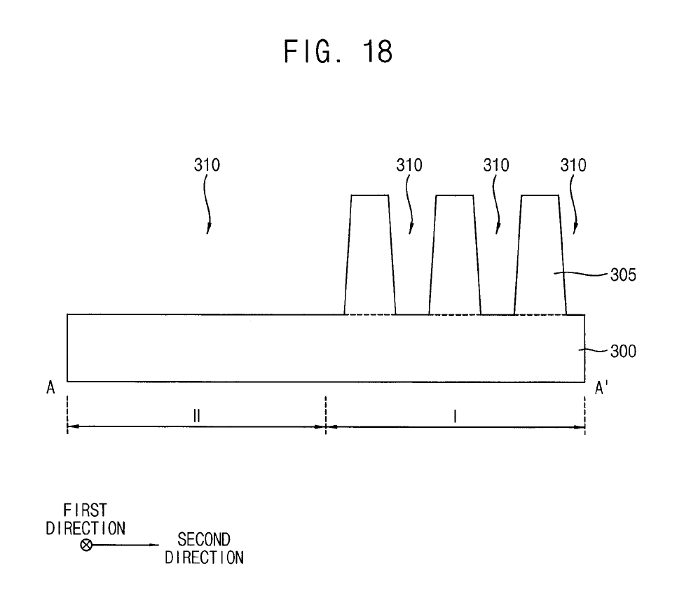

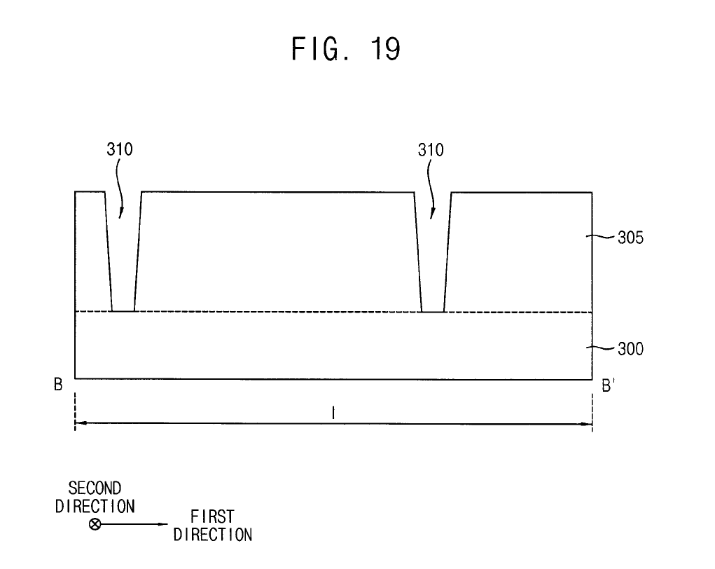

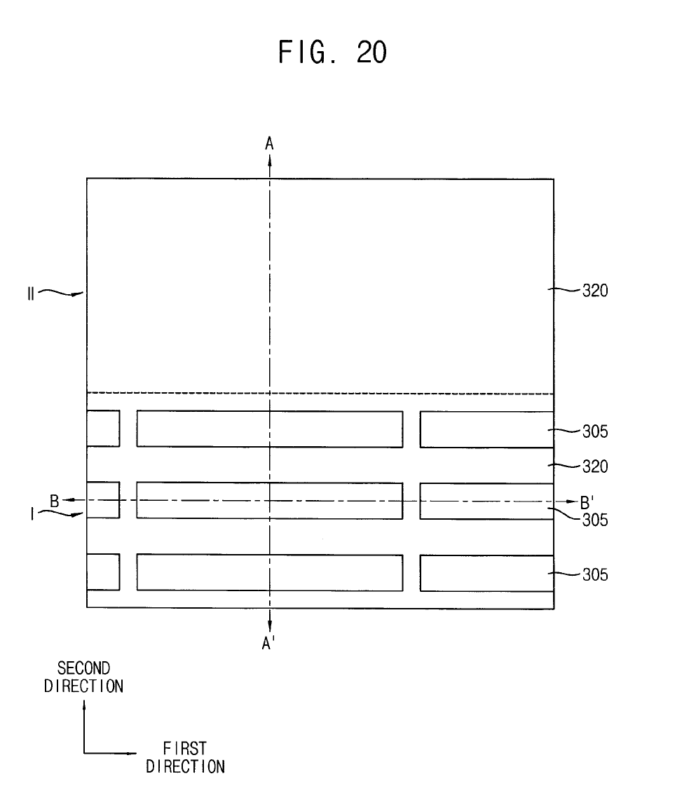

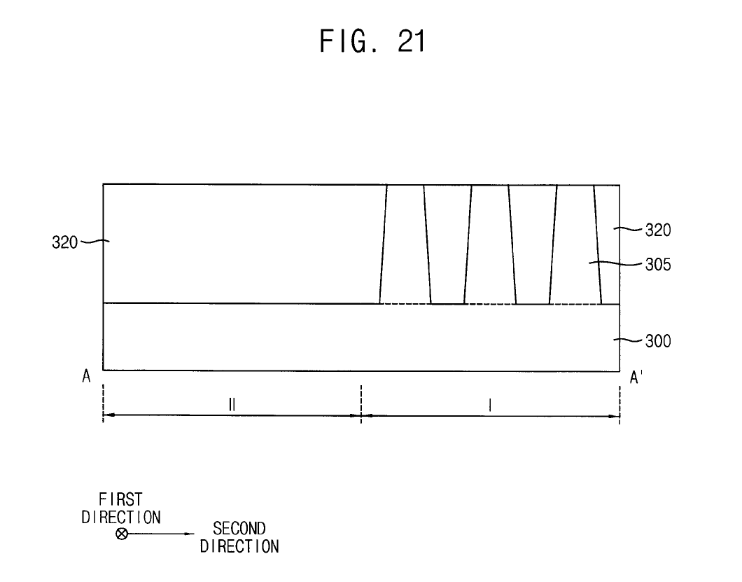

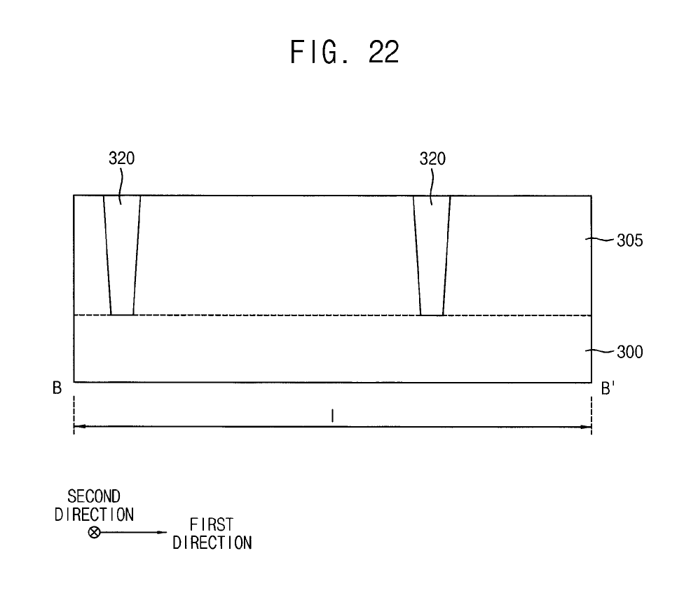

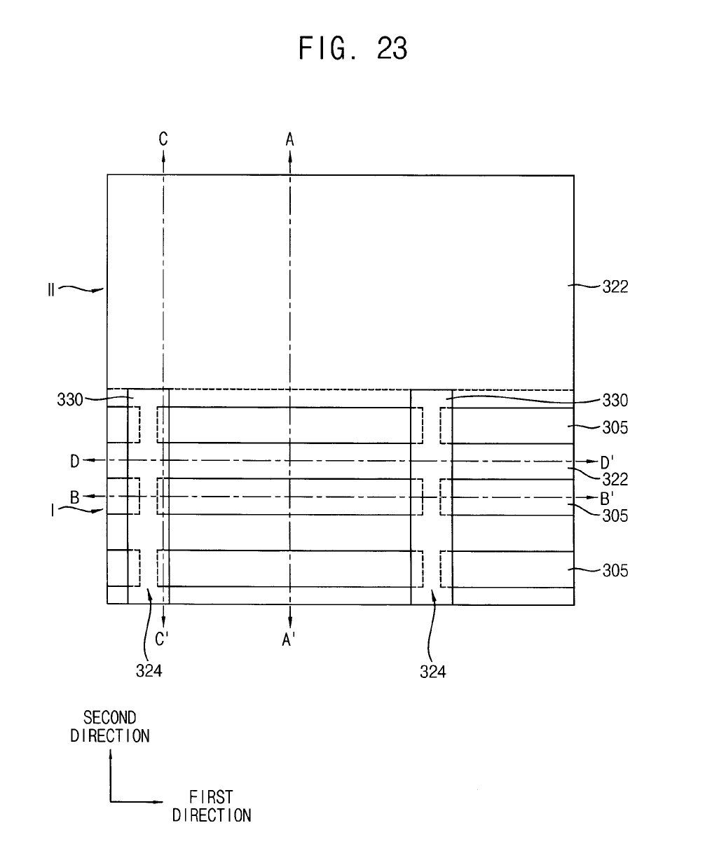

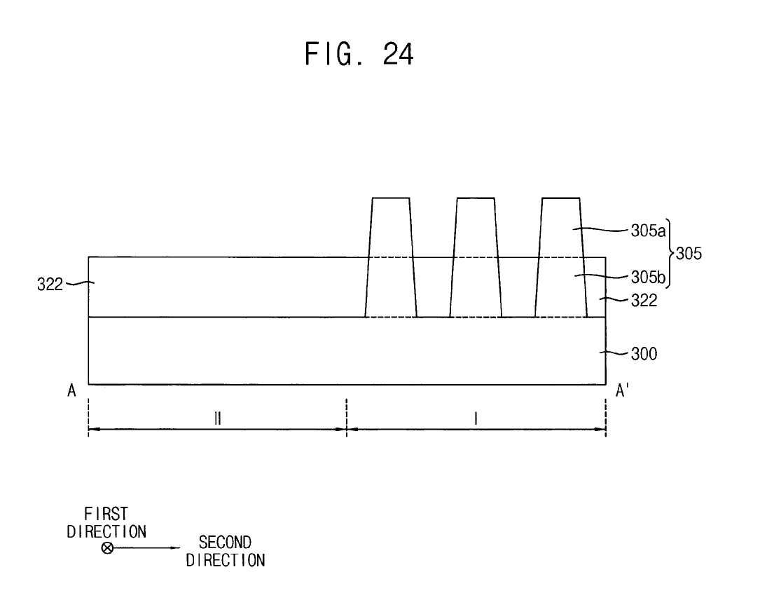

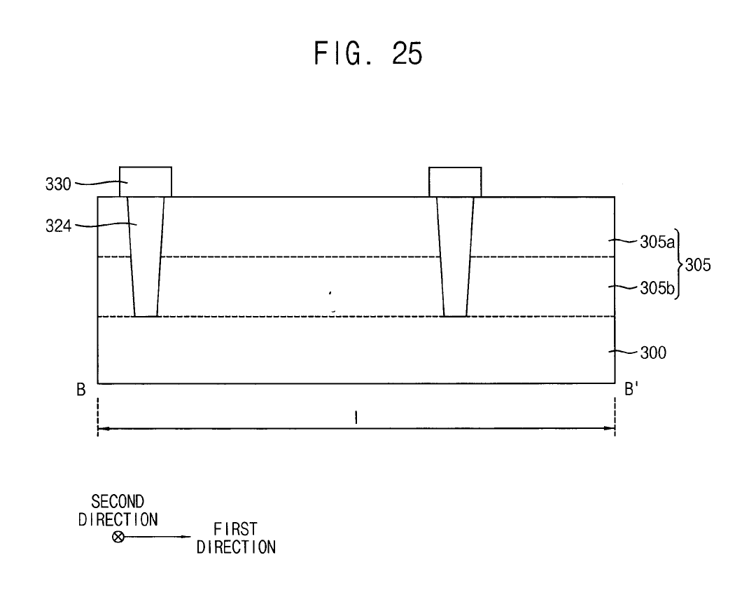

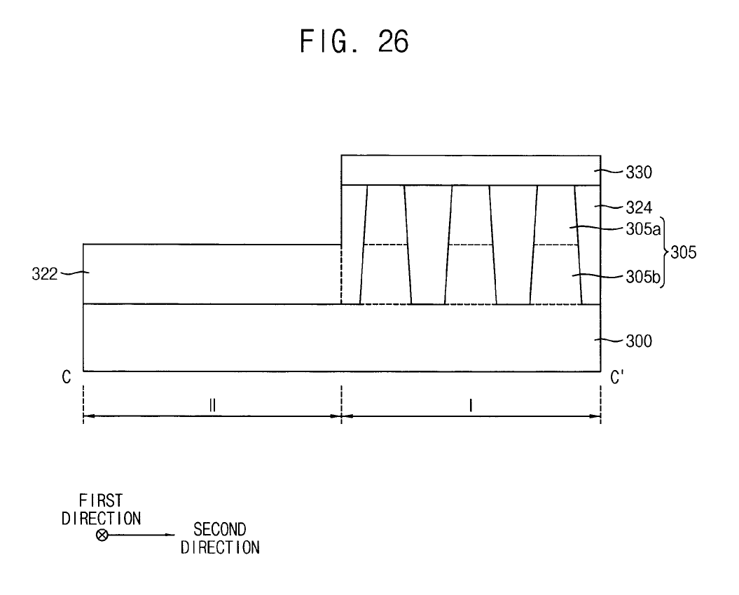

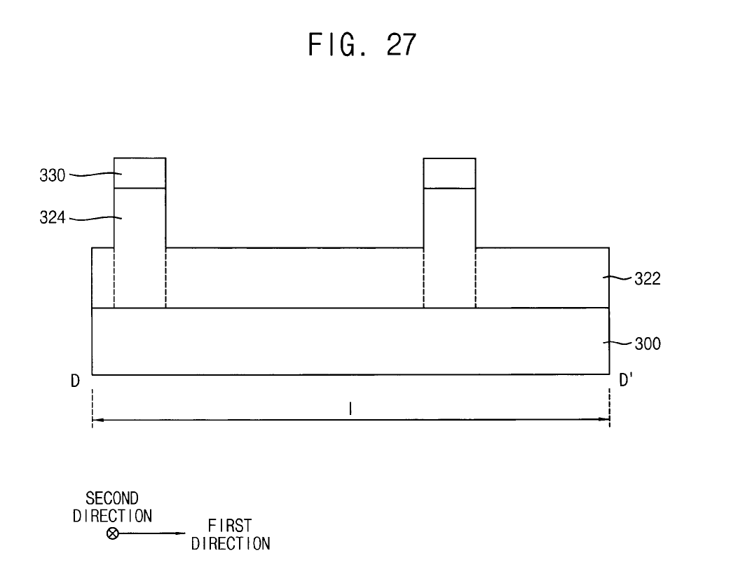

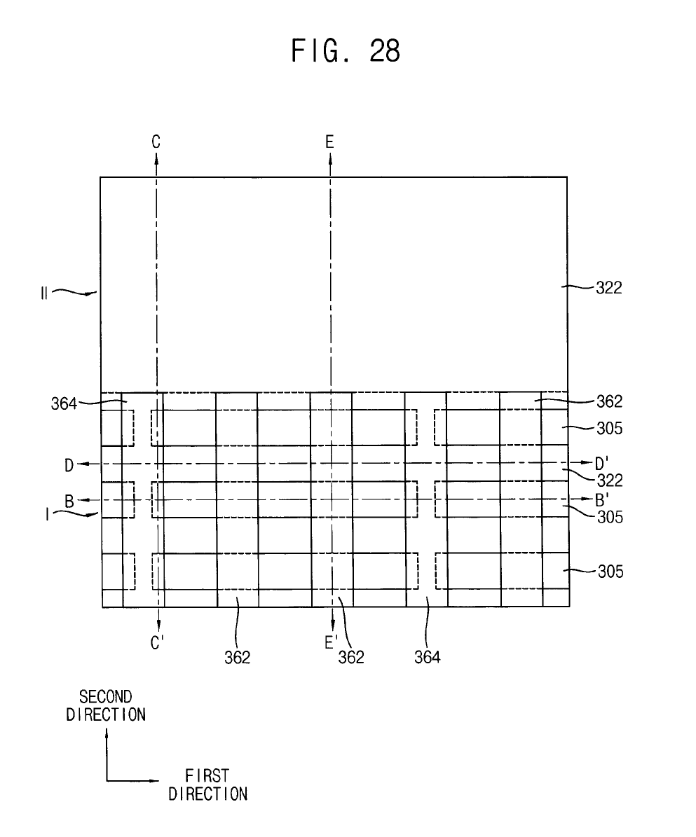

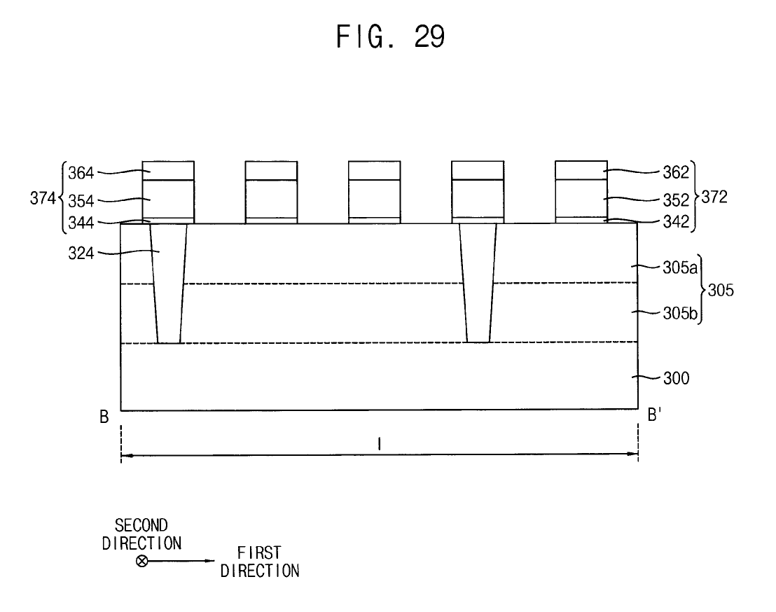

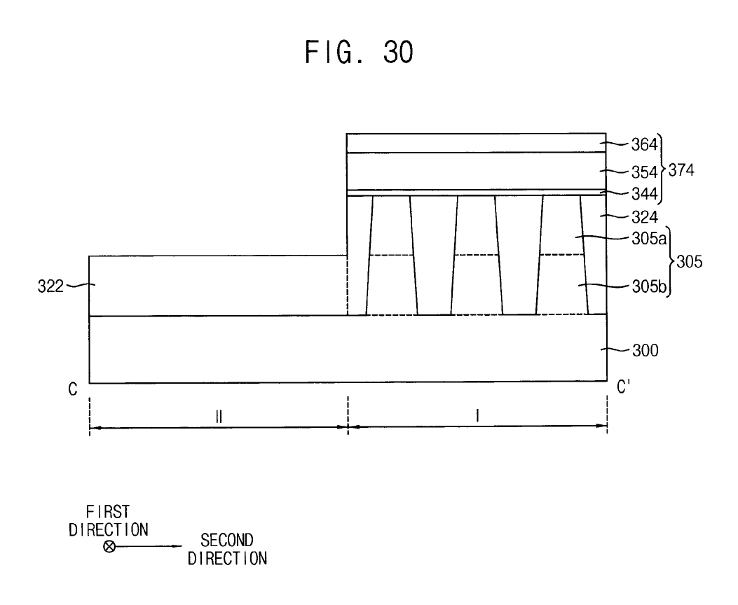

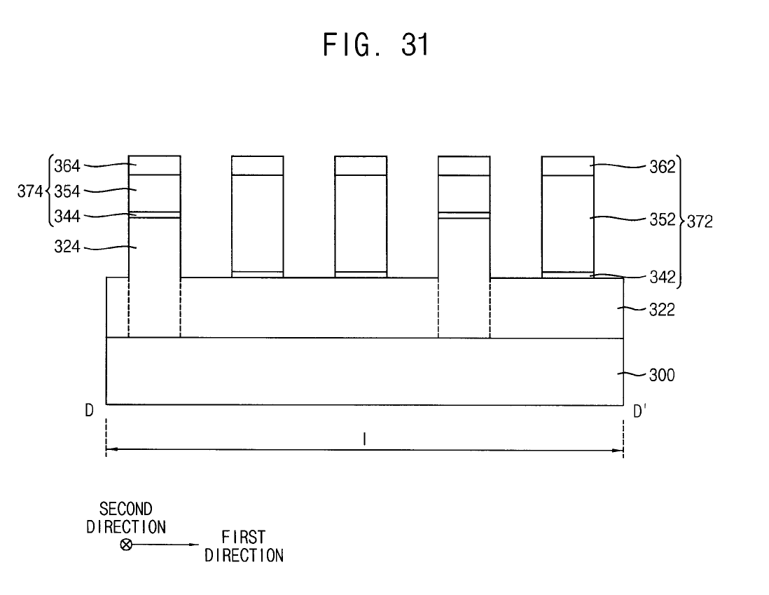

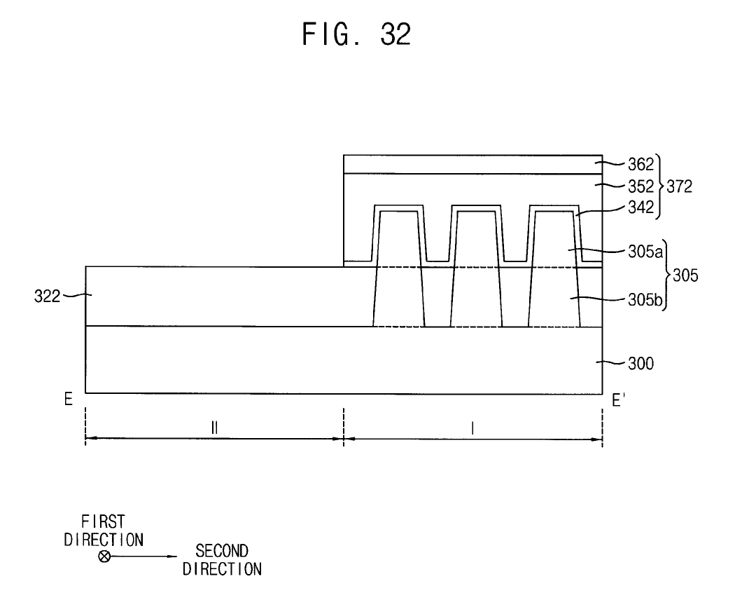

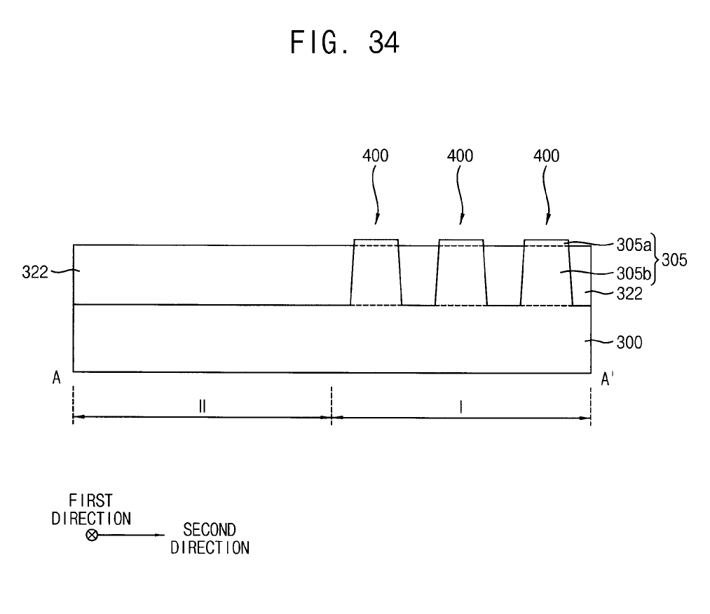

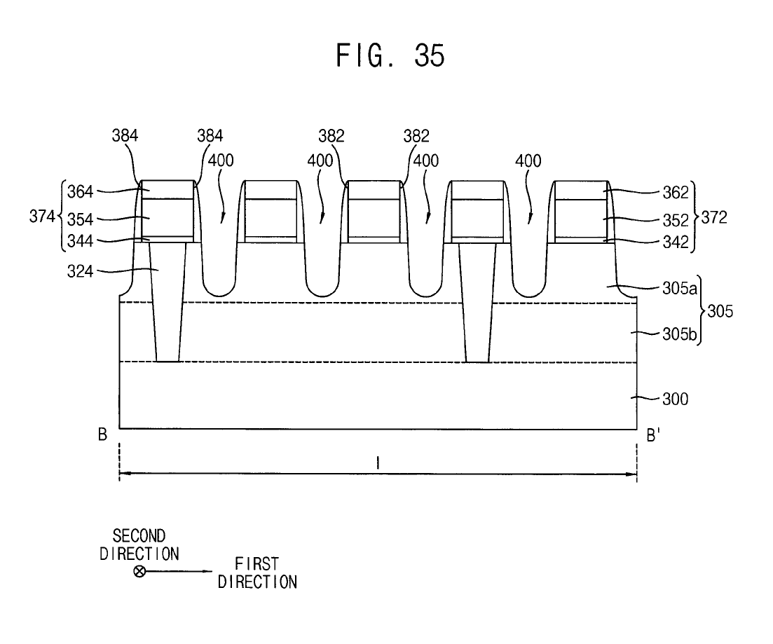

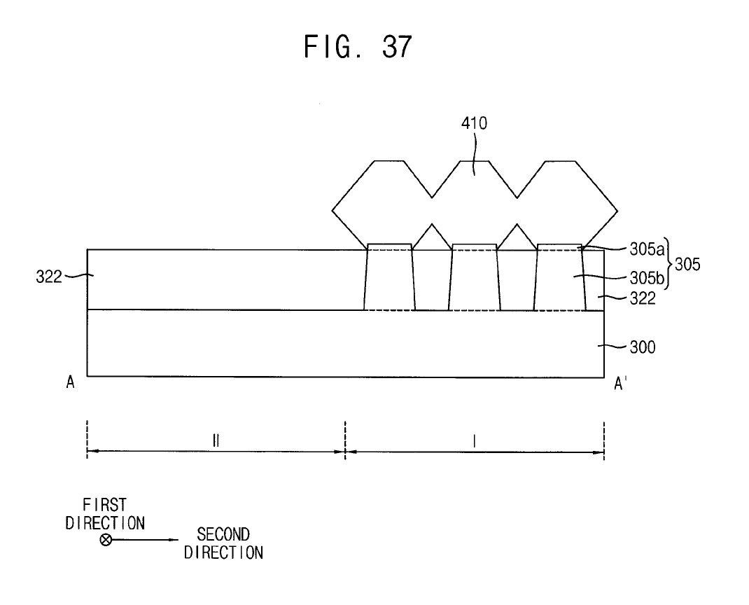

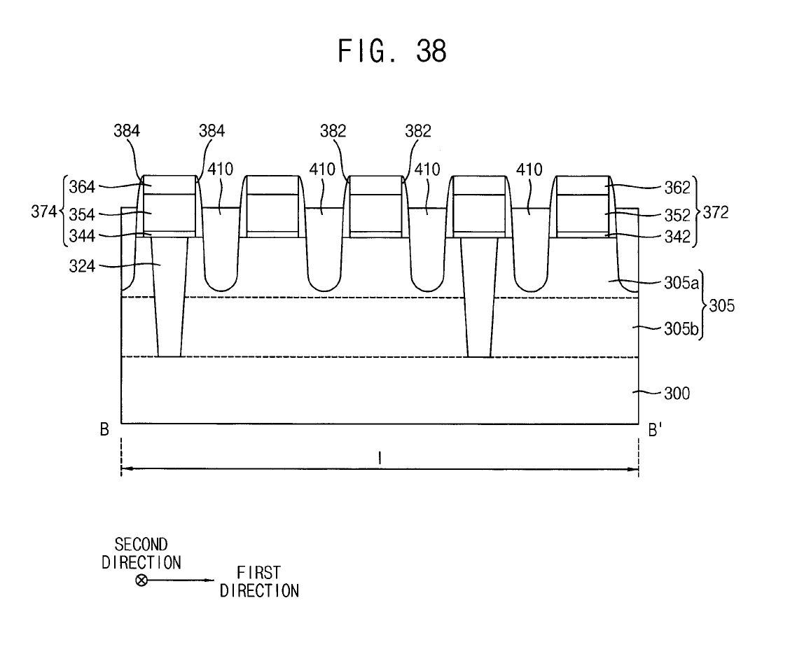

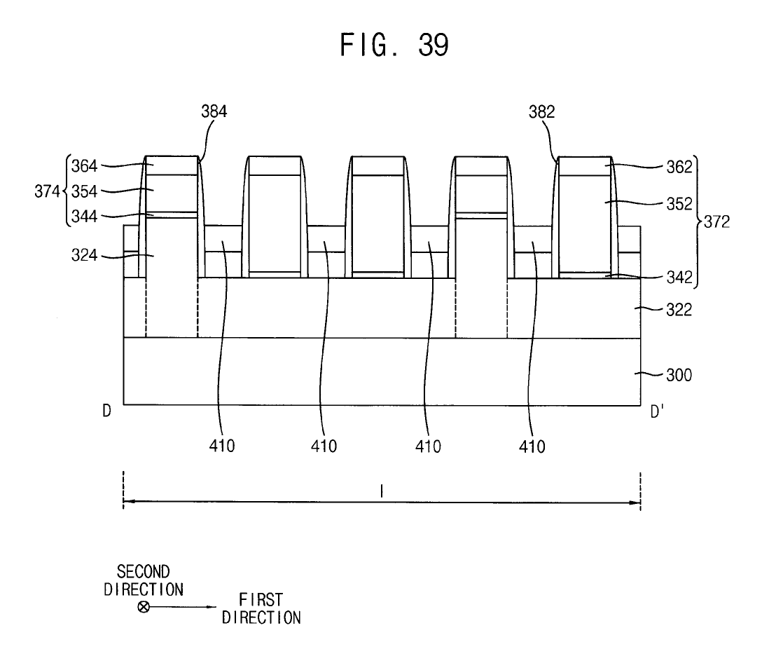

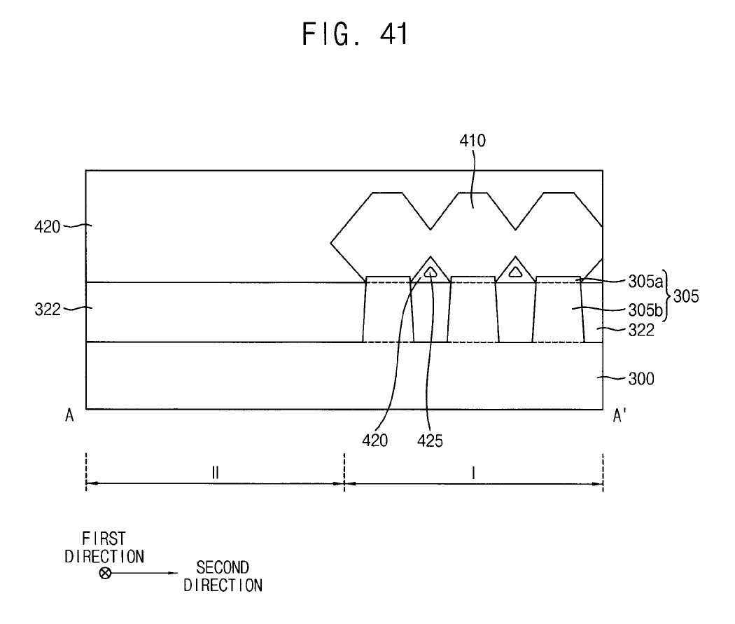

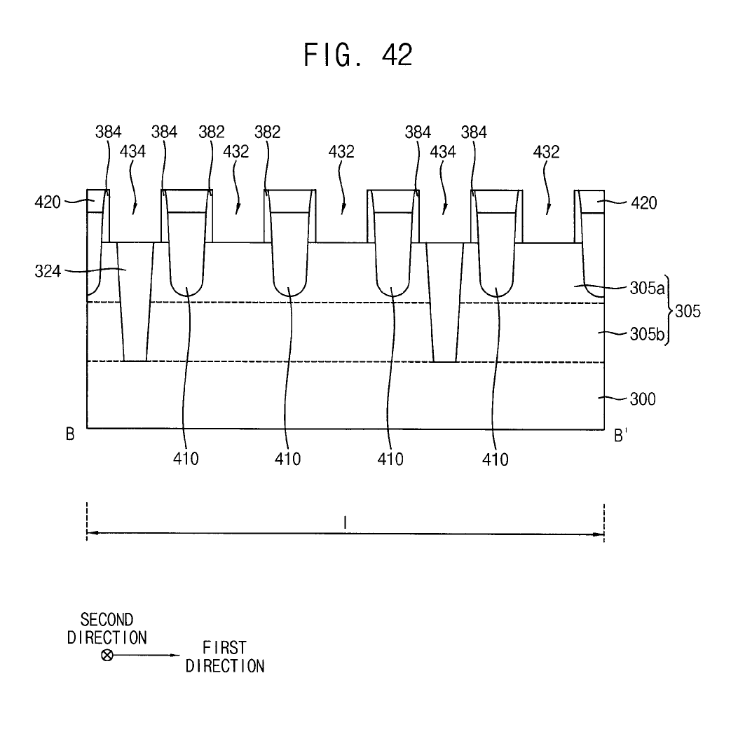

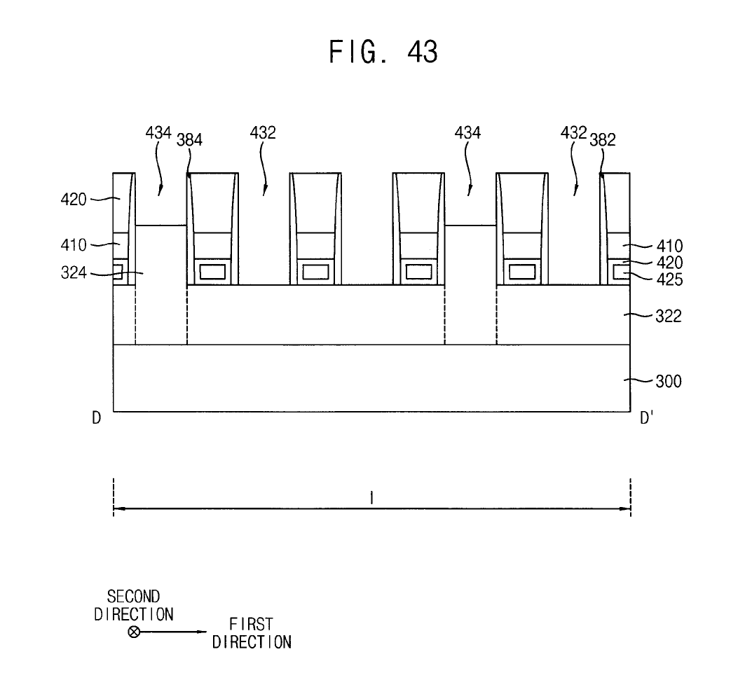

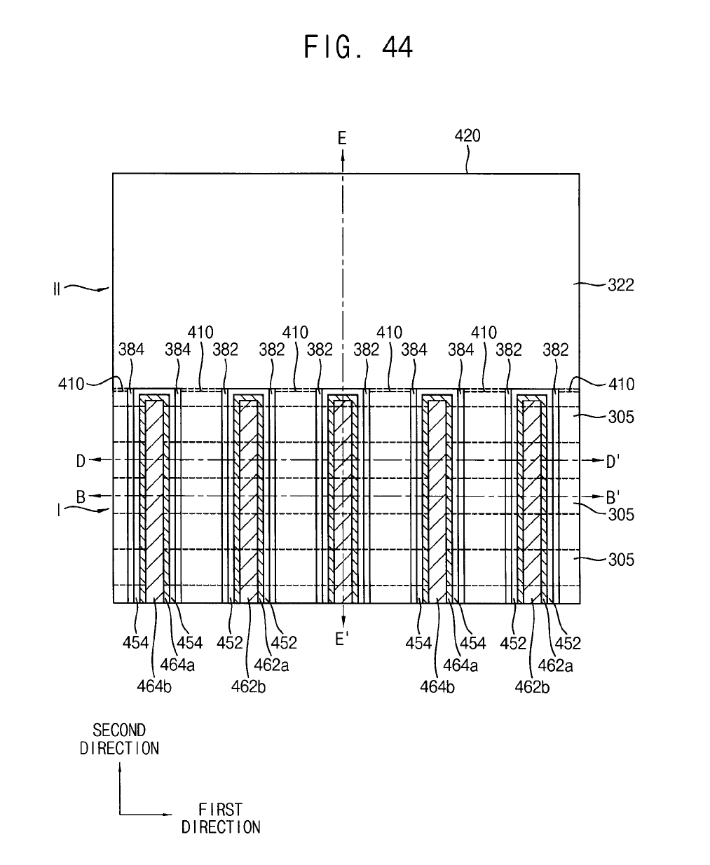

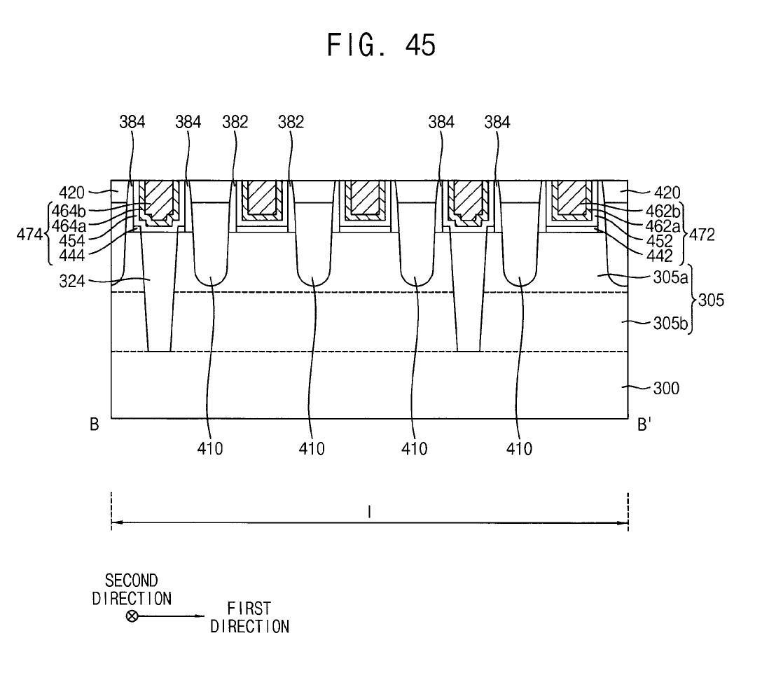

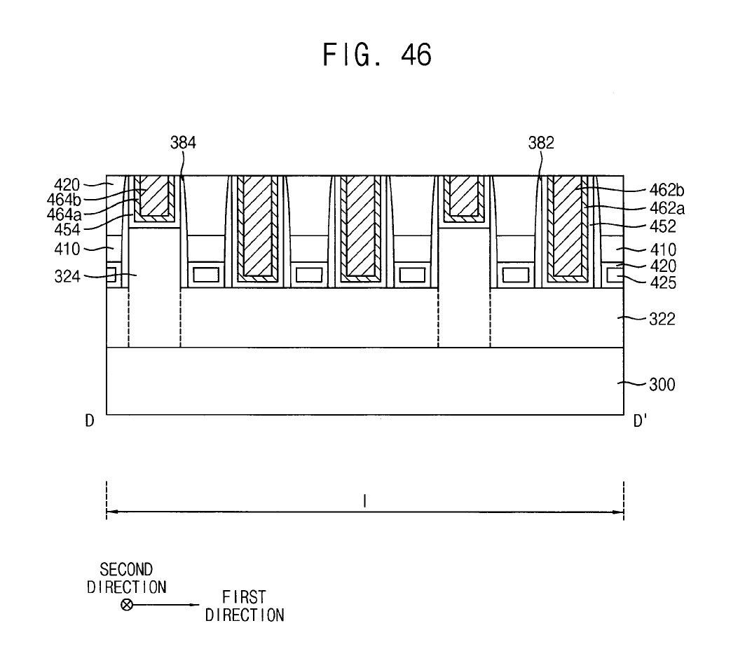

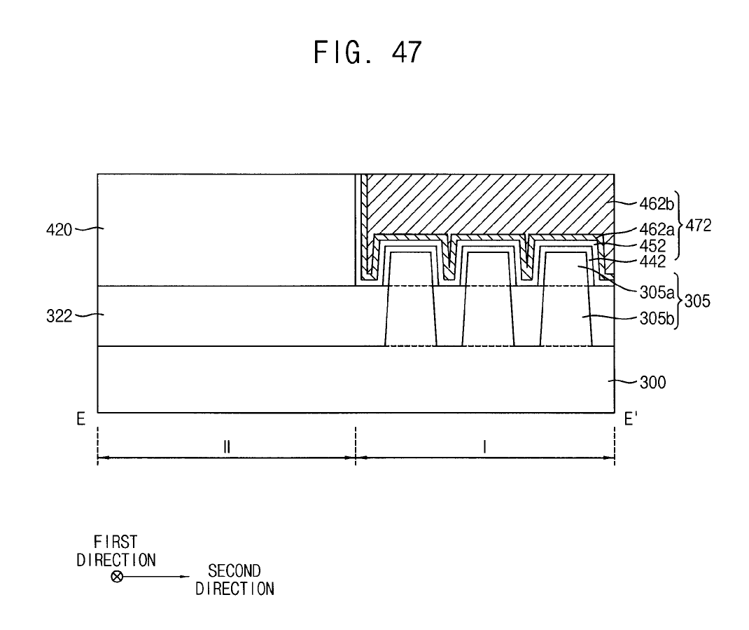

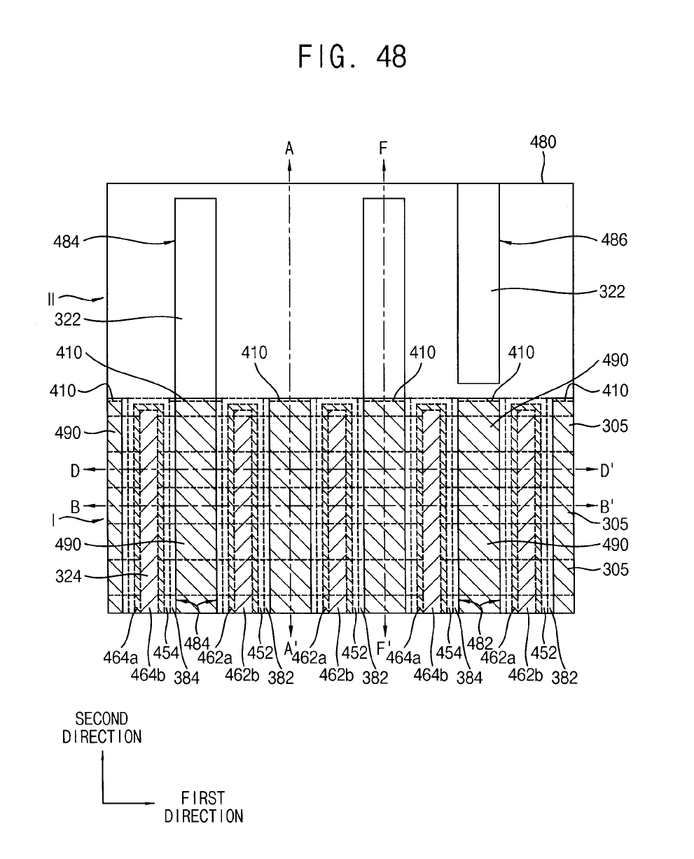

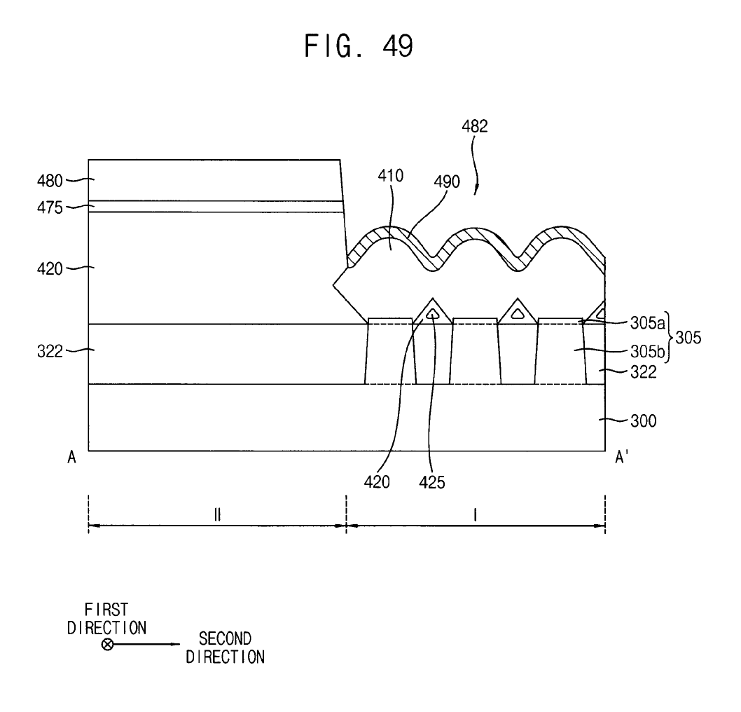

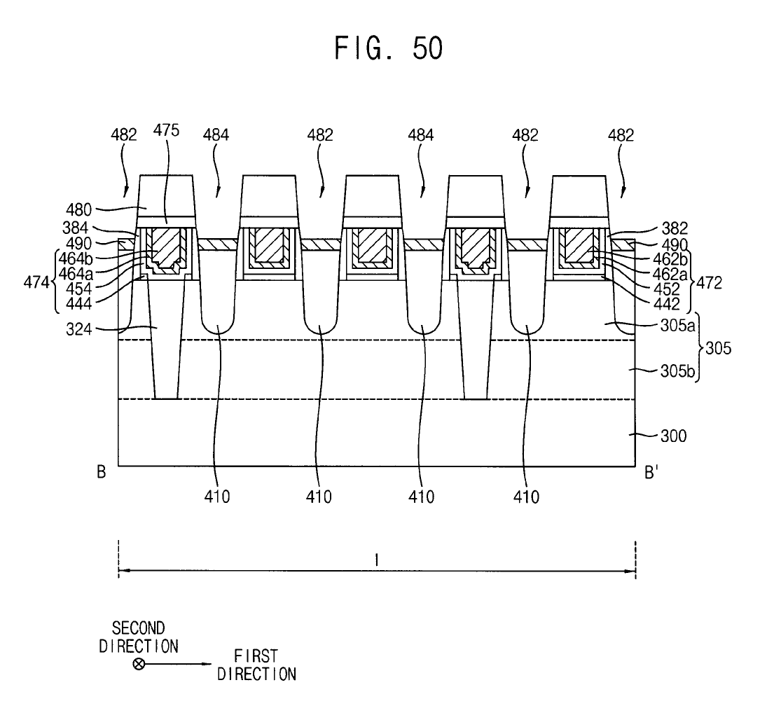

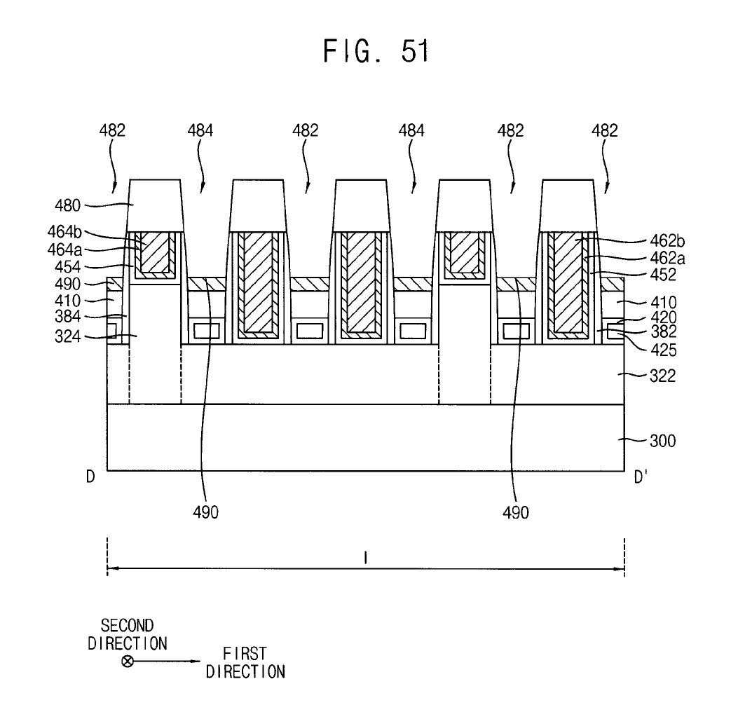

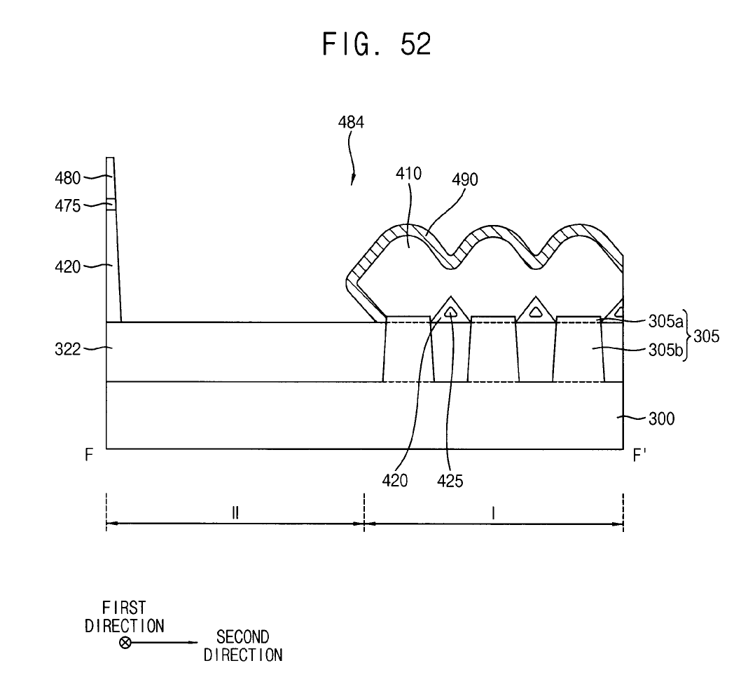

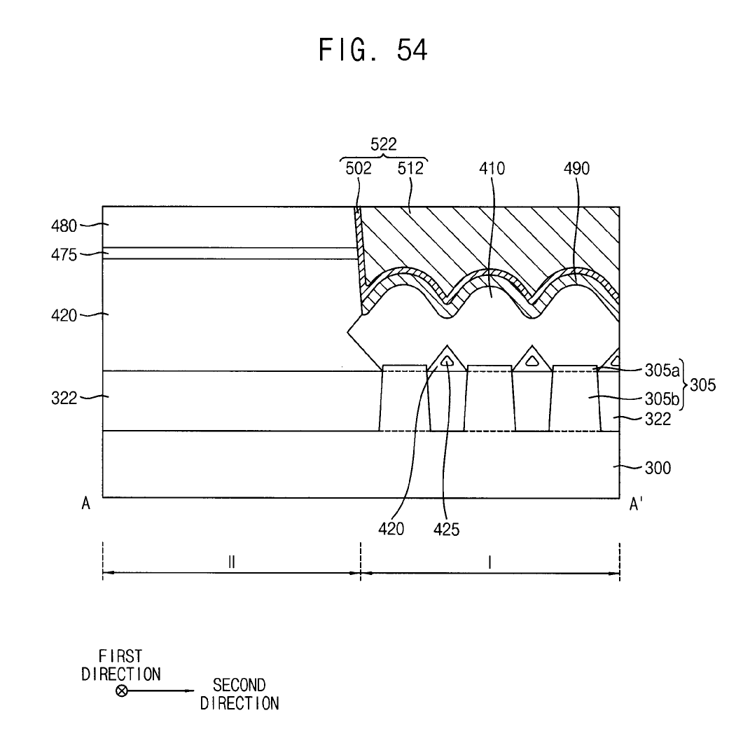

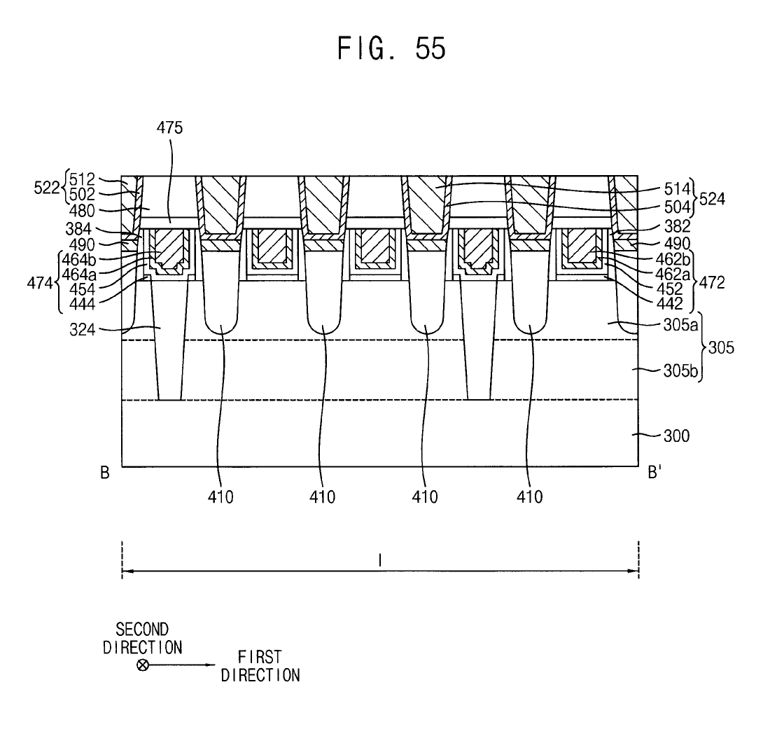

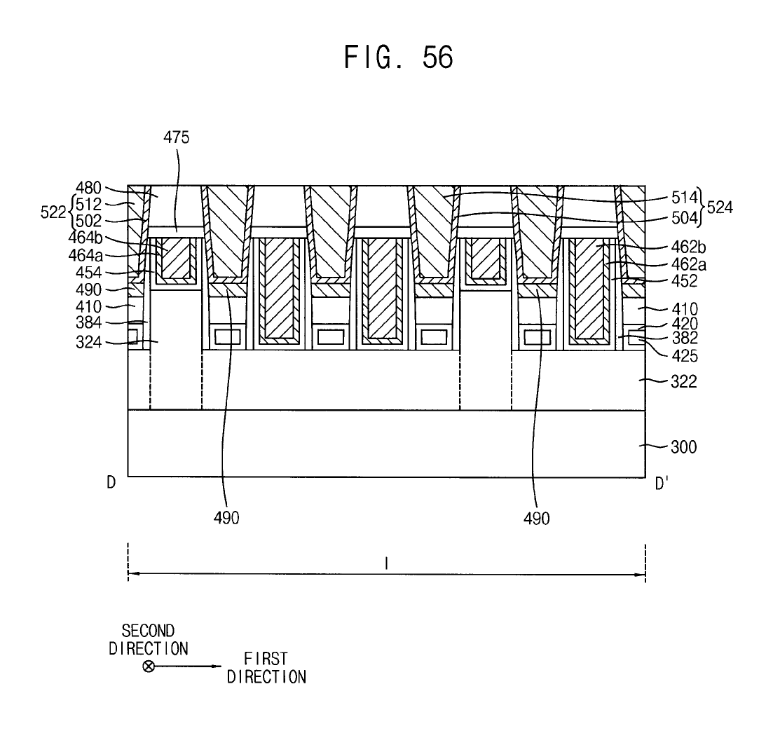

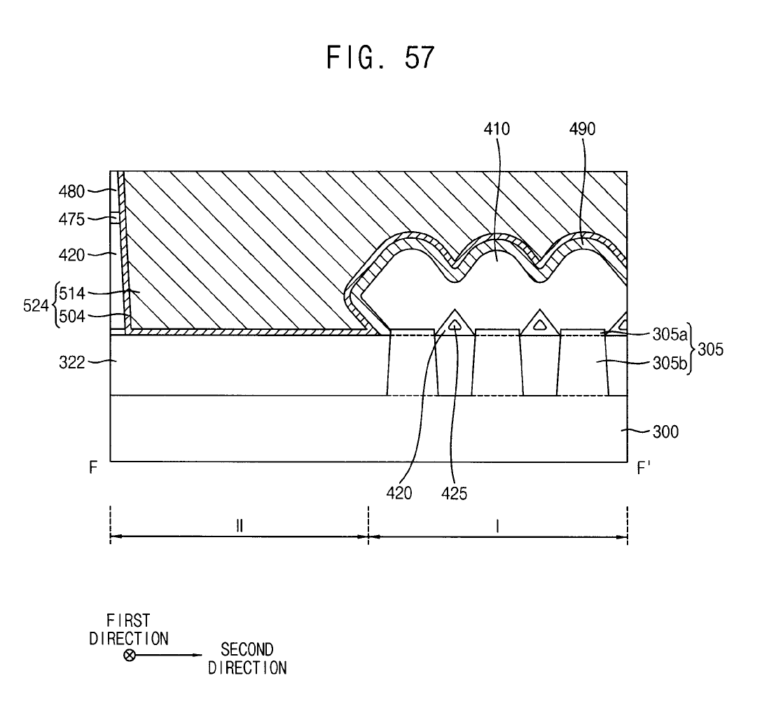

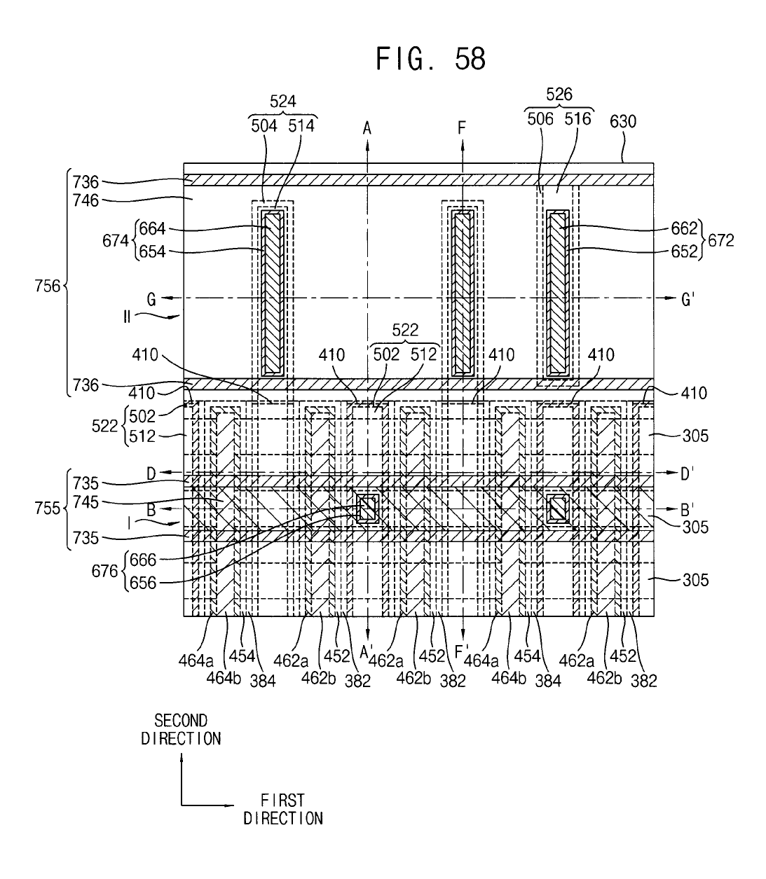

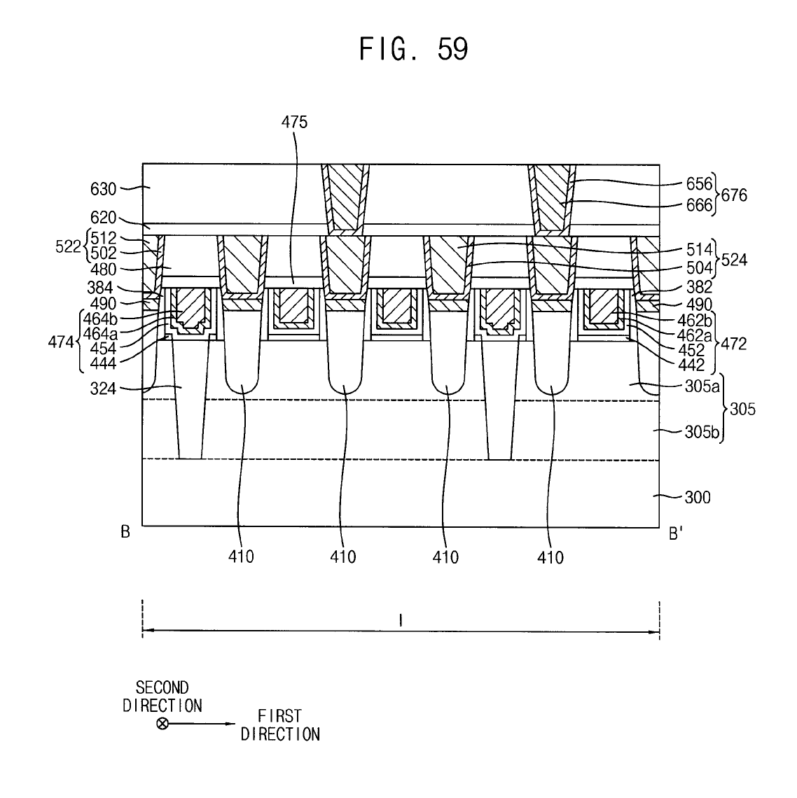

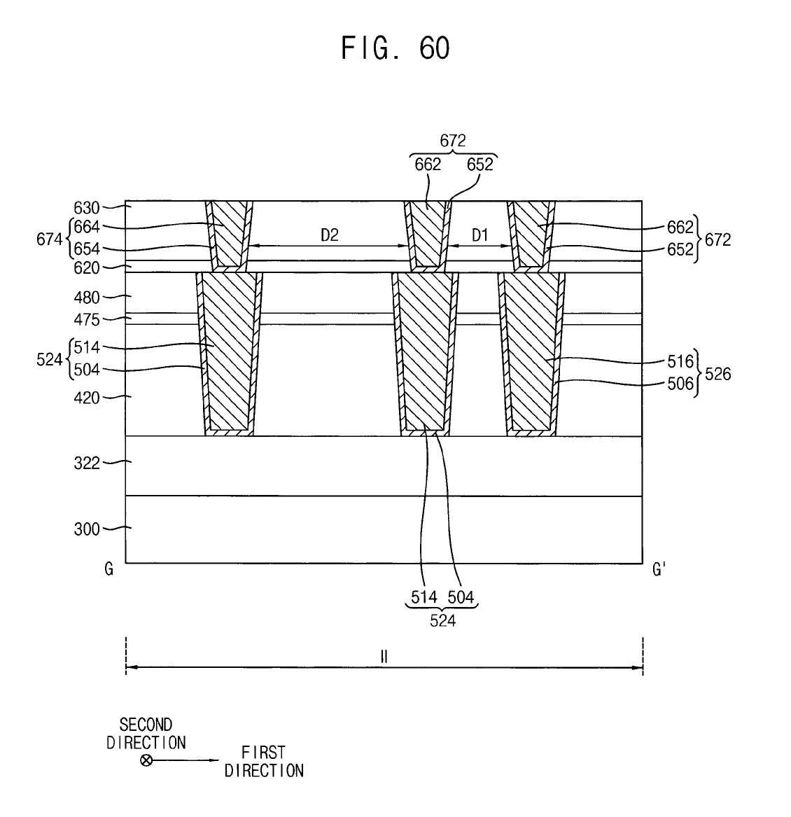

FIGS. 17 to 60 are plan views and cross-sectional views illustrating stages of a method of manufacturing a semiconductor device in accordance with example embodiments. Particularly, FIGS. 17, 20, 23, 28, 33, 36, 40, 44, 48, 53 and 58 are plan views, FIGS. 18-19, 21-22, 24-27, 29-32, 34-35, 37-39, 41-43, 45-47, 49-52, 54-57 and 59-60 are cross-sectional views. FIGS. 18, 21, 24, 34, 37, 41, 49 and 54 are cross-sectional views taken along line A-A′ of corresponding plan views as shown variously in FIGS. 17, 20, 23, 28, 33, 36, 40, 44, 48, 53 and 58; FIGS. 19, 22, 25, 29, 35, 38, 42, 45, 50, 55 and 59 are cross-sectional views taken along line B-B′ of corresponding plan views as shown variously in FIGS. 17, 20, 23, 28, 33, 36, 40, 44, 48, 53 and 58; FIGS. 26 and 30 are cross-sectional views taken along line C-C′ of corresponding plan views as shown variously in FIGS. 23 and 28; FIGS. 27, 31, 39, 43, 46, 51 and 56 are cross-sectional views taken along line D-D′ of corresponding plan views as shown variously in FIGS. 23, 28, 36, 40, 44, 48, 53 and 58; FIGS. 32 and 47 are cross-sectional views taken along line E-E′ of corresponding plan views as shown variously in FIGS. 28 and 44; FIGS. 52 and 57 are cross-sectional views taken along line F-F′ of corresponding plan views as shown variously in FIGS. 48, 53 and 58; and FIG. 60 is a cross-sectional view taken along line G-G′ as shown in FIG. 58. This method may include processes substantially the same as or similar to those described with reference to FIGS. 2 to 6, and detailed descriptions thereof are omitted herein.

Referring to FIGS. 17 to 19, an upper portion of a substrate 300 may be partially removed to form a plurality of first recesses 310, and thus a plurality of active fins 305 may be formed to protrude from the substrate 300.

The substrate 300 may include a semiconductor material, e.g., silicon, germanium, silicon-germanium, etc., or III-V semiconductor compounds, e.g., GaP, GaAs, GaSb, etc. In an example embodiment, the substrate 300 may be an SOI substrate, a GOI substrate, etc.

The substrate 300 may include first and second regions I and II, respectively. In example embodiments, the first region I may be a cell region in which cells may be formed, and the second region II may be a power rail region in which a power rail may be formed. Each of the first and second regions I and II may be defined as not only portions of the substrate 300 but also corresponding spaces above and/or beneath the portions of the substrate 300. A region of the substrate 300 in which the active fins 305 are formed may be defined as an active region, and a region of the substrate 300 in which no active fin is formed may be defined as a field region.

In example embodiments, each of the active fins 305 may extend in a first direction substantially parallel to a top surface of the substrate 300, and the plurality of active fins 305 may be formed in the first direction and/or in a second direction substantially parallel to the top surface of the substrate 300 and substantially perpendicular to the first direction.

Referring to FIGS. 20 to 22, an isolation layer 320 may be formed on the substrate 300 to fill the recesses 310. In example embodiments, the isolation layer 320 may be formed by forming an insulation layer on the substrate 300 to sufficiently fill the first recesses 310, and planarizing the insulation layer (e.g., until a top surface of the active fins 305 of the substrate 300 is exposed). The insulation layer may be formed of an oxide, e.g., silicon oxide.

Referring to FIGS. 23 to 27, after forming a mask 330 on the active fins 305 and the isolation layer 320, an upper portion of the isolation layer 320 not covered by the mask 330 may be etched to form a first isolation pattern 322 having a top surface lower than that of the isolation layer 320.

In example embodiments, the mask 330 may be formed to extend in the second direction in the first region I, and a plurality of masks 330 may be formed in the first direction. Each of the masks 330 may cover ends of the active fins 305 disposed in the first direction and a portion of the isolation layer 320 therebetween. The mask 330 may be formed of a nitride, e.g., silicon nitride.

When the first isolation pattern 322 is formed, a portion of the isolation layer 320, which may be covered by the mask 330 not to be etched in the etching process, may be referred to as a second isolation pattern 324. Accordingly, a top surface of the second isolation pattern 324 may be higher than that of the first isolation pattern 322. In example embodiments, the top surface of the second isolation pattern 324 may be substantially coplanar with those of the active fins 305. Alternatively, the active fins 305 may be partially etched in the etching process, and thus the top surface of the second isolation pattern 324 may be slightly higher than those of the active fins 305.

Upon forming the first and second isolation patterns 322 and 324 on the substrate 300, the field region of the substrate 300 may be covered by the first and second isolation patterns 322 and 324, and the active region of the substrate 300 may not be covered by the first and second isolation patterns 322 and 324, except for the ends thereof in the first direction.

In example embodiments, each of the active fins 305 may include a lower active pattern 305b, having a sidewall that is covered by the first isolation pattern 322, and an upper active pattern 305a protruding from the top surface of the first isolation pattern 322. In example embodiments, in the etching process, a portion of the upper active pattern 305a may be also etched, and thus the upper active pattern 305a may have a width that is slightly smaller than a width of the lower active pattern 305b.

Referring to FIGS. 28 to 32, after removing the mask 330, first and second dummy gate layer structures 372 and 374 may be formed on the substrate 300. The first and second dummy gate structures 372 and 374 may be formed by sequentially forming a dummy gate insulation layer, a dummy gate electrode layer, and a dummy gate mask layer on the active fins 305 of the substrate 300 and the isolation patterns 322 and 324, patterning the dummy gate mask layer (e.g., by a photolithography process using a photoresist pattern, not shown) to form first and second dummy gate masks 362 and 364, and sequentially etching the dummy gate electrode layer and the dummy gate insulation layer using the first and second dummy gate masks 362 and 364 as an etching mask.

Thus, each of the first dummy gate structures 372 may be formed to include a first dummy gate insulation pattern 342, a first dummy gate electrode 352 and the first dummy gate mask 362 sequentially stacked on the active fins 305 of the substrate 300 and portions of the first isolation pattern 322 adjacent to the active fins 305 in the second direction, and each of the second dummy gate structures 374 may be formed to include a second dummy gate insulation pattern 344, a second dummy gate electrode 354 and the second dummy gate mask 364 sequentially stacked on the ends of the active fins 305 of the substrate 300 in the first direction and portions of the second isolation pattern 324 therebetween.

The dummy gate insulation layer may be formed of an oxide, e.g., silicon oxide, the dummy gate electrode layer may be formed of, e.g., polysilicon, and the dummy gate mask layer may be formed of a nitride, e.g., silicon nitride. The dummy gate insulation layer may be formed by a CVD process, an ALD process, or the like. Alternatively, the dummy gate insulation layer may be formed by a thermal oxidation process on an upper portion of the substrate 300, and in this case, the dummy gate insulation layer may not be formed on the first and second isolation patterns 322 and 324 but formed only on the active fins 305. The dummy gate electrode layer and the dummy gate mask layer may be also formed by a CVD process, an ALD process, etc.

In example embodiments, each of the first and second dummy gate structures 372 and 374 may be formed to extend in the second direction on the active fins 305 of the substrate 300 and the isolation patterns 322 and 324 in the first region I, and a plurality of first dummy gate structures 372 and a plurality of second dummy gate structures 374 may be formed to be spaced apart from each other in the first direction. Although the figures show two first dummy gate structures 372 formed on a central portion of each of the active fins 305 and two second dummy gate structures 374 formed on the ends of each of the active fins 305, it will be appreciated that the inventive concepts are not limited thereto.

For example, any number of first dummy gate structures 372 may be formed on a central portion of each of the active fins 305. However, when lengths of the active fins 305 extending in the first direction are substantially the same, and a distance between ones of the first dummy gate structures 372 in the first direction on each of the active fins 305 is constant, the number and order by which the first and second dummy gate structures 372 and 374 are disposed in the first direction may be uniform. In the figures, two first dummy gate structures 372 and one second dummy gate structure 374 are alternately and repeatedly disposed in the first direction.

In example embodiments, the dummy gate structures in the first region I may be spaced apart from each other at a distance smaller than a distance between the dummy gate structures spaced apart from each other in the second direction II.

An ion implantation process may be further performed to form an impurity region (not shown) at upper portions of the active fins 305 adjacent to the first and second dummy gate structures 372 and 374.

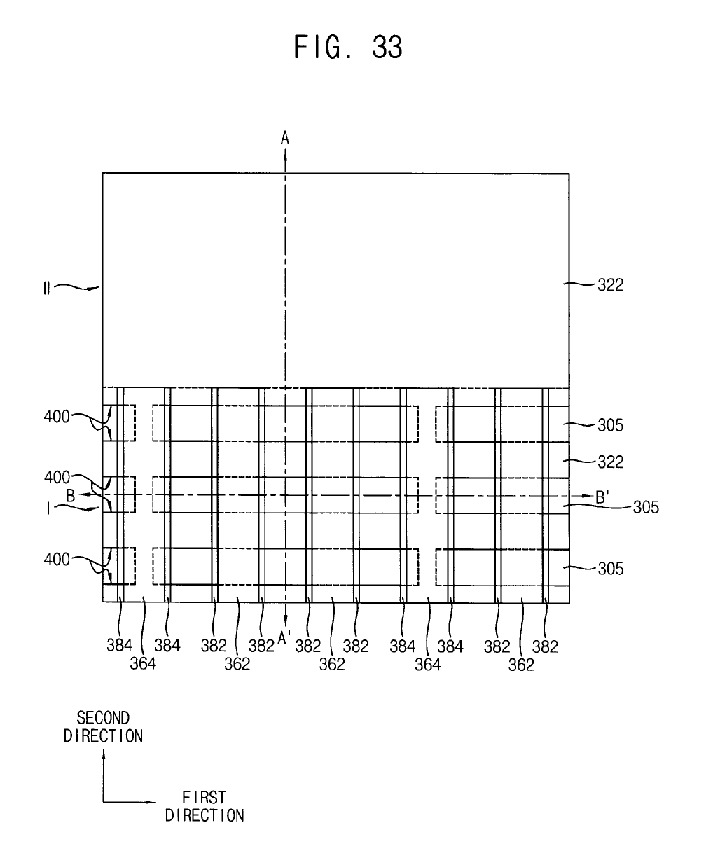

Referring to FIGS. 33 to 35, first and second gate spacers 382 and 384 may be formed on sidewalls of the first and second dummy gate structures 372 and 374, respectively, and a fin spacer (not shown) may be formed on sidewalls of each of the active fins 305. The first and second gate spacers 382 and 384 and the fin spacer may thus form a spacer structure.

In example embodiments, the first and second gate spacers 382 and 384 and the fin spacer may be formed by forming a spacer layer on the first and second dummy gate structures 372 and 374, the active fins 305, and the first and second isolation patterns 322 and 324, and anisotropically etching the spacer layer. The spacer layer may be formed of a nitride, e.g., silicon nitride, silicon carbonitride, silicon oxycarbonitride, etc. The first and second gate spacers 382 and 384 may be formed on the sidewalls of the first and second dummy gate structures 372 and 374, respectively, opposite to each other in the first direction, and the fin spacer may be formed on the sidewalls of each of the active fins 305 opposite to each other in the second direction.

Upper portions of the active fins 305 adjacent to the first and second dummy gate structures 372 and 374 may be etched to form a second recess 400. For example, the upper portions of the active fins 305 may be etched using the first and second dummy gate structures 372 and 374 and the first and second gate spacers 382 and 384 on the sidewalls thereon as an etching mask to form the second recess 400. The fin spacer may be also etched in the etching process.

Although the upper active pattern 305a in each of the active fins 305 are illustrated as being partially etched to form the second recess 400, it will be appreciated that the inventive concepts are not limited thereto. For example, the second recess 400 may be formed by removing not only the upper active pattern 305a, but also a portion of the lower active pattern 305b. In example embodiments, the second recess 400 may have a cross-section that, when viewed along the first direction, has a U-like shape. It will nevertheless be appreciated that the cross-section of the second recess 400 may have any other shape.

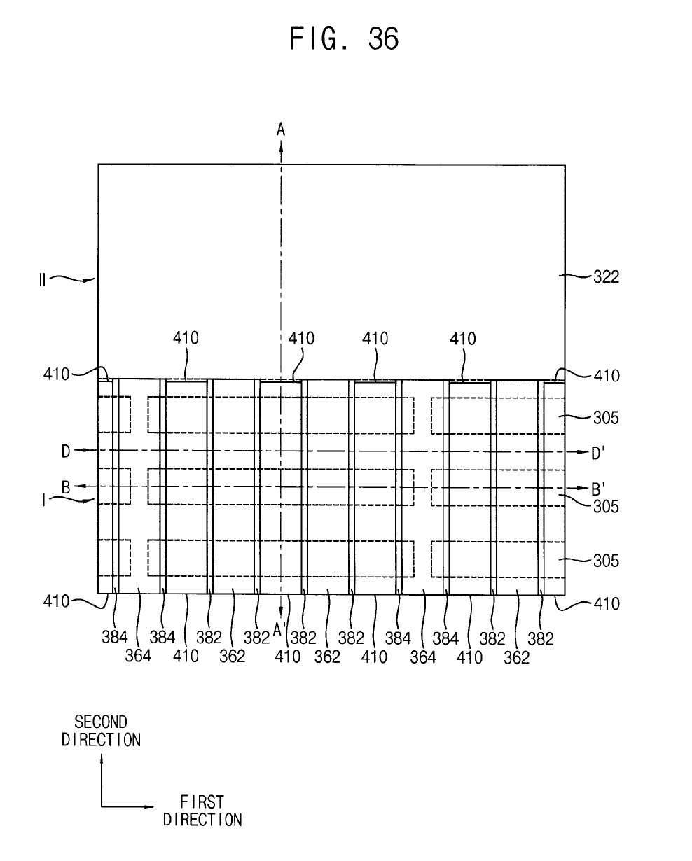

Referring to FIGS. 36 to 39, a source/drain layer 410 may be formed on each of the active fins 305 to fill the second recess 400. In example embodiments, the source/drain layer 410 may be formed by a selective epitaxial growth (SEG) process using a top surface of each of the active fins 305 exposed by the second recess 400 as a seed.

In example embodiments, the SEG process may be performed using a silicon source gas, e.g., disilane (Si₂H₆) gas, and a carbon source gas, e.g., monomethylsilane (SiH₃CH₃) gas, to form a single crystalline silicon carbide layer. Alternatively, the SEG process may be performed using only a silicon source gas, e.g., disilane (Si₂H₆) gas, to form a single crystalline silicon layer. An n-type impurity source gas, e.g., phosphine (PH₃) gas, may be also used to form a single crystalline silicon carbide layer doped with n-type impurities or a single crystalline silicon layer doped with n-type impurities. Accordingly, the source/drain layer 410 may serve as a source/drain region of an NMOS transistor.

Alternatively, the SEG process may be performed using a silicon source gas, e.g., dichlorosilane (SiH₂Cl₂) gas, and a germanium source gas, e.g., germane (GeH₄) gas, to form a single crystalline silicon-germanium layer. A p-type impurity source gas, e.g., diborane (B₂H₆) gas, may be also used to form a single crystalline silicon-germanium layer doped with p-type impurities. Accordingly, the source/drain layer 410 may serve as a source/drain region of a PMOS transistor.

The source/drain layer 410 may grow both in vertical and horizontal directions, and may not only fill the second recess 400, but also contact portions of the first and second gate spacers 382 and 384. An upper portion of the source/drain layer 400 may have a cross-section that, when viewed along the second direction, having a shape such as a pentagon or hexagon. When the active fins 305 are spaced apart from each other in the second direction by a short distance, neighboring ones of the source/drain layers 410 in the second direction may be merged with each other to form a single layer. In the figures, one merged source/drain layer 410 grown from the neighboring ones of the active fins 305 in the second direction is shown.

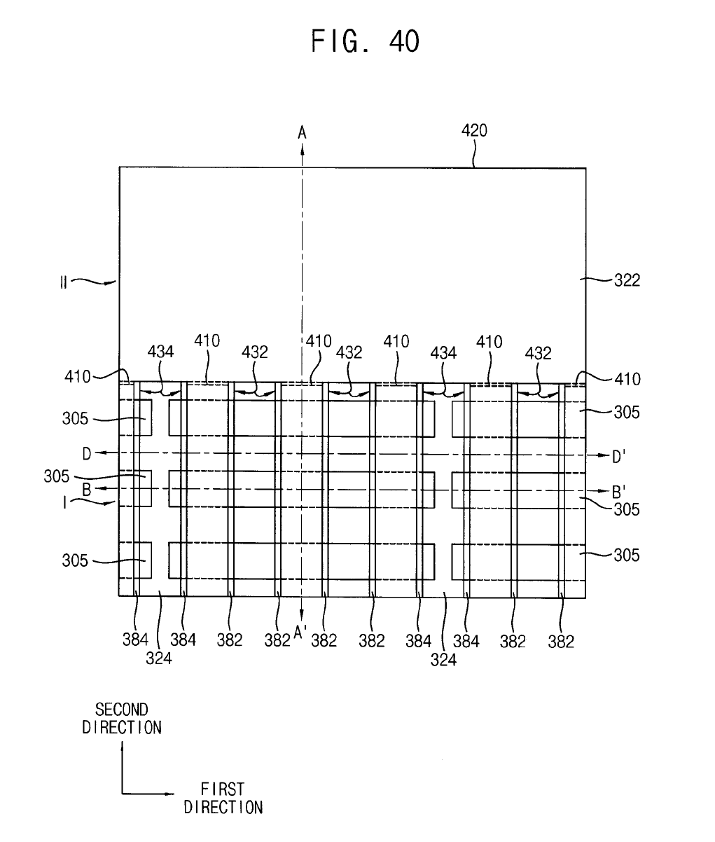

Referring to FIGS. 40 to 43, a first insulating interlayer 420 (e.g., an oxide such as silicon oxide) may be formed on the active fins 305 and the first and second isolation patterns 322 and 324 to cover the first and second dummy gate structures 372 and 374, the first and second gate spacers 382 and 384, and the source/drain layers 410. The first insulating interlayer 420 may be planarized (e.g., by a CMP process and/or an etch back process) until a top surface of the first and second dummy gate electrodes 352 and 354 of the first and second dummy gate structures 372 and 374, respectively, is exposed. The first and second dummy gate masks 362 and 364 may be also removed, and upper portions of the first and second gate spacers 382 and 384 may be also removed. A space between the merged source/drain layer 410 and the first isolation pattern 322 may not be fully filled with the first insulating interlayer 320, and thus an air gap 425 may be formed.

The exposed first and second dummy gate electrodes 352 and 354, and the first and second dummy gate insulation patterns 342 and 344 thereunder, may be removed to form a first opening 432 exposing a top surface of the active fin 305, a top surface of the first isolation pattern 322 and an inner sidewall of the first gate spacer 382, and to form a second opening 434 exposing a top surface of the active fin 305, a top surface of the second isolation pattern 324 and an inner sidewall of the second gate spacer 384.

Referring to FIGS. 44 to 47, first and second gate structures 472 and 474 may be formed to fill the first and second openings 432 and 434, respectively. For example, after a thermal oxidation process is performed on the top surfaces of the active fins 305 exposed by the first and second openings 432 and 434 to form first and second interface patterns 442 and 444, respectively, a gate insulation layer and a workfunction control layer may be sequentially formed on the first and second interface patterns 442 and 444, the first and second isolation patterns 322 and 324, the first and second gate spacers 382 and 384 and the first insulating interlayer 420, and a gate electrode layer may be formed on the workfunction control layer to sufficiently fill remaining portions of the first and second openings 432 and 434.

The gate insulation layer may be formed of a metal oxide having a high dielectric constant, e.g., hafnium oxide, tantalum oxide, zirconium oxide, or the like, by a CVD process, a PVD process, an ALD process, or the like. The workfunction control layer may be formed of a metal nitride or a metal alloy, e.g., titanium nitride, titanium aluminum, titanium aluminum nitride, tantalum nitride, tantalum aluminum nitride, etc. The gate electrode layer may be formed of a metal having a low resistance, e.g., aluminum, copper, tantalum, etc., or a nitride thereof. The workfunction control layer and the gate electrode layer may be formed by a CVD process, a PVD process, an ALD process, or the like. In an example embodiment, a heat treatment process, e.g., a rapid thermal annealing (RTA) process, a spike rapid thermal annealing (spike RTA) process, a flash rapid thermal annealing (flash RTA) process or a laser annealing process may be further performed on the gate electrode layer.

The first and second interface patterns 442 and 444 may be formed by a CVD process, a PVD process, an ALD process instead of the thermal oxidation process, and in this case, the first and second interface patterns 442 and 444 may be formed not only on the top surfaces of the active fins 305, but also on the top surfaces of the first and second isolation layer patterns 322 and 324 and the inner sidewalls of the first and second gate spacers 382 and 384.

The gate electrode layer, the workfunction control layer and the gate insulation layer may be planarized (e.g., by a CMP process and/or an etch back process) until the top surface of the first insulating interlayer 420 is exposed to form a first gate insulation pattern 452 and a first workfunction control pattern 462a sequentially stacked on the top surface of the first interface pattern 442, the top surface of the first isolation pattern 322, and the inner sidewall of the first gate spacer 382, and a first gate electrode 462b filling a remaining portion of the first opening 432 on the first workfunction control pattern 462a. Thus, a bottom and a sidewall of the first gate electrode 462b may be covered by the first workfunction control pattern 462a. Additionally, a second gate insulation pattern 454 and a second workfunction control pattern 464a may be sequentially stacked on the top surface of the second interface pattern 444, the top surface of the second isolation pattern 324, and the inner sidewall of the second gate spacer 384, and a second gate electrode 464b filling a remaining portion of the second opening 434 may be formed on the second workfunction control pattern 464a. Thus, a bottom and a sidewall of the second gate electrode 464b may be covered by the second workfunction control pattern 464a.

The sequentially stacked first interface pattern 442, the first gate insulation pattern 452, the first workfunction control pattern 462a and the first gate electrode 462b may form a first gate structure 472, and the first gate structure 472 and the source/drain layer 410 may form an NMOS transistor or a PMOS transistor. Additionally, the sequentially stacked second interface pattern 444, the second gate insulation pattern 454, the second workfunction control pattern 464a and the second gate electrode 464b may form a second gate structure 474, and the second gate structure 474 and the source/drain layer 410 may form an NMOS transistor or a PMOS transistor.

Referring to FIGS. 48 to 52, a capping layer 475 and a second insulating interlayer 480 may be sequentially formed on the first insulating interlayer 420, the first and second gate structure 472 and 474, and the first and second gate spacer 382 and 384, and third, fourth and fifth openings 482, 484 and 486 may be formed through the capping layer 475 and the first and second insulating interlayers 420 and 480 to expose upper surfaces of the source/drain layers 410.

In example embodiments, the third opening 482 may extend in the second direction in the first region I to expose an upper surface of the source/drain layer 410, and the fourth opening 484 may extend in the second direction in one of the first regions I and the second region and II to expose not only an upper surface of the source/drain layer 410, but also a top surface of the first isolation pattern 322 in the second region II. The fifth opening 486 may extend in the second direction in the second region II and another one of the first regions I, which may be opposite to the one of the first regions I in the second direction, and may expose an upper surface of the source/drain layer 410 in the another one of the first regions I and a top surface of the first isolation pattern 322 in the second region I.

In example embodiments, the third and fourth openings 482 and 484 may be formed to be self-aligned with the first and second gate spacers 382 and 384, respectively. However, the inventive concepts are not limited thereto, and the third and fourth openings 482 and 484 may be formed to expose central portions of the source/drain layer 410 between the first and second gate spacers 382 and 384.

In the figures, five third openings 482, two fourth openings 484 and one fifth opening 486 are shown, however, the inventive concepts are not limited thereto. In some embodiments, the third opening 482 may not be formed, and only the fourth and fifth openings 484 and 486 may be formed. In this case, the number and order of the fourth and fifth openings 484 and 486 may not be limited.

The capping layer 475 may be formed of a nitride, e.g., silicon nitride, and the second insulating interlayer 480 may be formed of a material substantially the same as or different from that of the first insulating interlayer 410. For example, the second insulating interlayer 480 may be formed of an oxide, e.g., silicon oxide.

A metal layer may be formed on the exposed upper surfaces of the source/drain layers 410 and thereafter thermally treated to react a portion of the metal layer with silicon in the source/drain layers 410. Any non-reacted portion of the metal layer may thereafter be removed, leaving a metal silicide pattern 490 formed on each of the upper surfaces of the source/drain layers 410. The metal layer may be formed of, e.g., cobalt, nickel, titanium, etc. In some embodiments, the metal silicide pattern 490 may not be formed.

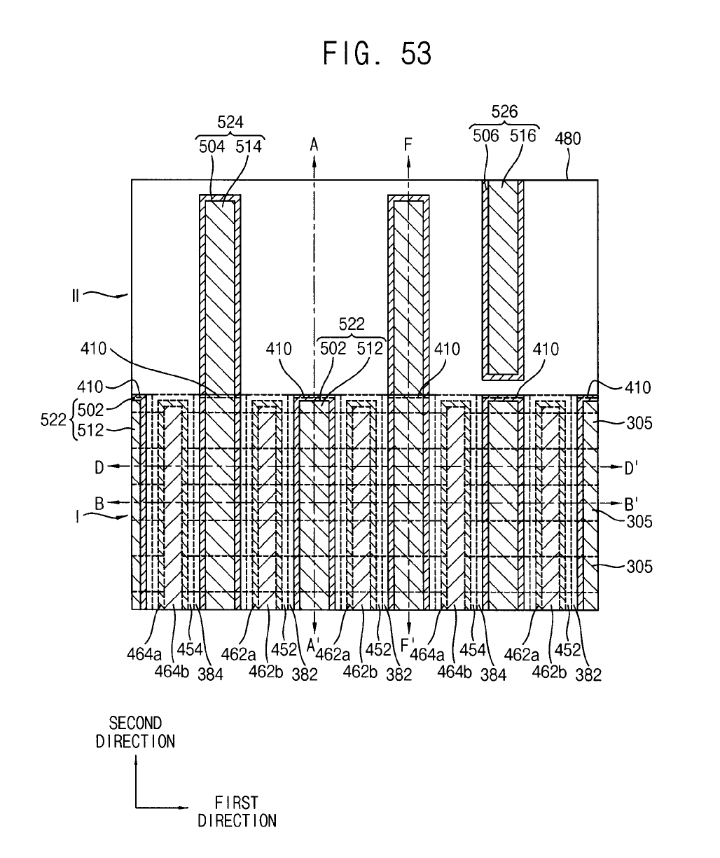

Referring to FIGS. 53 to 57, first, second and third lower contact plugs 522, 524 and 526 may be formed to fill the third, fourth and fifth openings 482, 484 and 486, respectively. The first, second and third lower contact plugs 522, 524 and 526 may form a lower contact plug structure.

In example embodiments, the first, second and third lower contact plugs 522, 524 and 526 may be formed by forming a lower barrier layer on the metal silicide pattern 490, sidewalls of the third, fourth and fifth openings 482, 484 and 486, and the second insulating interlayer 480, filling a lower conductive layer on the lower barrier layer to sufficiently fill remaining portions of the third, fourth and fifth openings 482, 484 and 486, and planarizing the lower conductive layer and the lower barrier layer until a top surface of the second insulating interlayer 480 is exposed. The lower barrier layer may be formed of a metal nitride, e.g., tantalum nitride, titanium nitride, etc., and/or a metal, e.g., tantalum, titanium, etc. The lower conductive layer may be formed of a metal, e.g., tungsten, copper, aluminum, etc.

Thus, the first lower contact plug 522 may include a first lower barrier pattern 502 and a first lower conductive pattern 512 sequentially stacked, the second lower contact plug 524 may include a second lower barrier pattern 504 and a second lower conductive pattern 514 sequentially stacked, and the third lower contact plug 526 may include a third lower barrier pattern 506 and a third lower conductive pattern 516 sequentially stacked. The first lower barrier pattern 502 may cover a bottom and a sidewall of the first lower conductive pattern 512, the second lower barrier pattern 504 may cover a bottom and a sidewall of the second lower conductive pattern 514, and the third lower barrier pattern 506 may cover a bottom and a sidewall of the third lower conductive pattern 516.

In example embodiments, the first lower contact plug 522 filling the third opening 482 may extend in the second direction in one of the first regions I, and may contact the metal silicide pattern 490 on the source/drain layer 410; and the second lower contact plug 524 filling the fourth opening 484 may extend in the second direction in the one of the first regions I and the second region II, and may contact the metal silicide pattern 490 on the source/drain layer 410 and the first isolation pattern 322. The third lower contact plug 526 filling the fifth opening 486 may extend in the second direction in the second region II and another one of the first regions I, which may be opposite to the aforementioned one of the first regions I in the second direction, and may contact the metal silicide pattern (not shown) on the source/drain layer (not shown).

Referring to FIGS. 58 to 60, processes substantially the same as or similar to those described with reference to FIGS. 2 and 3 may be performed. Thus, a first etch stop layer 620 and a third insulating interlayer 630 may be sequentially formed on the second insulating interlayer 480 and the lower contact plug structure, and first, second and third upper contact plugs 672, 674 and 676 may be formed through the third insulating interlayer 630 and the first etch stop layer 620 to contact the lower contact plug structure. The first, second and third upper contact plugs 672, 674 and 676 may form an upper contact plug structure.

The first etch stop layer 620 may be formed of a nitride, e.g., silicon nitride, silicon carbonitride, silicon oxycarbonitride, etc. The third insulating interlayer 630 may be formed of, e.g., silicon oxide. Alternatively, the third insulating interlayer 630 may be formed of a low-k dielectric material (e.g., silicon oxide doped with carbon (SiCOH), silicon oxide doped with fluorine (F—SiO₂), etc.), a porous silicon oxide, a spin-on organic polymer, an inorganic polymer (e.g., hydrogen silsesquioxane (HSSQ), methyl silsesquioxane (MSSQ), etc.), or the like.

Each of the first and second upper contact plugs 672 and 674 may be formed to contact the second lower contact plug 524 or the third lower contact plug 526 in the second region II. The third upper contact plug 676 may be formed to contact the first lower contact plug 522 in the first region I. Although the figures show two first upper contact plugs 672 contacting the second and third lower contact plugs 524 and 526, respectively, and one second upper contact plug 674 contacting one second lower contact plug 524, it will be appreciated that the inventive concepts are not limited thereto.

For example, each of the first upper contact plugs 672 may be formed on the second contact plug 524 or the third lower contact plug 526 in the second region II. Alternatively, the first upper contact plugs 672 may be formed on the second and third lower contact plugs 524 and 526, respectively, in the second region II. The second upper contact plug 674 may be formed on the third lower contact plug 526 in the second region II, or a plurality of second upper contact plugs 674 may be formed on some or all of the second and third lower contact plugs 524 and 526 in the second region II. However, in the second region II, at least one of the first and second upper contact plugs 672 and 674 may be formed on the second lower contact plug 524, and at least one of the first and second upper contact plugs 672 and 674 may be formed on the third lower contact plug 526.

In example embodiments, the first upper contact plugs 672 may be spaced apart from each other in the first direction by a first distance D1, and the second upper contact plug 674 may be spaced apart from the nearest one of the first upper contact plugs 672 thereto in the first direction by a second distance D2, which is greater than the first distance D1. The plurality of second upper contact plugs 674 may be spaced apart from each other in the first direction by a distance that is greater than the first distance D1.

The first upper contact plug 672 may be formed to include a first upper barrier pattern 652 and a first upper conductive pattern 662 sequentially stacked, the second upper contact plug 674 may be formed to include a second upper barrier pattern 654 and a second upper conductive pattern 664 sequentially stacked, and the third upper contact plug 676 may be formed to include a third upper barrier pattern 656 and a third upper conductive pattern 666 sequentially stacked. The first upper barrier pattern 652 may cover a bottom and a sidewall of the first upper conductive pattern 662, the second upper barrier pattern 654 may cover a bottom and a sidewall of the second upper conductive pattern 664, and the third upper barrier pattern 656 may cover a bottom and a sidewall of the third upper conductive pattern 666.

Each of the first, second and third upper barrier patterns 652, 654 and 656 may be formed of a metal nitride, e.g., tantalum nitride, titanium nitride, etc., and/or a metal, e.g., tantalum, titanium, etc. Each of the first, second and third upper conductive patterns 662, 664 and 666 may be formed of a metal, e.g., tungsten, copper, aluminum, etc. The first, second and third upper barrier patterns 652, 654 and 656 may be formed of substantially the same material or different materials, and the first, second and third upper conductive patterns 662, 664 and 666 may be formed of substantially the same material or different materials.

Thereafter, and referring back to FIGS. 9 to 16, processes substantially the same as or similar to those described with reference to FIGS. 4 to 6 and FIG. 1 may be performed to complete the semiconductor device. Thus, a second etch stop layer 680 and a fourth insulating interlayer 690 may be sequentially formed on the third insulating interlayer 630 and the upper contact plug structure, and first, second and third vias 752, 754 and 753, and first and second wirings 756 and 755 may be formed through the second etch stop layer 680 and the fourth insulating interlayer 690 to contact the upper contact plug structure. The first, second and third vias 752, 754 and 753 may form a via structure, and the first and second wirings 756 and 755 may form a wiring structure.

The second etch stop layer 680 may be formed of a nitride, e.g., silicon nitride, silicon carbonitride, silicon oxycarbonitride, aluminum nitride, etc., or an oxide, e.g., titanium oxide, tantalum oxide, zinc oxide, etc. The first and second etch stop layers 620 and 680 may be formed of substantially the same material or different materials. The first and second etch stop layers 620 and 680 may form an etch stop layer structure.

The fourth insulating interlayer 690 may be formed of, e.g., silicon oxide. Alternatively, the fourth insulating interlayer 690 may be formed of a low-k dielectric material (e.g., silicon oxide doped with carbon (SiCOH), silicon oxide doped with fluorine (F—SiO₂), etc.), a porous silicon oxide, a spin-on organic polymer, an inorganic polymer (e.g., hydrogen silsesquioxane (HSSQ), methyl silsesquioxane (MSSQ), etc.), or the like. The third and fourth insulating interlayers 630 and 690 may be formed of substantially the same material or different materials. The first, second, third and fourth insulating interlayers 420, 480, 630 and 690 may form an insulating interlayer structure.

The first via 752 may contact top surfaces of the first upper contact plugs 672 and an upper surface of a portion of the third insulating interlayer 630 therebetween, and further contact upper surfaces of portions of the third insulating interlayer 630 adjacent to outer edges of the first upper contact plugs 672. The second via 754 may contact a top surface of the second upper contact plug 674 and an upper surface of a portion of the third insulating interlayer 630 adjacent to the second upper contact plug 674. The third via 753 may contact a top surface of the third upper contact plug 676 and an upper surface of a portion of the third insulating interlayer 630 adjacent to the third upper contact plug 676.

When a plurality of second upper contact plugs 674 is formed, a plurality of second vias 754 may be formed on the plurality of second upper contact plugs 674, respectively. The first via 752 may commonly contact top surfaces of the plurality of first upper contact plugs 672. However, the second via 754 may not commonly contact top surfaces of the plurality of second upper contact plugs 674. Rather, each second via 754 of the plurality of second vias 754 may contact a respective top surface of an individual one of the plurality of second contact plugs 674. In example embodiments, the first via 752 may have a first width W1 in the first direction that is greater than a second width W2 of the second via 754 in the first direction.

A bottom of each of the first, second and third vias 752, 754 and 753 may not have a constant height, and a portion of the bottom of each of the first, second and third vias 752, 754 and 753 contacting top surfaces of the first, second and third contact plugs 672, 674 and 676, respectively, may be higher than a portion of the bottom of each of the first, second and third vias 752, 754 and 753 contacting upper surfaces of portions of the third insulating interlayer 630 laterally adjacent to the first, second and third contact plugs 672, 674 and 676, respectively.

The first wiring 756 may be formed through an upper portion of the fourth insulating interlayer 690 in the second region II to be connected to and integrally formed with the first and second vias 752 and 754. The first wiring 756 and the first and second vias 752 and 754 may be formed of substantially the same material, and a bottom of the first wiring 756 may commonly contact top surfaces of the first and second vias 752 and 754. In example embodiments, the first wiring 756 may extend in the first direction. In example embodiments, the first wiring 756 may serve as a power rail that may provide a voltage, e.g., source voltage, drain voltage, ground voltage, etc., for cells in the first region I.

The second wiring 755 may be formed through an upper portion of the fourth insulating interlayer 690 in the first region I to be connected to and integrally formed with the third via 753. The second wiring 755 and the third via 753 may be formed of substantially the same material, and a bottom of the second wiring 756 may contact a top surface of the third via 753. In example embodiments, the second wiring 755 may extend in the first direction or in the second direction, or may have various other shapes.

The first via 752 may be formed to include a fourth upper barrier pattern 732 and a fourth upper conductive pattern 742 sequentially stacked, the second via 754 may be formed to include a fifth upper barrier pattern 734 and a fifth upper conductive pattern 744 sequentially stacked, and the third via 753 may be formed to include a sixth upper barrier pattern 733 and a sixth upper conductive pattern 743 sequentially stacked. The fourth upper barrier pattern 732 may cover a bottom and a sidewall of the fourth upper conductive pattern 742, the fifth upper barrier pattern 734 may cover a bottom and a sidewall of the fifth upper conductive pattern 744, and the sixth upper barrier pattern 736 may cover a bottom and a sidewall of the sixth upper conductive pattern 746.

The first wiring 756 may be formed to include a seventh upper barrier pattern 736 and a seventh upper conductive pattern 746 sequentially stacked, the second wiring 755 may be formed to include an eighth upper barrier pattern 735 and an eighth upper conductive pattern 745 sequentially stacked. The seventh upper barrier pattern 736 may cover a portion of a bottom and a sidewall of the seventh upper conductive pattern 746, and the eighth upper barrier pattern 735 may cover a portion of a bottom and a sidewall of the eighth upper conductive pattern 745.

Each of the fourth, fifth, sixth, seventh and eighth barrier patterns 732, 734, 733, 736 and 735 may be formed of a metal nitride, e.g., tantalum nitride, titanium nitride, etc., and/or a metal, e.g., tantalum, titanium, etc., and the fourth, fifth, sixth, seventh and eighth conductive patterns 742, 744, 743, 746 and 745 may be formed of a metal, e.g., copper, aluminum, tungsten, etc. In example embodiments, the fourth, fifth, sixth, seventh and eighth barrier patterns 732, 734, 733, 736 and 735 may be formed of substantially the same material, and the fourth, fifth, sixth, seventh and eighth conductive patterns 742, 744, 743, 746 and 745 may be formed of substantially the same material.

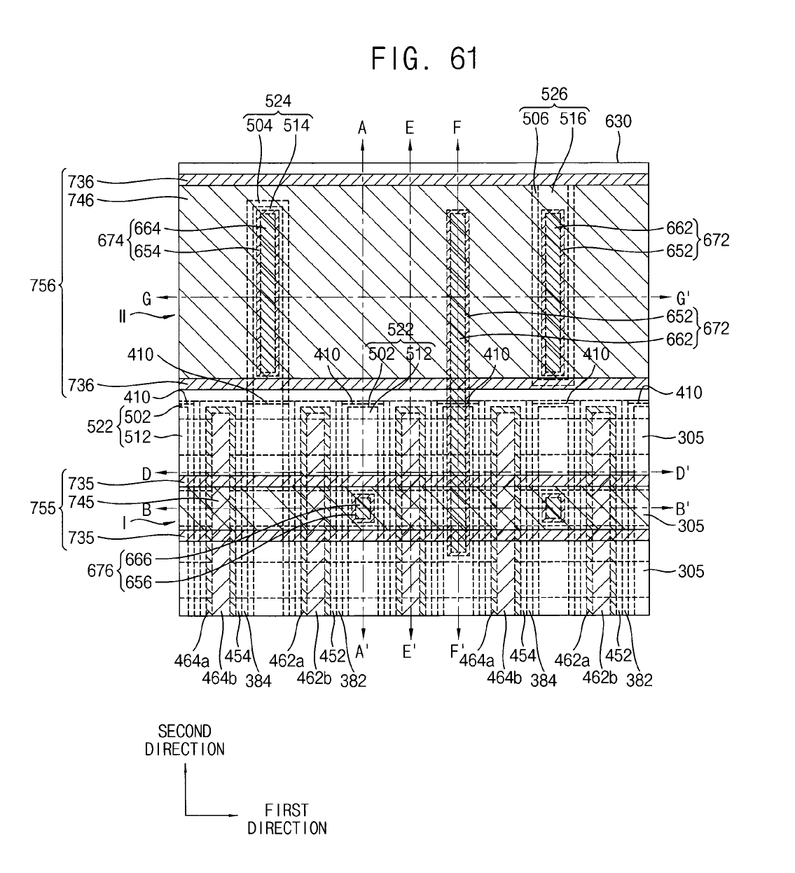

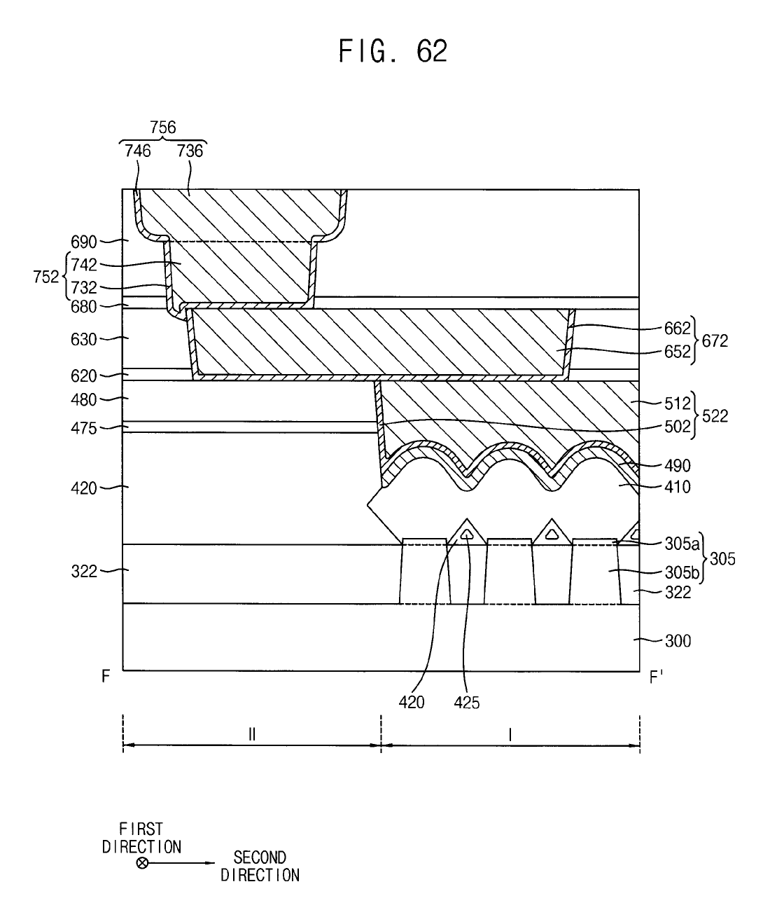

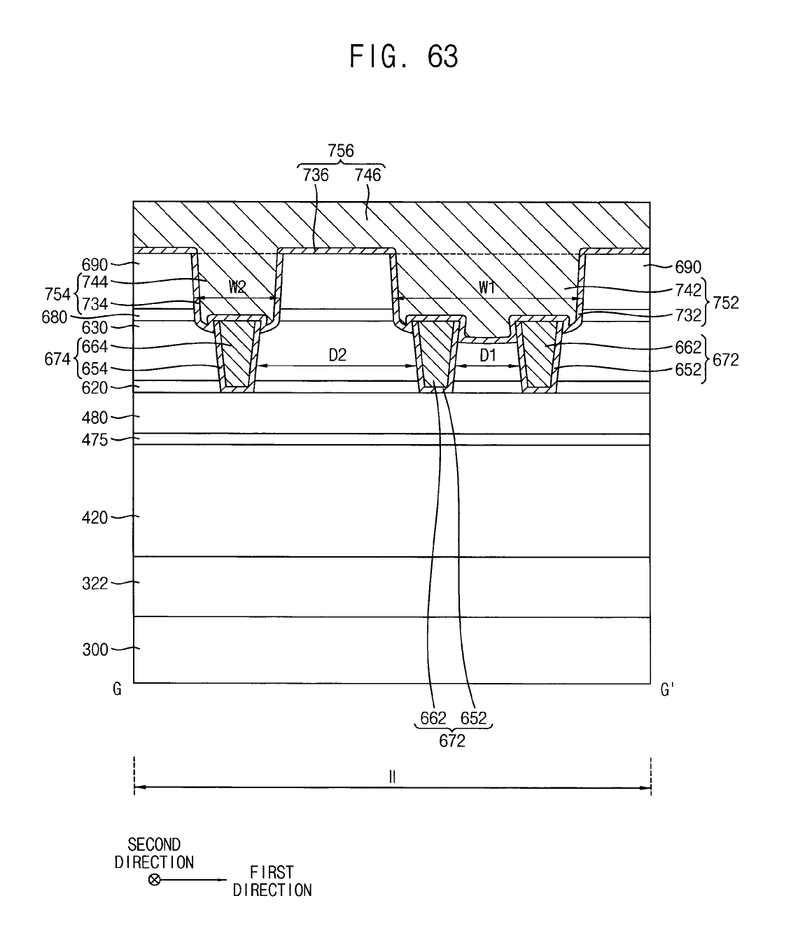

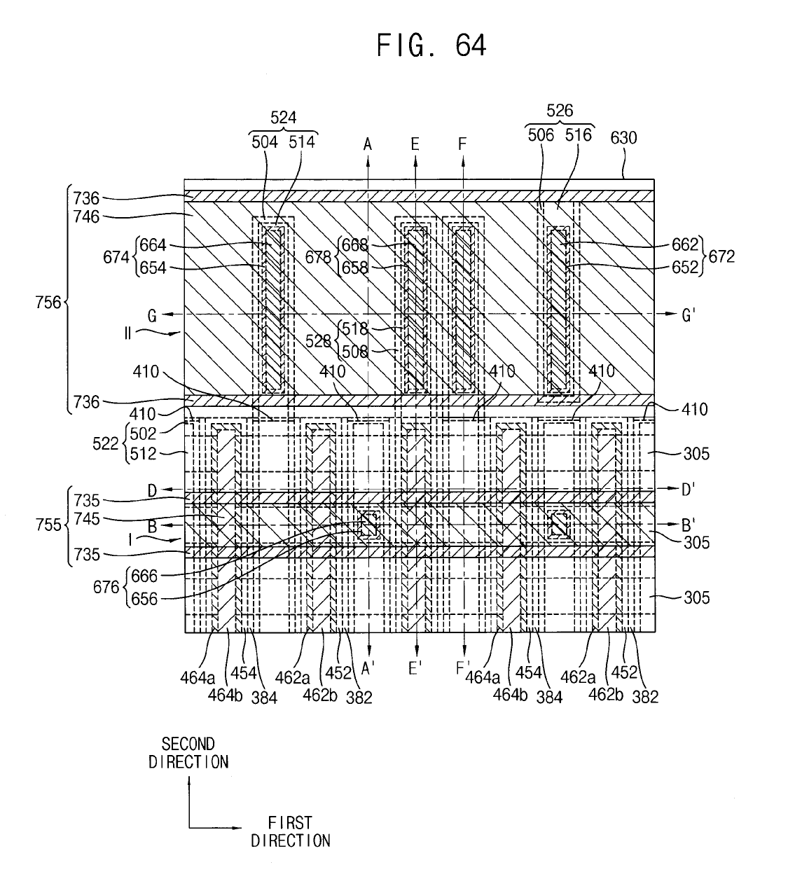

FIGS. 61 to 63 are a plan view and cross-sectional views illustrating a semiconductor device in accordance with example embodiments. Particularly, FIG. 61 is a plan view of the semiconductor device, and FIGS. 62 and 63 are cross-sectional views of the semiconductor device. FIG. 62 is a cross-sectional view taken along line F-F′ shown in FIG. 61, and FIG. 62 is a cross-sectional view taken along line G-G′ shown FIG. 61.

The semiconductor device may be substantially the same as or similar to that described with reference to FIGS. 9 to 16, except for the lower contact plug structure and the upper contact plug structure. Thus, like reference numerals refer to like elements, and detailed descriptions thereof may be omitted below in the interest of brevity.

Referring to FIGS. 61 to 63, the semiconductor device may include the transistor, a lower contact plug structure, an upper contact plug structure, the via structure, and the wiring structure on the substrate 300. The semiconductor device may further include the insulating interlayer structure, the etch stop layer structure, the spacer structure, and the metal silicide pattern 490 on the substrate 300.

The lower contact plug structure may penetrate through the first and second insulating interlayers 420 and 480 and a capping layer 475 therebetween, and may contact the metal silicide pattern 490. The lower contact plug structure may include only the first lower contact plug 522. In example embodiments, the first lower contact plug 522 may extend in the second direction in the first region I, and may contact the metal silicide pattern 490 on the source/drain layer 410.

The upper contact plug structure may penetrate through the first etch stop layer 620 and the third insulating interlayer 630, and may contact the lower contact plug structure. The upper contact plug structure may include the first, second and third upper contact plugs 672, 674 and 676. Each of the first and second upper contact plugs 672 and 674 may extend in the second direction in the first and second regions I and II, and may contact the first lower contact plug 522 in the first region I.

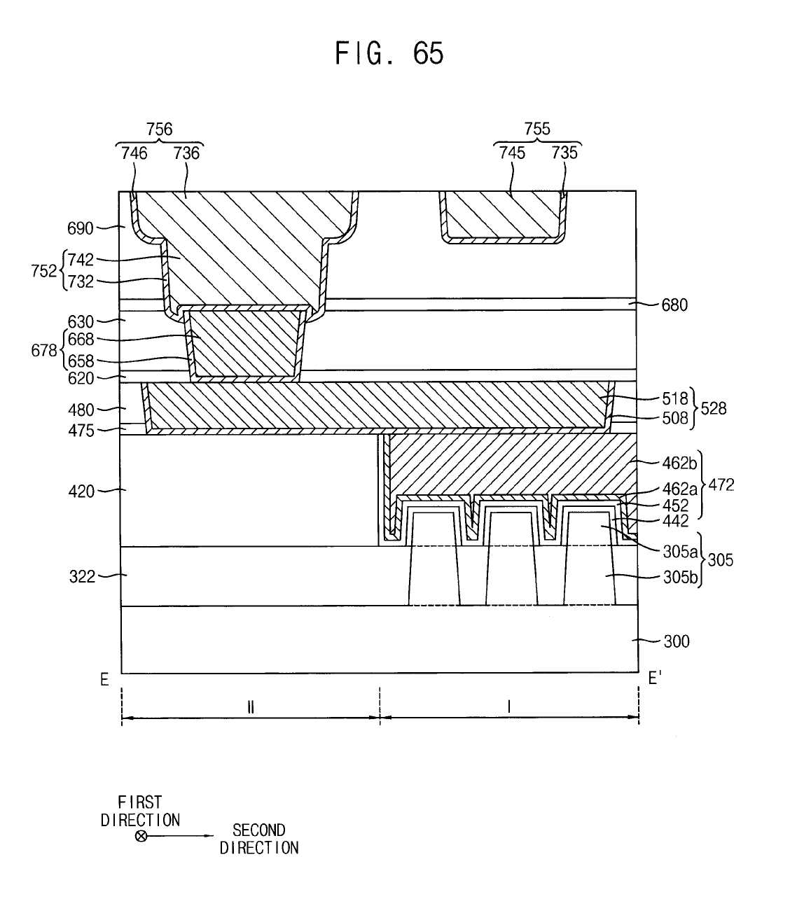

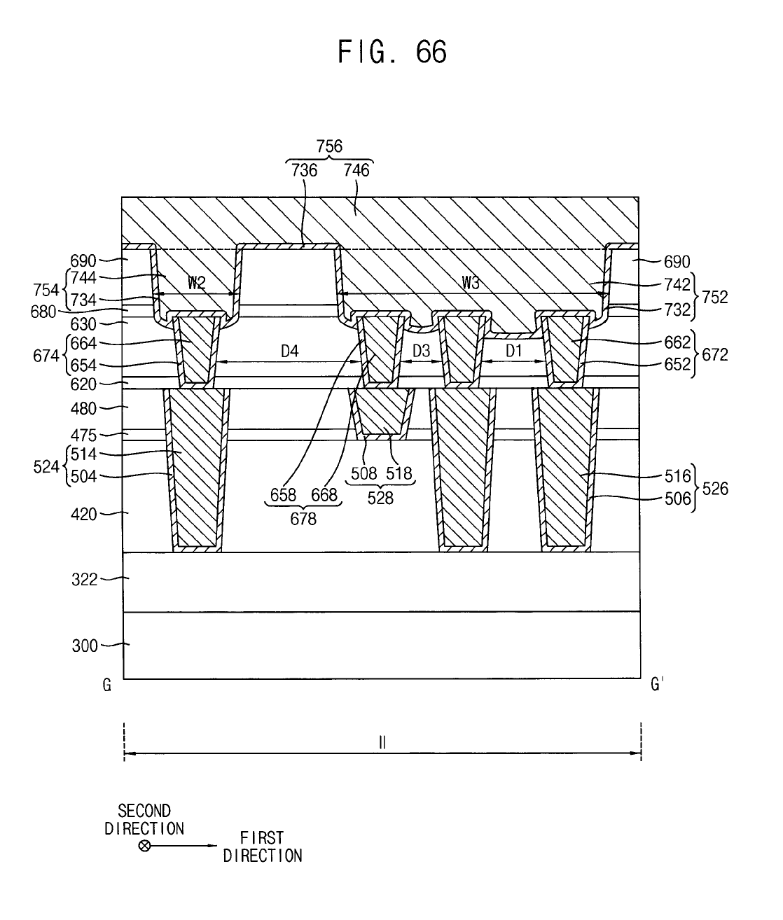

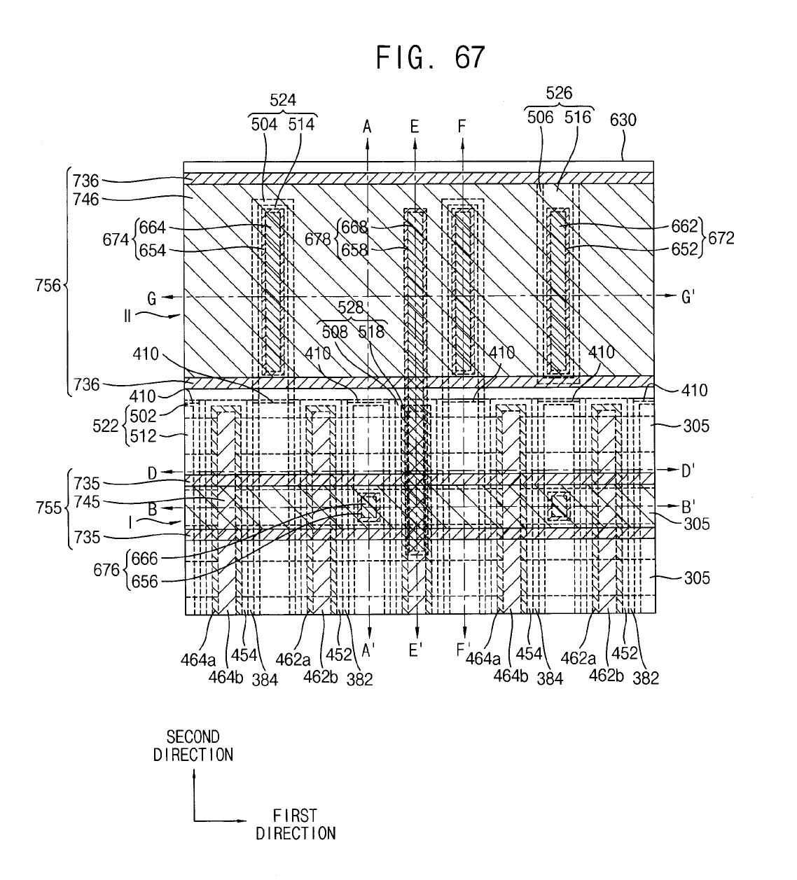

FIGS. 64 to 66 are a plan view and cross-sectional views illustrating a semiconductor device in accordance with example embodiments. Particularly, FIG. 64 is a plan view of the semiconductor device, and FIGS. 65 and 66 are cross-sectional views of the semiconductor device. FIG. 65 is a cross-sectional view taken along line E-E′ shown in FIG. 64, and FIG. 66 is a cross-sectional view taken along line G-G′ shown in FIG. 64.

The semiconductor device may be substantially the same as or similar to that described with reference to FIGS. 9 to 16, except for the lower contact plug structure, the upper contact plug structure and the via structure. Thus, like reference numerals refer to like elements, and detailed descriptions thereof may be omitted below in the interest of brevity.

Referring to FIGS. 64 to 66, the semiconductor device may include the transistor, a lower contact plug structure, an upper contact plug structure, a via structure, and the wiring structure on the substrate 300. The semiconductor device may further include the insulating interlayer structure, the etch stop layer structure, the spacer structure, and the metal silicide pattern 490 on the substrate 300.

The lower contact plug structure may penetrate through the first and second insulating interlayers 420 and 480 and a capping layer 475 therebetween, and may contact the metal silicide pattern 490 or the first gate structure 472. The lower contact plug structure may include the first, second and third lower contact plugs 522, 524 and 526 and a fourth lower contact plug 528.

In example embodiments, the fourth lower contact plug 528 may extend in the second direction in the first and second regions I and II, and may contact a top surface of the first gate structure 472 and a top surface of the first insulating interlayer 420. The fourth lower contact plug 528 may include a fourth lower barrier pattern 508 and a fourth lower conductive pattern 518 sequentially stacked, and the fourth lower barrier pattern 508 may cover a bottom and a sidewall of the fourth conductive pattern 518.

The upper contact plug structure may penetrate through the first etch stop layer 620 and the third insulating interlayer 630, and may contact the lower contact plug structure. The upper contact plug structure may include the first, second and third upper contact plugs 672, 674 and 676 and a fourth upper contact plug 678.

The fourth upper contact plug 678 may contact the fourth lower contact plug 528 in the second region II. In an example embodiment, the fourth upper contact plug 678 may be formed to be adjacent to the first upper contact plug 672, and may be spaced apart from the first upper contact plug 672 in the first direction by a third distance D3. The fourth upper contact plug 678 may be spaced apart from the second upper contact plug 674 by a fourth distance D4. The third distance D3 may be less than the fourth distance D4.

The via structure may penetrate through the second etch stop layer 680 and a lower portion of the fourth insulating interlayer 690, and may contact the upper contact plug structure. The via structure may include the first, second and third vias 752, 754 and 753.

In example embodiments, the first via 752 may contact top surfaces of the first and fourth upper contact plugs 672 and 678, and an upper surface of a portion of the third insulating interlayer 630 adjacent thereto. The second via 754 may contact a top surface of the second upper contact plug 674 and an upper surface of a portion of the third insulating interlayer 630 adjacent to the second upper contact plug 674. The third via 753 may contact a top surface of the third upper contact plug 676 and an upper surface of a portion of the third insulating interlayer 630 adjacent to the third upper contact plug 676. In example embodiments, a third width W3 of the first via 752 in the first direction may be greater than the second width W2 of the second via 754 in the first direction.

In the semiconductor device, various voltages may be applied from the second region II in which a power rail is formed to the first region I not only through the first, second and third lower contact plugs 522, 524 and 526 on the source/drain layer 410, but also through the fourth lower contact plug 528 on the first gate structure 472.

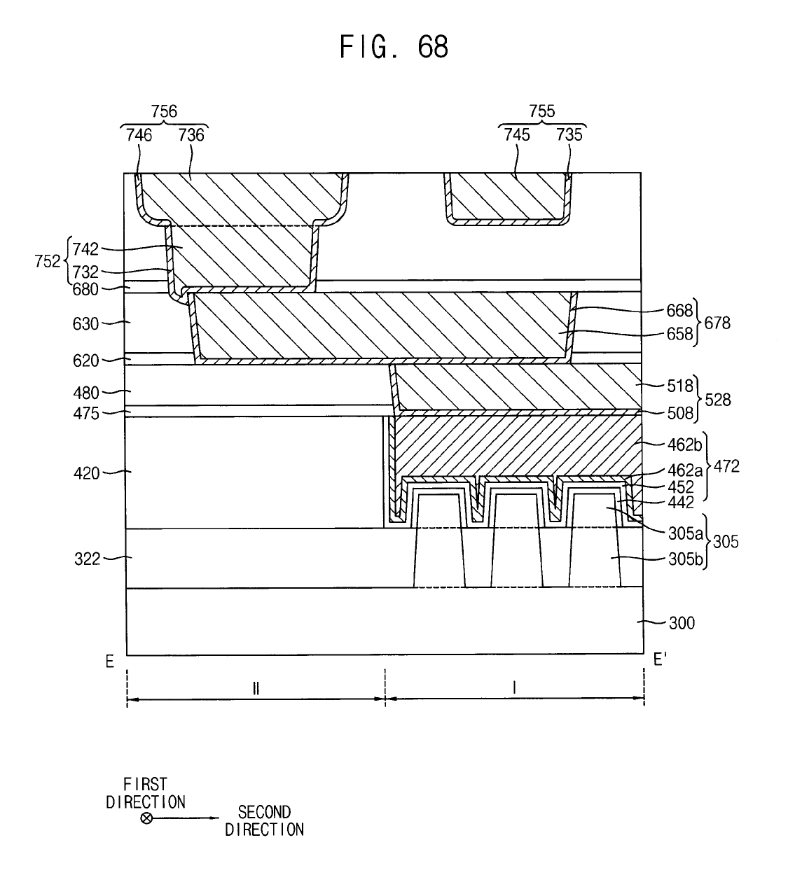

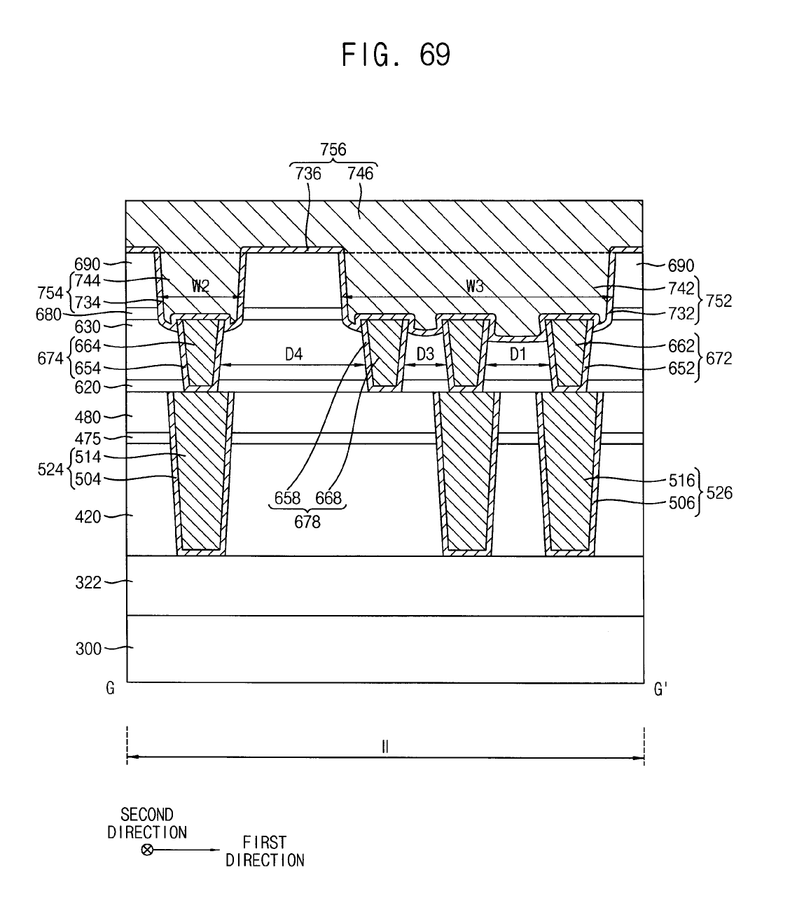

FIGS. 67 to 69 are a plan view and cross-sectional views illustrating a semiconductor device in accordance with example embodiments. Particularly, FIG. 67 is a plan view of the semiconductor device, and FIGS. 68 and 69 are cross-sectional views of the semiconductor device. FIG. 68 is a cross-sectional view taken along line E-E′ shown FIG. 67, and FIG. 69 is a cross-sectional view taken along line G-G′ shown in FIG. 67.

The semiconductor device may be substantially the same as or similar to that described with reference to FIGS. 9 to 16, except for the lower contact plug structure and the upper contact plug structure. Thus, like reference numerals refer to like elements, and detailed descriptions thereof may be omitted below in the interest of brevity.

Referring to FIGS. 67 to 69, the semiconductor device may include the transistor, a lower contact plug structure, an upper contact plug structure, the via structure, and the wiring structure on the substrate 300. The semiconductor device may further include the insulating interlayer structure, the etch stop layer structure, the spacer structure, and the metal silicide pattern 490 on the substrate 300.

The lower contact plug structure may penetrate through the first and second insulating interlayers 420 and 480 and a capping layer 475 therebetween, and may contact the metal silicide pattern 490 or the first gate structure 472. The lower contact plug structure may include the first, second and third lower contact plugs 522, 524 and 526 and a fourth lower contact plug 528. In example embodiments, the fourth lower contact plug 528 may extend in the second direction in the first region I, and may contact a top surface of the first gate structure 472.

The upper contact plug structure may penetrate through the first etch stop layer 620 and the third insulating interlayer 630, and may contact the lower contact plug structure. The upper contact plug structure may include the first, second and third upper contact plugs 672, 674 and 676 and a fourth upper contact plug 678. The fourth upper contact plug 678 may extend in the second direction in the first and second regions I and II, and may contact the fourth lower contact plug 528.

The above semiconductor device and the method of manufacturing the same may be applied to various types of memory devices including a power rail and methods of manufacturing the same. For example, the semiconductor device may be applied to a power rail of logic devices such as central processing units (CPUs), main processing units (MPUs), or application processors (APs), or the like. Additionally, the semiconductor device may be applied to a power rail of volatile memory devices such as DRAM devices or SRAM devices, or wiring structures of non-volatile memory devices such as flash memory devices, PRAM devices, MRAM devices, RRAM devices, or the like.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A semiconductor device, comprising:
a substrate including first and second cell regions and a power rail region, the first and second cell regions being disposed in a second direction, and the power rail region being disposed between the first and second regions;
a plurality of first contact plugs on the power rail region of the substrate, the plurality of first contact plugs being spaced apart from each other in a first direction by a first distance, and the first direction crossing the second direction;
a first via commonly contacting top surfaces of the first contact plugs; and
a power rail on the first via,
wherein the power rail provides a voltage for the first and second cell regions through the first via and the first contact plugs.

2. The semiconductor device of claim 1, wherein the power rail provides the voltage for the first cell region through at least one of the first via and the first contact plugs, and wherein the power rail provides the voltage for the second cell region through at least one of the first via and the first contact plugs.

3. The semiconductor device of claim 1, further comprising:
a second contact plug, wherein a second distance between the second contact plug and a nearest one of the first contact plugs thereto, in the first direction, is greater than the first distance; and
a second via contacting a top surface of the second contact plug, the second via being connected to the power rail.

4. The semiconductor device of claim 3, wherein the power rail provides the voltage for at least one of the first and second cell regions through the second via and the second contact plug.

5. The semiconductor device of claim 1, wherein the power rail and the first via include substantially the same material and integrally formed with each other.

6. The semiconductor device of claim 1, wherein a bottom of the first via is lower than the top surfaces of the first contact plugs.

7. The semiconductor device of claim 1, further comprising:
a first insulating interlayer on the substrate;
a first etch stop layer on the first insulating interlayer; and
a second insulating interlayer on the first etch stop layer,
wherein each of the first contact plugs penetrates through the second insulating interlayer and the first etch stop layer.

8. The semiconductor device of claim 7, wherein a bottom of the first via is lower than a top surface of the second insulating interlayer and higher than a top surface of the first etch stop layer.

9. The semiconductor device of claim 7, wherein a bottom of the first via contacts a top surface of the first etch stop layer.

10. The semiconductor device of claim 7, further comprising:
a second etch stop layer on the second insulating interlayer; and
a third insulating interlayer on the second etch stop layer,
wherein the first via penetrates through a lower portion of the third insulating interlayer and the second etch stop layer, and wherein the power rail penetrates through an upper portion of the third insulating interlayer and extends in the first direction.

11. The semiconductor device of claim 10, wherein the first via partially penetrates through an upper portion of the second insulating interlayer, and wherein a bottom of the first via is lower than the top surfaces of the first contact plugs.

12. The semiconductor device of claim 7, further comprising:
a gate structure on at least one of the first and second cell regions of the substrate;
a source/drain layer on a portion of the substrate adjacent to the gate structure;
a lower insulating interlayer between the substrate and the first insulating interlayer, the lower insulating interlayer covering a sidewall of the gate structure and the source/drain layer; and
a third contact plug on the source/drain layer, the third plug penetrating through the lower insulating interlayer and the first insulating interlayer and contacting one of the first contact plugs.

13. The semiconductor device of claim 12, wherein the third contact plug extends in the second direction, and is also formed on the power rail region of the substrate.

14. The semiconductor device of claim 12, wherein one of the first contact plugs extends in the second direction, and is formed on at least one of the first and second cell regions of the substrate on which the gate structure is formed.

15. The semiconductor device of claim 12, wherein a plurality of gate structures is formed in the first direction, and wherein the plurality of gate structures includes:
a first gate structure having a thickness varying in the second direction, the first gate structure being an active gate; and
a second gate structure having a thickness constant in the second direction, the first gate structure being a dummy gate.

16. The semiconductor device of claim 15, wherein top surfaces of the first and second gate structures are substantially coplanar with each other,
and wherein a bottom of the first gate structure has a height that varies in the second direction, and a bottom of the second gate structure has a height that is constant in the second direction.

17-20. (canceled)

21. A semiconductor device, comprising:
a substrate including a cell region and a power rail region, cells being formed in the cell region and a power rail being formed in the power rail region, and the power rail providing a voltage for the cells;
an active fin on the substrate, the active fin protruding from a top surface of an isolation pattern on the substrate, and the active fin extending in a first direction;
a gate structure extending in a second direction on the active fin and the isolation pattern, the second direction crossing the first direction;
a source/drain layer on a portion of the active fin adjacent to the gate structure;
a first lower contact plug on the source/drain layer;
a plurality of upper contact plugs disposed in the first direction on the power rail region of the substrate, at least one of the upper contact plugs being electrically connected to the first lower contact plug;
a first via commonly contacting top surfaces of the upper contact plugs; and
a power rail on the first via, the power rail extending in the first direction.

22. The semiconductor device of claim 21, wherein the active fin, the gate structure and the source/drain layer are formed on the cell region of the substrate.

23. The semiconductor device of claim 22, wherein the first lower contact plug extends in the first direction and contacts a bottom of at least one of the upper contact plugs, so that the first lower contact plug is formed on the cell region and the power rail region of the substrate.

24-34. (canceled)

35. A semiconductor device, comprising:
a substrate including a plurality of cell regions and a plurality of power rail regions, the cell regions and the power rail regions being alternately and repeatedly disposed in a second direction;
finFETs on the cell regions;
a lower contact plug structure electrically connected to at least one of the finFETs;
an upper contact plug structure on each of the power rail regions, the upper contact plug structure being electrically connected to the lower contact plug structure, and the upper contact plug structure including:
a plurality of first upper contact plugs adjacent to each other in a first direction substantially perpendicular to the second direction; and
a second upper contact plug;
a via structure on each of the power rail regions, the via structure including:
a first via commonly contacting top surfaces of the first upper contact plugs and having a first width in the first direction; and
a second via contacting the second upper contact plug and having a second width in the first direction less than the first width; and
a power rail being integrally formed with the via structure, the power rail providing a voltage for at least one of the finFETs.

36-50. (canceled)
